(19) United States
(12) Patent Application Publication
(10) Pub. No.: US 2006/0260671 A1
(43) Pub. Date: Nov. 23, 2006

(54) Semiconductor device and semiconductor light emitting device

(75) Inventors: Hiroaki Ohta, Kyoto-shi (JP); Toshio Nishida, Kyoto-shi (JP)

Correspondence Address: HOGAN & HARTSON L.L.P., 1999 AVENUE OF THE STARS, SUITE 1400, LOS ANGELES, CA, 90067, US

(73) Assignee: ROHM CO., LTD.

(21) Appl. No.: 11/430,795

(22) Filed: May 8, 2006

(30) Foreign Application Priority Data
May 17, 2005 (JP) JP2005-143500
May 17, 2005 (JP) JP2005-143502

(51) Int. Cl. H01L 31/00

(52) U.S. Cl. 136/249; 257/198

(57) ABSTRACT

In the invention, a band gap change layer in which a composition is changed in a depositing direction is arranged between two semiconductor layers having the different compositions to decrease polarization generated by depositions of the two semiconductor layers.

The disclosures of Japanese Patent Application No. 2005-143500 and Japanese Patent Application No. 2005-143502 filed May, 17, 2005 including specification, drawings and claims are incorporated herein by reference in its entirety.

### BACKGROUND OF THE INVENTION

1. Field of the Invention

The present invention relates to a semiconductor device formed by depositing plural semiconductor layers.

2. Description of the Related Art

(First Related Art)

Recently a high-frequency device or a semiconductor light emitting device, used in high-speed communication instruments being developed, is formed by depositing plural semiconductor thin films on a substrate. Sometimes plural semiconductor devices in which the semiconductor thin films are deposited on the substrate are formed in a mesa shape in order to separate adjacent semiconductor devices from each other (for example, see http://www3.fed.or.jp/pub/review/FEDreviewVlN12ElSanoE.pdf; Research and Development Association for Future Electron Devices (Abbreviation:FED)(ONLINE JOURNAL “FED REVIEW”, December, 2001, “InP system Super High Frequency Device” by Mr. Eiichi Sano). For example, compound semiconductors such as InAlAs and InGaAs are deposited on an InP substrate by epitaxial growth, electrodes of a gate, a source, and a drain are formed of metal such as Ti/Al and Ni/Al, and a mesa is formed to perform device isolation by dry etching or the like.

Sometimes a part of the semiconductor device is formed in the mesa shape to narrow a carrier moving path in order to concentrate carriers from the electrode in a particular position of the semiconductor device. For example, in the semiconductor light emitting device, not only in order to improve a single-peak property of a light intensity distribution (transverse mode) but also in order to improve coupling efficiency between the semiconductor light emitting device and an external device such as an optical pickup, a part of the semiconductor light emitting device is formed in the mesa shape to narrow the carrier flow, which concentrates the carriers in an active layer (for example, see Japanese Patent Application Laid-Open No. 11-177175).

In the following description, “a part of the semiconductor device formed in the mesa shape” is abbreviated to “mesa”. “A neighborhood of a surface in which a junction portion between a contact layer and a first semiconductor layer emerges in the mesa” is referred to as “a neighborhood of a side wall of the mesa” and “an inside separated from the side wall of the mesa” is referred to as “a center portion of the mesa.”

FIG. 7 is a conceptual view showing a cross section of a conventional semiconductor device 707. The semiconductor device 707 includes an electrode 111, a substrate 112, a first semiconductor layer 115, a second semiconductor layer 117, a contact layer 118, and an electrode 119. In the semiconductor device 707, the mesa (mesa 107) is formed in the range of the electrode 119 to a part of the first semiconductor layer 115.

(Second Related Art)

A basic structure of the semiconductor light emitting device is a double heterojunction structure including a semiconductor layer called an active layer which generates light by recombination of the carriers and semiconductor layers called carrier supply layers which sandwich the active layer from both sides to supply the carriers to the active layer. Because a wavelength of the emitting light is determined by a band gap of the active layer, a material and a configuration are selected as the active layer such that the light having the desired wavelength is obtained. In order to easily supply the carriers to the active layer, the carrier supply layer is designed such that the band gap is broader than that of the active layer, and an impurity for determining a type (hole or electron) of the carrier is added in the carrier supply layer.

In the semiconductor light emitting device, particularly in a laser diode, not only in order to improve the single-peak property of the light intensity distribution (transverse mode) but also in order to improve the coupling efficiency between the semiconductor light emitting device and the external device such as the optical pickup, further in order to efficiently emit the light in the semiconductor light emitting device, it is necessary that the carriers be supplied while concentrated in a part of the active layer. Accordingly, the laser diode frequently has a stripe structure in which the electrode and the carrier supply layer are formed in the stripe shape in a direction perpendicular to a thickness direction (depositing direction) (for example, see Japanese Patent Application Laid-Open No. 05-055696).

FIG. 21 is a conceptual view showing a cross section of a conventional semiconductor light emitting device 840. The semiconductor light emitting device 840 adopts a stripe-shape electrode which supplies the carriers to a part of the active layer while concentrated. The stripe-shape electrode shall mean an electrode in which the metal electrode deposited adjacent to the semiconductor layer is formed in a strip shape like a microstrip line. For example, the semiconductor light emitting device 840 includes an electrode 211, an n-type substrate 212, an n-side first semiconductor layer 225 which is of a carrier supply layer for supplying electrons, an n-type second semiconductor layer 227, an active layer 214, a p-side first semiconductor layer 215 which is of a carrier supply layer for supplying holes, a p-type second semiconductor layer 217, and a stripe-shape electrode 219. In the semiconductor light emitting device 840, sometimes one or more semiconductor layers are arranged at least between the n-type second semiconductor layer 227 and the n-type substrate 212 or between the p-type second semiconductor layer 217 and the stripe-shape electrode 219. Sometimes the active layer 214 has an electron barrier layer on the side of the p-side first semiconductor layer 215 of the active layer 214 in order to prevent overflow of electron carriers.

### SUMMARY OF THE INVENTION

(First Object)

However, sometimes two semiconductor layers having different compositions are deposited adjacent to each other due to device requirements. For example, in the case where the first semiconductor layer 115 and the second semiconductor layer 117 are made of group-III nitride compounds similar to a semiconductor device 707 shown in FIG. 7 while having the different compositions, when the mesa 107 including the first semiconductor layer 115 and second semiconductor layer 117 is formed, a polarization charge caused by spontaneous polarization or lattice strain (hereinafter “piezoelectric polarization caused by spontaneous polarization or lattice strain” is abbreviated to “polarization”) is generated between the first semiconductor layer 115 and the second semiconductor layer 117. Particularly, the polarization charge emerges prominently at a hetero interface of a heterostructure in the group-III nitride compound which is deposited in a c-axis direction. In the case where the polarization charge is generated between the first semiconductor layer 115 and the second semiconductor layer 117, the carriers which are moved in the depositing direction of the mesa 107 from the second semiconductor layer 117 to the first semiconductor layer 115 receive repulsive force from an electric field of the polarization charge, and the carriers are moved while concentrated in the neighborhood of the side wall of the 107 as shown by carrier flows 191 of FIG. 7. However, because the neighborhood of the side wall of the mesa 107 has defective crystallinity due to the influence in forming the mesa 107, there is a problem that carrier transport is obstructed to increase an electrical resistance of the semiconductor device 707.

In view of the foregoing, a first object of the invention is to provide a semiconductor device in which the carriers can be smoothly moved and thereby the electrical resistance is decreased in the mesa where the two semiconductor layers having the different compositions from each other, are deposited.

(Second Object)

As shown in FIG. 21, in order to improve electric characteristics or to confine the light emitted at the active layer 214, the semiconductor light emitting device often includes the p-side first semiconductor layer 215 on the p-type side with respect to the active layer 214 between the p-type second semiconductor layer 217 and the active layer 214. However, in the case where the p-side first semiconductor layer 215 and the p-type second semiconductor layer 217 are made of the group-III nitride compounds while having the different compositions, the polarization charge is generated by the polarization between the p-side first semiconductor layer 215 and the p-type second semiconductor layer 217 due to the differences in polarization characteristics and lattice constant. Accordingly, in the case where the positive polarization charge is generated between the p-side first semiconductor layer 215 and the p-type second semiconductor layer 217, the holes which are partially injected into the p-type second semiconductor layer 217 by the stripe-shape electrode 219 receive the repulsive force from the electric field of the polarization charge. Accordingly, the hole transport from the p-type second semiconductor layer 217 to the p-side first semiconductor layer 215 is obstructed, which causes the holes to diffuse in the p-side first semiconductor layer 215 as shown by hole flows 291 of FIG. 21. On the other hand, in order to improve the electric characteristics or to confine the light emitted at the active layer 214, similarly to the p-type side, the semiconductor light emitting device often includes the n-side first semiconductor layer 225 on the n-type side of the active layer 214 between the n-type second semiconductor layer 227 and the active layer 214. Similarly to the p-type side, in the case where the negative polarization charge is generated by the polarization, the electron transport is obstructed.

Particularly, the polarization charge emerges prominently at the hetero interface of the heterostructure in the group-III nitride compound which is deposited in the c-axis direction, and the carrier transport is caused to become smooth by enhancing an impurity concentration. However, the enhancement of the impurity concentrations of the p-side first semiconductor layer 215 and n-side first semiconductor layer 225 which are located near the active layer 214 has an influence on optical characteristics and reliability of the semiconductor light emitting device 840 such as light absorption by the impurity and impurity diffusion into the active layer 214. Accordingly, there is a problem that a good balance is difficult to achieve between the smooth carrier transport and the optical characteristics and reliability of the semiconductor light emitting device 840.

In view of the foregoing, a second object of the invention is to provide a semiconductor light emitting device in which the carriers can be smoothly moved between the two semiconductor layers having the different compositions without enhancing the impurity concentration, namely, without degrading the optical characteristics and reliability.

In order to achieve the first object, in the invention, a band gap change layer in which the composition is changed in the depositing direction is arranged between the two semiconductor layers having the different compositions deposited in the mesa.

Specifically, a first aspect of the invention is a semiconductor device including a first semiconductor layer which is deposited on a substrate, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the substrate, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1); and an electrode which is located on an opposite side to the band gap change layer of the second semiconductor layer, a voltage being applied to the electrode from the outside, wherein, in the depositing direction, the semiconductor device is formed in a mesa shape in a range of the electrode to the second semiconductor layer or to the first semiconductor layer, and in the depositing direction from the first semiconductor layer toward the second semiconductor layer, a band gap of the band gap change layer is continuously monotonously changed from a band gap which is substantially equal to that of the first semiconductor layer to the first semiconductor layer to a band gap which is substantially equal to that of the second semiconductor layer from the side adjacent to the first semiconductor layer to the side adjacent to the second semiconductor layer.

The group-III nitride compound expressed by the composition formula of AlₓGa_{y}In_{1-x-y}N (0≦x≦1, 0≦y≦1, and 0≦x+y≦1) is a semiconductor in which the band gap can be adjusted by changing the composition. Accordingly, in the group-III nitride compound, the band gap of the band gap change layer can monotonously be changed by monotonously changing the composition designated by x and y.

According to the first aspect of the invention, in the band gap change layer where the composition is continuously monotonously changed from the composition of the second semiconductor layer to the composition of the first semiconductor layer, the side which is equal to the composition of the second semiconductor layer is caused to be adjacent to the second semiconductor layer, and the side which is equal to the composition of the first semiconductor layer is caused to be adjacent to the first semiconductor layer. The band gap change layer can avoid the steep change in composition from the second semiconductor layer to the first semiconductor layer, and the band gap change layer can continuously monotonously change the band gap from the second semiconductor layer to the first semiconductor layer. Accordingly, in the band gap change layer, the polarization charge can be dispersed between the second semiconductor layer and the first semiconductor layer, and the repulsive force to the polarization charge from the electric field is decreased, so that the carriers can be smoothly moved from the second semiconductor layer to the first semiconductor layer. Therefore, in the depositing direction, the mesa shape is formed in the range of the electrode to the second semiconductor layer or to the first semiconductor layer, which allows the carriers to be smoothly moved through the center portion of the mesa having the good crystallinity.

Accordingly, the first aspect of the invention can provide a semiconductor device in which the carriers can be smoothly moved and thereby the electrical resistance becomes low in the mesa where the two semiconductor layers having the different compositions are deposited.

A second aspect of the invention is a semiconductor device including a first semiconductor layer which is deposited on a substrate, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the substrate, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1); and an electrode which is located on an opposite side to the band gap change layer of the second semiconductor layer, a voltage being applied to the electrode from the outside, wherein, in the depositing direction, the semiconductor device is formed in a mesa shape in a range of the electrode to the second semiconductor layer or the first semiconductor layer, and in the depositing direction from the first semiconductor layer toward the second semiconductor layer, a band gap of the band gap change layer is monotonously changed in the stepwise manner from a band gap which is substantially equal to that of the first semiconductor layer to a band gap which is substantially equal to that of the second semiconductor layer from the side adjacent to the first semiconductor layer to the side adjacent to the second semiconductor layer.

The group-III nitride compound expressed by the composition formula of AlₓGa_{y}In_{1-x-y}N (0≦x≦1, 0≦y≦1, and 0≦x+y≦1) is a semiconductor in which the band gap can be adjusted by changing the composition. Accordingly, the plural group-III nitride compound thin films having the compositions designated by the different values of x and y are deposited to form the band gap change layer, which allows the band gap of the band gap change layer to be monotonously changed in the stepwise manner.

According to the second aspect of the invention, in the band gap change layer where the composition is monotonously changed in the stepwise manner from the composition of the second semiconductor layer to the composition of the first semiconductor layer, the side which is equal to the composition of the second semiconductor layer is caused to be adjacent to the second semiconductor layer, and the side which is equal to the composition of the first semiconductor layer is caused to be adjacent to the first semiconductor layer. The band gap change layer can avoid the steep change in composition from the second semiconductor layer to the first semiconductor layer, and the band gap change layer can monotonously change the band gap in the stepwise manner from the second semiconductor layer to the first semiconductor layer. Accordingly, in the band gap change layer, the polarization charge can be dispersed between the second semiconductor layer and the first semiconductor layer, and the repulsive force to the polarization charge from the electric field is decreased, so that the carriers can be smoothly moved from the second semiconductor layer to the first semiconductor layer. Therefore, in the depositing direction, the mesa shape is formed in the range of the electrode to the second semiconductor layer or to the first semiconductor layer, which allows the carriers to be smoothly moved through the center portion of the mesa having the good crystallinity.

Accordingly, the second aspect of the invention can provide a semiconductor device in which the carriers can be smoothly moved and thereby the electrical resistance becomes low in the mesa where the two semiconductor layers having the different compositions are deposited.

In a semiconductor device according to the invention, the second semiconductor layer is preferably formed into the p-type semiconductor. In the case where the second semiconductor layer is the p-type semiconductor, the carrier moved through the mesa becomes the hole. When compared with the electron, it is difficult that the hole having the large effective mass is moved near the sidewall of the mesa having the defective crystallinity. Therefore, the electrical resistance is large due to the polarization charge in the p-type mesa in which the holes are moved near the side wall of the mesa. The holes are smoothly moved near the center portion of the mesa by arranging the band gap change layer in the p-type mesa, so that the electrical resistance is decreased in the mesa.

Accordingly, the invention can provide a semiconductor device in which the carriers can be smoothly moved and thereby the electrical resistance becomes low in the mesa where the two semiconductor layers having the different compositions are deposited.

In a semiconductor device according to the invention, the thickness in the depositing direction of the band gap change layer is preferable 3 (nm) or more and less than 100 (nm).

In the band gap change layer which is inserted in order to mitigate the steep change in composition between the first semiconductor layer and the second semiconductor layer, it is necessary that the thickness in the depositing direction (hereinafter “thickness in depositing direction” is abbreviated to “thickness”) be 3 (nm) or more. On the other hand, because the electrical resistance is increased in propotion to the distance in the depositing direction of the mesa, the thickness of the band gap change layer is desirably lower than 100 (nm).

Accordingly, the invention can provide a semiconductor device in which the carriers can be smoothly moved and thereby the electrical resistance becomes low in the mesa where the two semiconductor layers having the different compositions are deposited.

In a semiconductor device according to the invention, the depositing directions of the first semiconductor layer, the band gap change layer, and the second semiconductor layer are preferably parallel to c-axis directions of the group-III nitride compound crystals of the first semiconductor layer, the band gap change layer, and the second semiconductor layer.

Even if the crystals of the group-III nitride compounds in which the polarization charge emerges prominently are deposited while orientated toward the c-axis direction, the polarization charge can be decreased to smoothly perform the carrier transport between the first semiconductor layer and the second semiconductor layer by sequentially depositing the first semiconductor layer, the band gap change layer, and the second semiconductor layer.

Accordingly, the invention can provide a semiconductor device in which the carriers can be smoothly moved and thereby the electrical resistance becomes low in the mesa where the two semiconductor layers having the different compositions are deposited.

In a semiconductor device according to the invention, assuming that ρ (cm⁻²) is charge density of polarization generated at an interface where the group-III nitride compound of the first semiconductor layer and the group-III nitride compound of the second semiconductor layer are adjacent to each other and d (cm) is the thickness of the band gap change layer, an impurity concentration n (cm⁻³) of an impurity added into the band gap change layer is preferably in a range of 0.5ρ/d≦n≦3ρ/d.

In order to decrease the electrical resistance of the semiconductor device, the impurity is preferably added to the band gap change layer. On the other hand, when the impurity concentration becomes high, the number of crystal defects is increased, and the electrical resistance of the semiconductor device cannot be decreased. In the case where the semiconductor device is used as the light emitting device, a light quantity absorbed in the crystal defect is increased, and then luminous efficiency is decreased. In the case where Mg is added as the impurity, the semiconductor device is degraded to decrease reliability by the Mg diffusion. Accordingly, the impurity concentration of the band gap change layer preferably exists in the above range.

A semiconductor device according to the invention further includes an active layer between the substrate and the first semiconductor layer, the active layer emitting light by recombination of an electron and a hole, wherein the first semiconductor layer functions as a light guide layer which guides the light emitted from the active layer, the light guide layer having relationship of x=0 and 0.95≦y≦1 in the composition formula, the second semiconductor layer functions as a cladding layer which supplies carriers to the active layer, the cladding layer having a relationship of x=m (0.05≦m≦0.1) and x+y=1 in the composition formula, a composition of the band gap change layer ranges within a relationship of 0≦x≦m and x+y=1 in the composition formula, and the semiconductor device functions as a semiconductor laser for the entire structure in which the first semiconductor layer, the band gap change layer, the second semiconductor layer, and the active layer are deposited.

The composition of the group-III nitride compound of the second semiconductor layer is set at the relationship of x=m (0.05≦m≦0.1) and x+y=1 in the composition formula, namely, at AlₘGa₁₋ₘN, and composition of the group-III nitride compound of the first semiconductor layer is set at the relationship of x=0 and y=1 in the composition formula, namely, at GaN. Therefore, the band gap of the second semiconductor layer becomes larger than that of the first semiconductor layer. Accordingly, the carriers can be smoothly moved to the first semiconductor layer from the second semiconductor layer through the band gap change layer, and the second semiconductor layer functions as the cladding layer which supplies the carriers.

The composition of the group-III nitride compound of the first semiconductor layer is set at the relationship of x=0 and 0.95≦y≦1 in the composition formula, namely, at the GaN or InGaN compound. That is, the refractive index is decreased, and the light emitted from the active layer is reflected by the first semiconductor layer. Therefore, because the first semiconductor layer promotes induced emission while guiding the light emitted from the active layer, the first semiconductor layer functions as the light guide layer.

Accordingly, the invention can provide a semiconductor device which can function as the semiconductor laser having the low electrical resistance by smoothly moving the carriers in the mesa where the two semiconductor layers having the different compositions are deposited.

In order to achieve the second object, in the invention, a band gap change layer in which the composition is changed in the depositing direction is arranged between the two semiconductor layers having the different compositions.

Specifically, a third aspect of the invention is a semiconductor light emitting device including an active layer which emits light by recombination of an electron and a hole; a first semiconductor layer which is deposited on a p-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the p-type side with respect to the active layer and a center in the direction of thickness of the band gap change layer ranges from 30 (nm) to 200 (nm), and a band gap of the band gap change layer is continuously monotonously changed from a band gap which is substantially equal to that of the first semiconductor layer to a band gap which is substantially equal to that of the second semiconductor layer from the side adjacent to the first semiconductor layer to the side adjacent to the second semiconductor layer.

The group-III nitride compound expressed by the composition formula of AlₓGa_{y}In_{1-x-y}N (0≦x≦1, 0≦y≦1, and 0≦x+y≦1) is a semiconductor in which the bandgap can be adjusted by changing the composition. Accordingly, in the group-III nitride compound, the band gap of the band gap change layer can monotonously be changed by monotonously changing the composition designated by x and y.

According to the third aspect of the invention, on the p-type side with respect to the active layer, the side which is equal to the composition of the second semiconductor layer is caused to be adjacent to the second semiconductor layer in the band gap change layer where the composition is continuously monotonously changed from the composition of the second semiconductor layer to the composition of the first semiconductor layer, and the side which is equal to the composition of the first semiconductor layer is caused to be adjacent to the first semiconductor layer. The band gap change layer can avoid the steep change in composition from the second semiconductor layer to the first semiconductor layer, and the band gap change layer can continuously monotonously change the band gap from the second semiconductor layer to the first semiconductor layer. Accordingly, in the band gap change layer, the polarization charge can be dispersed between the second semiconductor layer and the first semiconductor layer, and the repulsive force to the polarization charge from the electric field is decreased, so that the holes which are of the carrier can be smoothly moved from the second semiconductor layer to the first semiconductor layer.

In the depositing direction of the active layer, a distance between the end on the p-type side and the center in the direction of thickness of the band gap change layer rages from 30 (nm) to 200 (nm). Therefore, the carriers can be moved through the second semiconductor layer, the band gap change layer, and the first semiconductor layer to reach the active layer, and the impurity added to the first semiconductor layer near the active layer can be decreased.

Accordingly, the third aspect of the invention can provide a semiconductor light emitting device in which the carriers can be smoothly moved between the two semiconductor layers having the different compositions without enhancing the impurity concentration, namely, without degrading the optical characteristics and reliability.

A fourth aspect of the invention is a semiconductor light emitting device including an active layer which emits light by recombination of an electron and a hole; a first semiconductor layer which is deposited on a p-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the p-type side with respect to the active layer and a center in the direction of thickness of the band gap change layer ranges from 30 (nm) to 200 (nm), and a band gap of the band gap change layer is monotonously changed in the stepwise manner from a band gap which is substantially equal to that of the first semiconductor layer to a band gap which is substantially equal to that of the second semiconductor layer from the side adjacent to the first semiconductor layer to the side adjacent to the second semiconductor layer.

The group-III nitride compound expressed by the composition formula of AlₓGa_{y}In_{1-x-y}N (0≦x≦1, 0≦y≦1, and 0≦x+y≦1) is a semiconductor in which the band gap can be adjusted by changing the composition. Accordingly, the plural group-III nitride compound thin films having the compositions designated by the different values of x and y are deposited to form the band gap change layer, which allows the band gap of the band gap change layer to be monotonously changed in the stepwise manner.

According to the fourth aspect of the invention, on the p-type side with respect to the active layer, the side which is equal to the composition of the second semiconductor layer is caused to be adjacent to the second semiconductor layer in the band gap change layer where the composition is monotonously changed in the stepwise manner from the composition of the second semiconductor layer to the composition of the first semiconductor layer, and the side which is equal to the composition of the first semiconductor layer is caused to be adjacent to the first semiconductor layer. The band gap change layer can avoid the steep change in composition from the second semiconductor layer to the first semiconductor layer, and the band gap change layer can monotonously change the band gap in the stepwise manner from the second semiconductor layer to the first semiconductor layer. Accordingly, in the band gap change layer, the polarization charge can be dispersed between the second semiconductor layer and the first semiconductor layer, and the repulsive force to the polarization charge from the electric field is decreased, so that the holes which are of the carrier can be smoothly moved from the second semiconductor layer to the first semiconductor layer.

In the depositing direction of the active layer, the distance between the end on the p-type side with respect to the active layer and the center in the direction of thickness of the band gap change layer ranges from 30 (nm) to 200 (nm). Therefore, the carriers can be smoothly moved through the second semiconductor layer, the band gap change layer, and the first semiconductor layer to reach the active layer, and the impurity added to the first semiconductor layer near the active layer can be decreased.

Accordingly, the fourth aspect of the invention can provide a semiconductor light emitting device in which the carriers can be smoothly moved between the two semiconductor layers having the different compositions without enhancing the impurity concentration, namely, without degrading the optical characteristics and reliability.

A semiconductor light emitting device according to the third and fourth aspects of the invention further includes an electrode which is located on an opposite side to the band gap change layer of the second semiconductor layer, a voltage being applied to the electrode from the outside, and the semiconductor light emitting device may be formed in a mesa shape in a range of the electrode to the second semiconductor layer or to the first semiconductor layer.

In order to supply the carriers while the carriers are concentrated in a part of the active layer, sometimes a part of the semiconductor light emitting device is formed in the mesa shape, a moving path of the carriers is narrowed, and the electric current is narrowed down.

In the case where the group-III nitride compounds having the different compositions are deposited in the mesa, the holes receive the repulsive force of the polarization charge, and the holes are moved while concentrated in the neighborhood of the mesa side wall having the defective crystallinity, which obstructs the smooth hole transport. In the invention, in the case where the semiconductor light emitting device is formed in the mesa shape up to the first semiconductor layer, the band gap change layer is included in the mesa. Because the band gap change layer can decrease the polarization charge, the holes can be moved near the center portion of the mesa, and the hole transport can smoothly be performed from the second semiconductor layer to the first semiconductor layer.

On the other hand, in the case where the group-III nitride compounds having the different compositions are deposited between the mesa-shaped semiconductor layer and the active layer, because the holes receive the repulsive force of the polarization charge, the holes narrowed down by the mesa are diffused in the group-III nitride compounds. The band gap change layer can decrease the polarization charge. Therefore, in the invention, the semiconductor light emitting device is formed in the mesa shape up to the second semiconductor layer, the holes passing through the mesa are not diffused in the second semiconductor layer, but the holes can be smoothly moved to the first semiconductor layer from the second semiconductor layer through the band gap change layer.

Accordingly, the third aspect and fourth aspect of the invention can provide a semiconductor light emitting device in which the carriers can be smoothly moved between the two semiconductor layers having the different compositions without enhancing the impurity concentration, namely, without degrading the optical characteristics and reliability. When compared with the electron, because the hole having the large effective mass is easily affected by the neighborhood of the side wall of the mesa having the defective crystallinity, the band gap change layer has the large effect.

A fifth aspect of the invention is a semiconductor light emitting device including an active layer which emits light by recombination of an electron and a hole; a first semiconductor layer which is deposited on an n-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the n-type side with respect to the active layer and a center in the direction of thickness of the band gap change layer ranges from 30 (nm) to 200 (nm), and a band gap of the band gap change layer is continuously monotonously changed from a band gap which is substantially equal to that of the first semiconductor layer to a band gap which is substantially equal to that of the second semiconductor layer from the side adjacent to the first semiconductor layer to the side adjacent to the second semiconductor layer.

Similarly to the third aspect of the invention, even on the n-type side with respect to the active layer, the band gap change layer can disperse the polarization charge in the range of the second semiconductor layer to the first semiconductor layer. Therefore, the repulsive force to the polarization charge from the electric field is decreased, and the electrons which are of the carrier can be smoothly moved from the second semiconductor layer to the first semiconductor layer.

In the depositing direction of the active layer, the distance between the end on the n-type side with respect to the active layer and the center in the direction of thickness of the band gap change layer ranges from 30 (nm) to 200 (nm). Therefore, the carriers can be smoothly moved through the second semiconductor layer, the band gap change layer, and the first semiconductor layer to reach the active layer, and the impurity added to the first semiconductor layer near the active layer can be decreased.

Accordingly, the fifth aspect of the invention can provide a semiconductor light emitting device in which the carriers can be smoothly moved between the two semiconductor layers having the different compositions without enhancing the impurity concentration, namely, without degrading the optical characteristics and reliability.

A sixth aspect of the invention is a semiconductor light emitting device including an active layer which emits light by recombination of an electron and a hole; a first semiconductor layer which is deposited on an n-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the n-type side with respect to the active layer and a center in the direction of thickness of the band gap change layer ranges from 30 (nm) to 200 (nm), and a band gap of the band gap change layer is monotonously changed in the stepwise manner from a band gap which is substantially equal to that of the first semiconductor layer to a band gap which is substantially equal to that of the second semiconductor layer from the side adjacent to the first semiconductor layer to the side adjacent to the second semiconductor layer.

Similarly to the fourth aspect of the invention, even on the n-type side with respect to the active layer, the band gap change layer can disperse the polarization charge in the range of the second semiconductor layer to the first semiconductor layer. Therefore, the repulsive force to the polarization charge from the electric field is decreased, and the electrons which are of the carrier can be smoothly moved from the second semiconductor layer to the first semiconductor layer.

In the depositing direction of the active layer, the distance between the end on the n-type side with respect to the active layer and the center in the direction of thickness of the band gap change layer ranges from 30 (nm) to 200 (nm). Therefore, the carriers can be smoothly moved through the second semiconductor layer, the band gap change layer, and the first semiconductor layer to reach the active layer, and the impurity added to the first semiconductor layer near the active layer can be decreased.

Accordingly, the sixth aspect of the invention can provide a semiconductor light emitting device in which the carriers can be smoothly moved between the two semiconductor layers having the different compositions without enhancing the impurity concentration, namely, without degrading the optical characteristics and reliability.

In the semiconductor light emitting device according to the invention, the thickness of the band gap change layer is desirably 3 (nm) or more and less than 100 (nm).

In the band gap change layer which is inserted in order to mitigate the steep change in composition between the first semiconductor layer and the second semiconductor layer, it is necessary that the thickness be 3 (nm) or more. On the other hand, because the electrical resistance is increased in propotion to the thickness of the band gap change layer, the thickness of the band gap change layer is desirably lower than 100 (nm).

Accordingly, the invention can provide a semiconductor light emitting device in which the carriers can be smoothly moved between the two semiconductor layers having the different compositions without enhancing the impurity concentration, namely, without degrading the optical characteristics and reliability.

In the semiconductor light emitting device according to the invention, the band gap of the second semiconductor layer is preferably broader than that of the first semiconductor layer.

The band gap of the group-III nitride compound of the second semiconductor layer is formed broader than the band gap of the group-III nitride compound of the first semiconductor layer, which enables the carriers to be stabilized in the first semiconductor layer rather than in the second semiconductor layer from the viewpoint of energy. Accordingly, the carriers can be smoothly moved to the first semiconductor layer from the second semiconductor layer through the band gap change layer.

Accordingly, the invention can provide a semiconductor light emitting device in which the carriers can be smoothly moved between the two semiconductor layers having the different compositions without enhancing the impurity concentration, namely, without degrading the optical characteristics and reliability.

In a semiconductor light emitting device according to the invention, the depositing directions of the first semiconductor layer, the band gap change layer, and the second semiconductor layer are preferably parallel to c-axis directions of the group-III nitride compound crystals of the first semiconductor layer, the band gap change layer, and the second semiconductor layer.

Even if the crystals of the group-III nitride compounds in which the polarization charge emerges prominently are deposited while orientated toward the c-axis direction, the polarization charge can be decreased to smoothly perform the carrier transport from the first semiconductor layer to the second semiconductor layer by sequentially depositing the first semiconductor layer, the band gap change layer, and the second semiconductor layer.

Accordingly, the invention can provide a semiconductor light emitting device in which the carriers can be smoothly moved between the two semiconductor layers having the different compositions without enhancing the impurity concentration, namely, without degrading the optical characteristics and reliability.

In a semiconductor light emitting device according to the invention, preferably the first semiconductor layer functions as a light guide layer which guides the light emitted from the active layer, the light guide layer having relationship of x=0 and 0.95≦y≦1 in the composition formula, the second semiconductor layer functions as a cladding layer which supplies carriers to the active layer, the cladding layer having a relationship of x=m (0.05≦m≦0.1) and x+y=1 in the composition formula, a composition of the band gap change layer ranges within a relationship of 0≦x≦m and x+y=1 in the composition formula, and the semiconductor light emitting device functions as a semiconductor laser for the entire structure in which the first semiconductor layer, the band gap change layer, the second semiconductor layer, and the active layer are deposited.

The composition of the group-III nitride compound of the second semiconductor layer is set at the relationship of x=m (0.05≦m≦0.1) and x+y=1 in the composition formula, namely, at AlₘGa₁₋ₘN, and composition of the group-III nitride compound of the first semiconductor layer is set at the relationship of x=0 and y=1 in the composition formula, namely, at GaN. Therefore, the band gap of the second semiconductor layer becomes larger than that of the first semiconductor layer. Accordingly, the carriers can be smoothly moved to the first semiconductor layer from the second semiconductor layer through the band gap change layer, and the second semiconductor layer functions as the cladding layer which supplies the carriers.

The composition of the group-III nitride compound of the first semiconductor layer is set at the relationship of x=0 and 0.95≦y≦1 in the composition formula, namely, at the GaN or InGaN compound. Therefore, the refractive index is decreased, and the light emitted from the active layer is reflected by the first semiconductor layer. Because the first semiconductor layer which arranged on the p-type side and/or n-type side with respect to the active layer promotes the induced emission while guiding the light emitted from the active layer, the first semiconductor layer functions as the light guide layer.

Accordingly, the invention can provide a semiconductor light emitting device in which the carriers can be smoothly moved between the two semiconductor layers having the different compositions without enhancing the impurity concentration, namely, without degrading the optical characteristics and reliability and which functions as a semiconductor laser.

In a semiconductor light emitting device according to the invention, assuming that ρ (cm⁻²) is charge density of polarization generated at an interface where the group-III nitride compound of the first semiconductor layer and the group-III nitride compound of the second semiconductor layer are adjacent to each other and d (cm) is the thickness of the band gap change layer, an impurity concentration n (cm⁻³) of an impurity added into the band gap change layer is preferably in a range of 0.5ρ/d≦n≦3ρ/d.

In order to decrease the electrical resistance of the semiconductor light emitting device, the impurity is preferably added to the band gap change layer. On the other hand, when the impurity concentration becomes high, because the number of crystal defects is increased, the electrical resistance of the semiconductor light emitting device is increased, and the light quantity absorbed in the crystal defect is increased, and then the luminous efficiency of the semiconductor light emitting device is decreased. In the case where Mg is added as the impurity, the semiconductor light emitting device is degraded to decrease the reliability by the Mg diffusion. Accordingly, the impurity concentration of the band gap change layer exists preferably in the above range.

Accordingly, the invention can provide a semiconductor light emitting device in which the carriers can be smoothly moved between the two semiconductor layers having the different compositions without enhancing the impurity concentration, namely, without degrading the optical characteristics and reliability.

The first aspect or second aspect of the invention can provide a semiconductor device in which the carriers can be smoothly moved and thereby the electrical resistance becomes low in the mesa where the two semiconductor layers having the different compositions are deposited.

Any one of the third aspect to sixth aspect of the invention can provide a semiconductor light emitting device in which the carriers can be smoothly moved between the two semiconductor layers having the different compositions without enhancing the impurity concentration, namely, without degrading the optical characteristics and reliability.

### BRIEF DESCRIPTION OF THE DRAWINGS

FIG. 1 is a conceptual view showing a configuration of a semiconductor device 701 which is of an embodiment according to a first aspect of the invention;

FIG. 2 is a conceptual view showing a band diagram of the semiconductor device 701 which is of the embodiment according to the first aspect of the invention;

FIG. 3 is a conceptual view showing a configuration of a semiconductor device 703 which is of an embodiment according to a second aspect of the invention;

FIG. 4 is a conceptual view showing a band diagram of the semiconductor device 703 which is of the embodiment according to the second aspect of the invention;

FIG. 5 is a conceptual view showing a configuration of a semiconductor device 705 which is of another embodiment according to the first aspect of the invention;

FIG. 6 is a conceptual view showing a band diagram of the semiconductor device 705 which is of another embodiment according to the first aspect of the invention;

FIG. 7 is a conceptual view showing a configuration of a conventional semiconductor device 707;

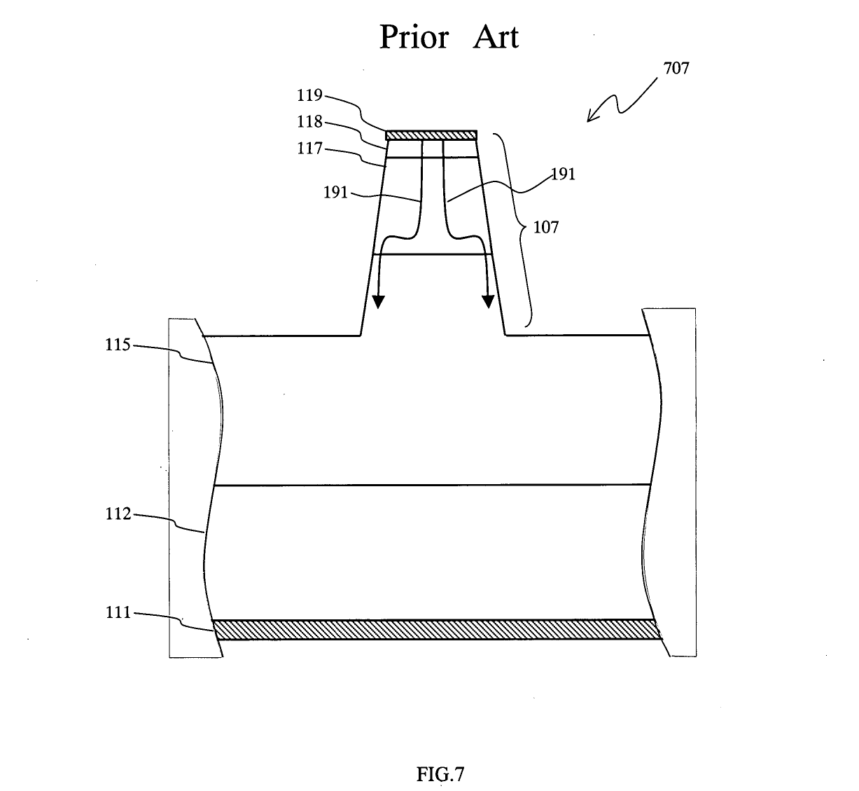

FIG. 8 is a conceptual view showing a cross section of a semiconductor light emitting device 801 which is of an embodiment according to a third aspect of the invention;

FIG. 9 is a conceptual view showing a band diagram of the semiconductor light emitting device 801 which is of the embodiment according to the third aspect of the invention;

FIG. 10 is a conceptual view showing a cross section of a semiconductor light emitting device 803 which is of another embodiment according to the third aspect of the invention;

FIG. 11 is a conceptual view showing a band diagram of the semiconductor light emitting device 803 which is of another embodiment according to the third aspect of the invention;

FIG. 12 is a conceptual view showing a cross section of a semiconductor light emitting device 805 which is of an embodiment according to a fourth aspect of the invention;

FIG. 13 is a conceptual view showing a band diagram of the semiconductor light emitting device 805 which is of the embodiment according to the fourth aspect of the invention;

FIG. 14 is a conceptual view showing a cross section of a semiconductor light emitting device 807 which is of an embodiment according to a fifth aspect of the invention;

FIG. 15 is a conceptual view showing a band diagram of the semiconductor light emitting device 807 which is of the embodiment according to the fifth aspect of the invention;

FIG. 16 is a conceptual view showing a cross section of a semiconductor light emitting device 809 which is of an embodiment according to a sixth aspect of the invention;

FIG. 17 is a conceptual view showing a band diagram of the semiconductor light emitting device 809 which is of the embodiment according to the sixth aspect of the invention;

FIG. 18 is a conceptual view showing a cross section of a semiconductor light emitting device 811 which is of another embodiment according to the third aspect of the invention;

FIG. 19 is a conceptual view showing a band diagram of the semiconductor light emitting device 811 which is of another embodiment according to the third aspect of the invention;

FIG. 20 is a conceptual view showing a cross section of a semiconductor light emitting device 813 which is of still another embodiment according to the third aspect of the invention; and

FIG. 21 is a conceptual view showing a cross section of a conventional semiconductor light emitting device 840.

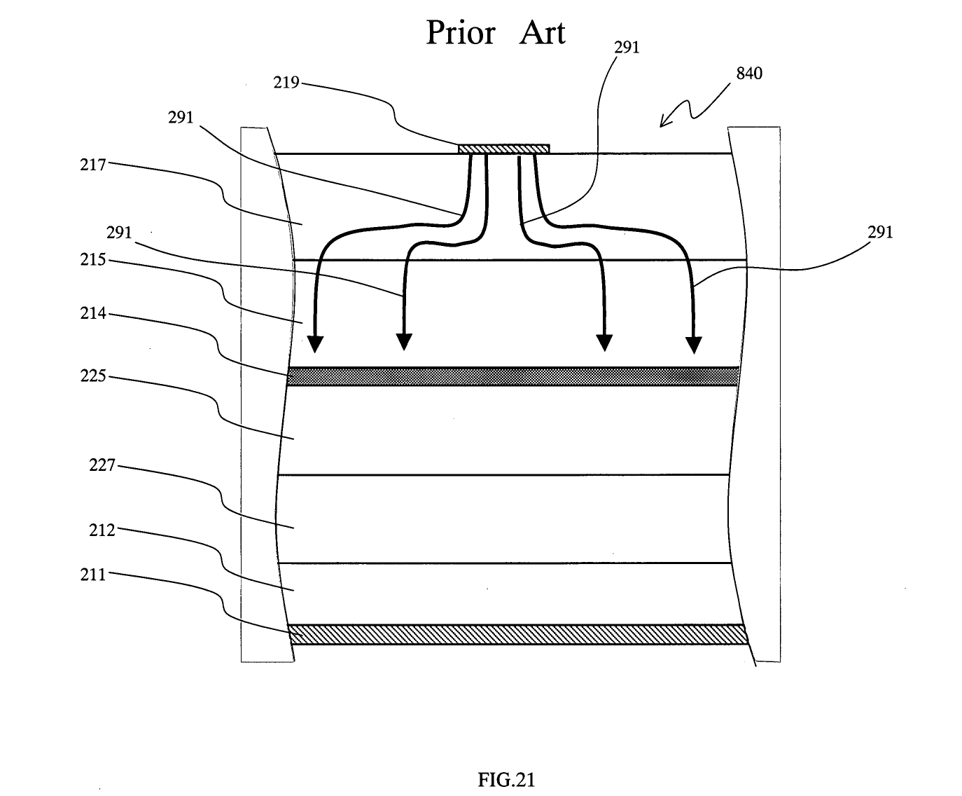

### DESCRIPTION OF THE PREFERRED EMBODIMENT

Preferred embodiments of the invention will be described below with reference to the drawings. The invention shall not be limited to the following embodiments.

### First Embodiment

A first embodiment is a semiconductor device including a first semiconductor layer which is deposited on a substrate, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the substrate, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1); and an electrode which is located on an opposite side to the band gap change layer of the second semiconductor layer, a voltage being applied to the electrode from the outside, wherein, in the depositing direction, the semiconductor device is formed in a mesa shape in a range of the electrode to the second semiconductor layer or to the first semiconductor layer, and in the depositing direction from the first semiconductor layer toward the second semiconductor layer, a band gap of the band gap change layer is continuously monotonously changed from a band gap which is substantially equal to that of the first semiconductor layer to a band gap which is substantially equal to that of the second semiconductor layer.

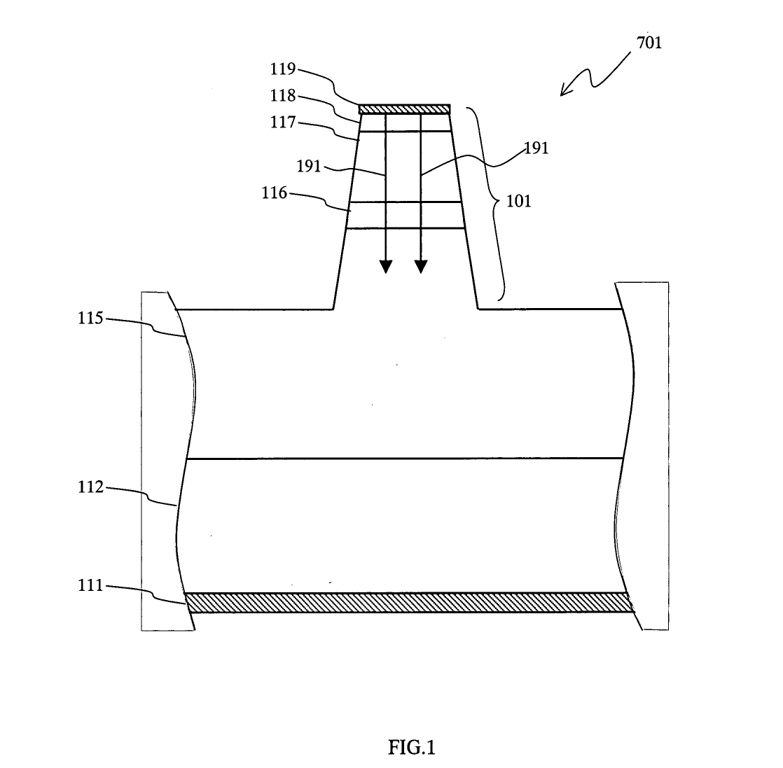

FIG. 1 is a conceptual view showing a configuration of a semiconductor device 701 which is of an embodiment according to a first aspect of the invention. The semiconductor device 701 includes an electrode 111, a substrate 112, a first semiconductor layer 115, a band gap change layer 116, a second semiconductor layer 117, a contact layer 118, and an electrode 119. In the semiconductor device 701, the semiconductor layers are deposited on the substrate 112.

In the depositing direction, the mesa shape may be formed in the range of the electrode 119 to the first semiconductor layer 115, in the range of the electrode 119 to a part of the first semiconductor layer 115, or in the range of the electrode 119 to the whole of the first semiconductor layer 115.

In the semiconductor device 701, a mesa 101 is made by forming the range of the electrode 119 to a part of the first semiconductor layer 115 in the mesa shape.

The electrode 111 and the electrode 119 are arranged in order to apply the voltage to the semiconductor device 701. It is desirable that the electrode 111 and the electrode 119 be made of a material which can come into ohmic contact with the semiconductor, because efficiency is lost as the semiconductor device when rectification is generated in bringing the electrode and the semiconductor into contact with each other. It is also desirable that the electrode 111 and the electrode 119 be made of a material having a small contact resistance with an interconnection of a device such as an external power supply. Therefore, it is preferable to form a structure in which a material which becomes a buffer is sandwiched between the material being in contact with the semiconductor and the material connected to the interconnection. Ti/Al/Ti/Au and Al/Au can be cited as an example of the electrode material being in contact with the n-type semiconductor. Ni/Au, Pd/Au, and Pt/Au can be cited as an example of the electrode material being in contact with the p-type semiconductor.

In order to decrease the contact resistance with the substrate 112, the electrode 111 is preferably deposited in the whole surface on the opposite side to the side on which the first semiconductor layer 115 of the substrate 112 is deposited (hereinafter “the opposite side to the side on which the first semiconductor layer 115 of the substrate 112 is deposited” is abbreviated to as “backside of substrate 112”).

The substrate 112 physically supports the semiconductor device 701. A material on which a semiconductor thin film is well grown is selected as the substrate of the semiconductor device 701. In the case where a thin film which is made of the group-III nitride compound expressed by a composition formula of AlₓGa_{y}In_{1-x-y}N (0≦x≦1, 0≦y≦1, 0≦x+y≦1) (hereinafter “the group-III nitride compound expressed by the composition formula of AlₓGa_{y}In_{1-x-y}N (0≦x≦1, 0≦y≦1, 0≦x+y≦1)” is abbreviated to “AlₓGa_{y}In_{1-x-y}N compound”) is deposited, sapphire (Al₂O₃), gallium nitride (GaN), and silicon carbide (SiC) can be cited as an example of the substrate.

The second semiconductor layer 117 is a semiconductor layer made of an AlₓGa_{y}In_{1-x-y}N compound. An example of the second semiconductor layer 117 includes the group-III nitride compound having relationships of x=m (0.01≦m≦0.15, preferably 0.05≦m≦0.10) and x+y=1 in the composition formula, namely, the group-III nitride compound in which the composition formula is expressed as AlₘGa₁₋ₘN (hereinafter “the group-III nitride compound in which the composition formula is expressed as AlₘGa₁₋ₘN” is abbreviated to “AlₘGa₁₋ₘN compound”). The second semiconductor layer 117 is preferably p-type. When the second semiconductor layer 117 is a p-type semiconductor, a p-type impurity is added in order to enhance carrier density. Mg can be cited as an example of the impurity added to the second semiconductor layer 117, and an example of an impurity concentration ranges from 5×10¹⁸ (cm⁻³) to 1×10²⁰ (cm⁻³). Preferably a thickness of the second semiconductor layer 117 ranges from 100 (nm) to 2000 (nm), and more preferably the thickness ranges from 200 (nm) to 500 (nm).

The first semiconductor layer 115 is a semiconductor layer made of an AlₓGa_{y}In_{1-x-y}N compound. A band gap of the first semiconductor layer 115 is preferably narrower than that of the second semiconductor layer 117. Specifically, an example of the first semiconductor layer 115 includes the group-III nitride compound having relationships of x=0 and y=1 in the composition formula, namely, the group-III nitride compound in which the composition formula is expressed as GaN (hereinafter “the group-III nitride compound in which the composition formula is expressed as GaN” is abbreviated to “GaN compound”). The composition of the first semiconductor layer 115 may be set at x=0 and 0.95≦y≦1 in the composition formula, namely, the first semiconductor layer 115 may be made of the GaInN compound. Preferably the thickness of the first semiconductor layer 115 ranges from 20 (nm) to 200 (nm), and more preferably the thickness ranges from 50 (nm) to 150 (nm). When the second semiconductor layer 117 is made of a p-type semiconductor, no impurity is added to the first semiconductor layer 115, or the first semiconductor layer 115 is designed such that the impurity concentration is lower than the p-type impurity concentration added to the second semiconductor layer 117.

The band gap change layer 116 is an AlₓGa_{y}In_{1-x-y}N compound layer in which the composition is continuously monotonously changed in the depositing direction. That is, in the composition in the depositing direction of the band gap change layer 116, values of x and y in the composition formula are continuously monotonously changed from one side of the band gap change layer 116 to the other side. For example, in the depositing direction of the band gap change layer 116, one side of the band gap change layer 116 is the GaN compound in which x=0 and y=1 in the composition formula, the other side of the band gap change layer 116 is the Al_{0.08}Ga_{0.92}N compound in which x=0.08 and y=0.92 in the composition formula, and the value of x is continuously monotonously changed from 0 to 0.08 from one side toward the other side in the composition formula while the value of y is continuously monotonously changed from 1 to 0.92 with the relationship of x+y=1 maintained. Since the composition of the band gap change layer 116 is continuously monotonously changed, the polarization charge can be decreased in the band gap change layer 116.

Preferably the thickness of the band gap change layer 116 is 3 (nm) or more and less than 100 (nm), and more preferably the thickness ranges from 3 (nm) to 50 (nm).

When the second semiconductor layer 117 is made of a p-type semiconductor, the p-type impurity, e.g., Mg may be added into the band gap change layer 116 in order to form the band gap change layer 116 into the p-type semiconductor. For example, the impurity concentration can range from 1×10¹⁸ (cm⁻³) to 1×10¹⁹ (cm⁻³).

Assuming that ρ (cm⁻²) is charge density of the polarization generated at the interface where the group-III nitride compound of the first semiconductor layer and the group-III nitride compound of the second semiconductor layer are adjacent to each other and d (cm) is the thickness of the band gap change layer, an impurity concentration n (cm⁻³) of the impurity added into the band gap change layer is preferably set in the range of Formula 1, namely, the impurity concentration n is preferably set in the range of 50% to 300% of a quotient in which the charge density ρ is divided by the thickness d of the band gap change layer.
0.5×ρ/d≦n≦3×ρ/d [Formula 1]

Preferably the impurity concentration n is set in the range of Formula 2, and more preferably the impurity concentration n is set in the range of Formula 3.
0.8×ρ/d≦n≦2×ρ/d [Formula 2]
0.95×ρ/d≦n≦1.05×ρ/d [Formula 3]

The impurity concentration of the band gap change layer arranged between the GaN compound and the Al_{0.08}Ga_{0.92}N compound will be illustrated below. The polarization charge density generated at the interface between the GaN compound and the Al_{0.08}Ga_{0.92}N compound is ρ=3×10¹² (cm⁻²). When the thickness of the band gap change layer is set at 10 (nm), the impurity concentration n of the impurity added into the band gap change layer preferably ranges from 1.5×10¹⁸ (cm⁻³) to 9×10¹⁸ (cm⁻³).

The contact layer 118 is a semiconductor layer which is in ohmic contact with the electrode 119. The GaN compound whose thickness ranges from 10 (nm) to 100 (nm) can be cited as an example of the contact layer 118. The impurity may be added to the contact layer 118 in order to suppress the electrical resistance to a lower level. In the case where the contact layer 118 is made of the GaN compound while the second semiconductor layer 117 is made of the p-type semiconductor, Mg can be cited as an example of the added p-type impurity.

Each of the semiconductor layers in the semiconductor device 701 is deposited by utilizing a metal organic chemical vapor deposition method (hereinafter “metal organic chemical vapor deposition” is abbreviated to “MOCVD method”). The MOCVD method is one in which reactant gas is introduced to a reactor (chamber) and the reactant gas is thermally decomposed and reacted to perform the epitaxial growth of the thin film on the substrate whose temperature is kept in the range of 600° C. to 1100° C. The semiconductor layers having the different compositions or different thicknesses can easily be deposited by controlling production parameters such as a flow rate and a concentration of the reactant gas, reaction temperature and time, and a kind of diluent gas.

In the case where the first semiconductor layer 115, the band gap change layer 116, the second semiconductor layer 117, and the contact layer 118 are formed by AlₓGa_{y}In_{1-x-y}N compound thin films, vapor in which bubbling is performed with hydrogen or nitrogen which is of the carrier gas to group III elements of Ga(CH₃)₃ (trimethyl gallium, hereinafter abbreviated to “TMG”), In(C₂H₅)₃ (triethyl indium, hereinafter abbreviated to “TMI”), and Al(CH₃)₃ (trimethyl aluminium, hereinafter abbreviated to “TMA”) is used as source gas, and an ammonia vapor is used in order to make the nitride in the MOCVD method. For the impurity, CP₂Mg (cyclopentadienyl magnesium) which is of a p-type dopant can be used as the source gas, or SiH₄ (silane) which is of an n-type dopant can be used as the source gas. The source gas is introduced into the chamber along with the carrier gas of hydrogen or nitrogen. In the MOCVD method, the desired AlₓGa_{y}In_{1-x-y}N compound can be grown by setting a ratio of the mixed gas in which CP₂Mg or SiH₄, TMG, TMI, TMA, and ammonia are mixed together, the flow rate of the mixed gas, and the substrate temperature as the production parameters. In the MOCVD method, the thickness of the AlₓGa_{y}In_{1-x-y}N compound can be controlled by the reaction time. The AlₓGa_{y}In_{1-x-y}N compounds having the different compositions can continuously be deposited by sequentially changing the production parameters.

In the semiconductor device 701, the first semiconductor layer 115, the band gap change layer 116, the second semiconductor layer 117, and the contact layer 118 are sequentially deposited on the substrate 112. One or more semiconductor layers may be deposited between the substrate 112 and the first semiconductor layer 115.

Specifically the semiconductor device 701 is produced as follows. The substrate 112 is placed in the chamber, and the temperature of the substrate 112 is raised to an extend ranging from 600 to 1100° C. while the carrier gas is substituted for the inside of the chamber.

Then, the mixed gas (mixed gas G) of TMG, TMI, TMA, ammonia, and CP₂Mg having the mixture ratio in which the first semiconductor layer 115 is grown is introduced to perform the reaction on the substrate 112 for a predetermined time. The first semiconductor layer 115 is deposited by the reaction. For example, in the case where the first semiconductor layer 115 is made of the non-doped GaN compound, the mixed gas G of TMG and ammonia is used.

Then, the band gap change layer 116 is deposited on the first semiconductor layer 115. The reaction gas for depositing the band gap change layer 116 will be described later.

Then, the mixed gas (mixed gas H) of TMG, TMI, TMA, ammonia, and CP₂Mg having the mixture ratio in which the second semiconductor layer 117 is grown is introduced to perform the reaction on the band gap change layer 116 for a predetermined time. The second semiconductor layer 117 is deposited on the band gap change layer 116 by the reaction. For example, in the case where the second semiconductor layer 117 is made of the p-type Al_{0.08}Ga_{0.92}N compound, the mixed gas H of TMG, TMA, ammonia, and CP₂Mg is used.

In the growth of the band gap change layer 116, the mixed gas is reacted while the mixture ratio of the mixed gas introduced into the chamber is continuously monotonously changed from the ratio of the mixed gas G to the ratio of the mixed gas H. In the depositing direction, the composition of the band gap change j layer 116 deposited by the reaction is continuously monotonously changed from the composition of the first semiconductor layer 115 to the composition of the second semiconductor layer 117. Accordingly, the band gap change layer 116 becomes a semiconductor layer in which the band gap is not steeply changed. The p-type band gap change layer 116 can be formed by adding CP₂Mg to the mixed gas.

After the second semiconductor layer 117 is deposited, the mixed gas (mixed gas I) of TMG, ammonia, and CP₂Mg having the mixture ratio in which the contact layer 118 is grown is introduced to perform the reaction on the second semiconductor layer 117 for a predetermined time. The contact layer is deposited by the reaction.

A molecular beam epitaxial growth method (MBE method) may be adopted for the method of growing the group-III nitride compound on the substrate 112.

After the contact layer 118 is deposited, the material of the electrode 119 is deposited on the contact layer 118, and the material of the electrode 111 is deposited on the backside of the substrate 112. A sputtering method or a vacuum evaporation method can be adopted for the method of depositing the electrode.

The mesa 101 is formed after the materials of the electrodes are deposited. The following means can be cited as an example of means for forming the mesa 101. After the material of the electrode 119 is deposited, a stripe-shape resist pattern is formed on the material of the electrode 119 by a photolithography technique. Then, dry etching is performed in the depositing direction up to the desired position of the second semiconductor layer 117 or first semiconductor layer 115 from a part of the material of the electrode 119 which is exposed with no resist pattern. Then, the resist pattern is removed to complete the mesa 101. Since the etching is performed to the second semiconductor layer 117 or a part of the thickness of first semiconductor layer 115, an end point, i.e., a height of the mesa 101 is controlled by an etching time.

In the case where the composition on one side of the band gap change layer 116 is equalized to that of the first semiconductor layer 115 while the composition on the other side is equalized to that of the second semiconductor layer 117, the band gap change layer 116 is deposited such that one side of the band gap change layer 116 is adjacent to the first semiconductor layer 115 while the other side is adjacent to the second semiconductor layer 117. Since the composition is continuously monotonously changed from the first semiconductor layer 115 to the second semiconductor layer 117, the band gap is also continuously monotonously changed from the first semiconductor layer 115 to the second semiconductor layer 117. For example, in the case where the first semiconductor layer 115 is made of the GaN compound while the second semiconductor layer 117 is made of the Al_{0.08}Ga_{0.92}N compound, the composition on one side of the band gap change layer 116 is set to GaN while the composition on the other side is set to Al_{0.08}Ga_{0.92}N, which eliminates the steep composition change between the first semiconductor layer 115 and the band gap change layer 116 and between the band gap change layer 116 and the second semiconductor layer 117 to continuously monotonously change the composition from the first semiconductor layer 115 to the second semiconductor layer 117.

Accordingly, the polarization charge obstructing the carrier transport can be dispersed, and the carriers can be smoothly moved near the center portion of the mesa 101 from the second semiconductor layer 117 to the first semiconductor layer 115 or from the first semiconductor layer 115 to the second semiconductor layer 117. For example, in the case where the second semiconductor layer 117 is made of a p-type semiconductor, the holes can be smoothly moved near the center portion of the mesa 101 from the second semiconductor layer 117 to the first semiconductor layer 115.

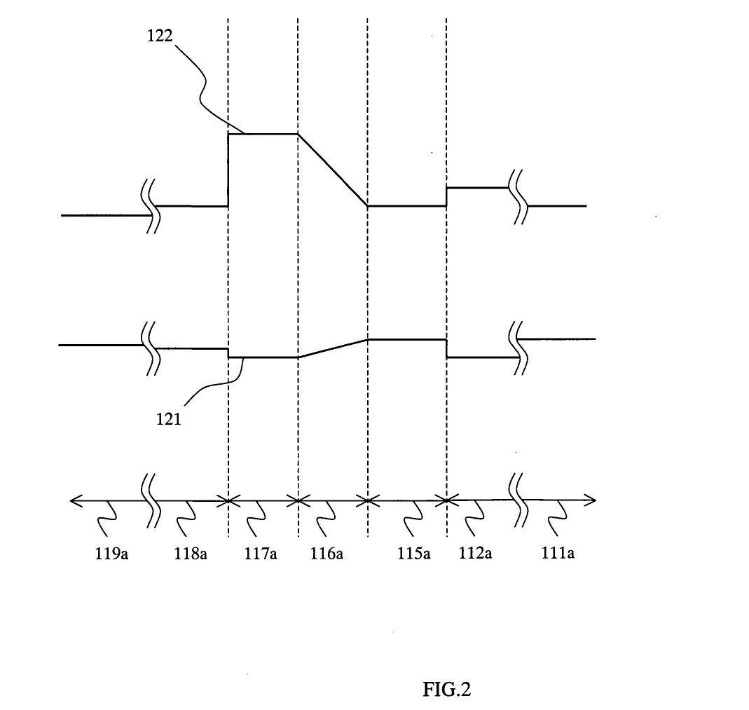

FIG. 2 is a conceptual view showing a band diagram of the semiconductor device 701. In FIG. 2, the numeral 111a designates a band gap in a region of the electrode 111, the numeral 112a designates a band gap in a region of the substrate 112, the numeral 115a designates a band gap in a region of the first semiconductor layer 115, the numeral 116a designates a band gap in a region of the band gap change layer 116, the numeral 117a designates a band gap in a region of the second semiconductor layer 117, the numeral 118a designates a band gap in a region of the contact layer 118, and the numeral 119a designates a band gap in a region of the electrode 119. The numeral 121 designates a top level of a valence band, and the numeral 122 designates a bottom level of a conduction band. In FIG. 2, parts of the band gaps are omitted in the range of the electrode 111 to the substrate 112 and in the range of the contact layer 118 to the electrode 119. In the following description, the second semiconductor layer 117 and the contact layer 118 are made of the p-type semiconductor.

The holes injected from the electrode 119 can be smoothly moved toward the direction of the substrate 112 through the p-type contact layer 118 and second semiconductor layer 117 in which the holes are the majority carrier. The band gap of the first semiconductor layer 115 is narrower than that of the second semiconductor layer 117, and the top level 121 of the valence band of the first semiconductor layer 115 and the top level 121 of the valence band of the second semiconductor layer 117 are gently connected to each other with the band gap change layer 116, which allows the holes to be moved along the top level 121 of the valence band to the first semiconductor layer 115 which is stabilized from the viewpoint of energy.

Because the band gap change layer 116 of the mesa 101 makes the hole transport smooth between the second semiconductor layer 117 and the first semiconductor layer 115, the holes of the semiconductor device 701 can be moved near the center portion of the mesa 101 having the good crystallinity as shown by carrier flows 191 of FIG. 1, and the electrical resistance can be decreased in the mesa 101.

That is, in the mesa, the band gap change layer is arranged between the second semiconductor layer and the first semiconductor layer, which allows the carriers to be smoothly moved through the center portion of the mesa having the good crystallinity.

Accordingly, the first aspect of the invention can provide a semiconductor device in which the carriers can be smoothly moved and thereby the electrical resistance becomes low in the mesa where the first semiconductor layer 115 and second semiconductor layer 117 having the different compositions are deposited.

Because the electrical resistance is low, a built-in voltage is low, and a drive voltage applied to the semiconductor device 701 can be decreased.

The reaction between the carriers and the passivation material with which the mesa 101 is covered can be decreased by decreasing the number of carriers moved in the neighborhood of the side wall of the mesa 101, and the reliability of the semiconductor device 701 can be improved.

The polarization charge emerges prominently, when the crystals of the two group-III nitride compounds having the different compositions are deposited while orientated in the c-axis direction. Therefore, the effect of the band gap change layer 116, namely, the effect of the dispersion of the polarization charge becomes maximum, in the case where the depositing directions of the first semiconductor layer 115, the band gap change layer 116, and the second semiconductor layer 117 are parallel to the c-axis directions of the group-III nitride compound crystals of the first semiconductor layer 115, the band gap change layer 116, and the second semiconductor layer 117.

Accordingly, the first aspect of the invention can provide a semiconductor device in which the carriers can be smoothly moved and thereby the electrical resistance becomes low in the mesa where crystals of the first semiconductor layer 115 and second semiconductor layer 117 having the different compositions are deposited while orientated in the c-axis direction.

### Second Embodiment

A second embodiment is a semiconductor device including a first semiconductor layer which is deposited on a substrate, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the substrate, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1); and an electrode which is located on an opposite side to the band gap change layer of the second semiconductor layer, a voltage being applied to the electrode from the outside, wherein, in the depositing direction, the semiconductor device is formed in a mesa shape in a range of the electrode to the second semiconductor layer or the first semiconductor layer, and, in the depositing direction from the first semiconductor layer toward the second semiconductor layer, a band gap of the band gap change layer is monotonously changed in the stepwise manner from a band gap which is substantially equal to that of the first semiconductor layer to a band gap which is substantially equal to that of the second semiconductor layer.

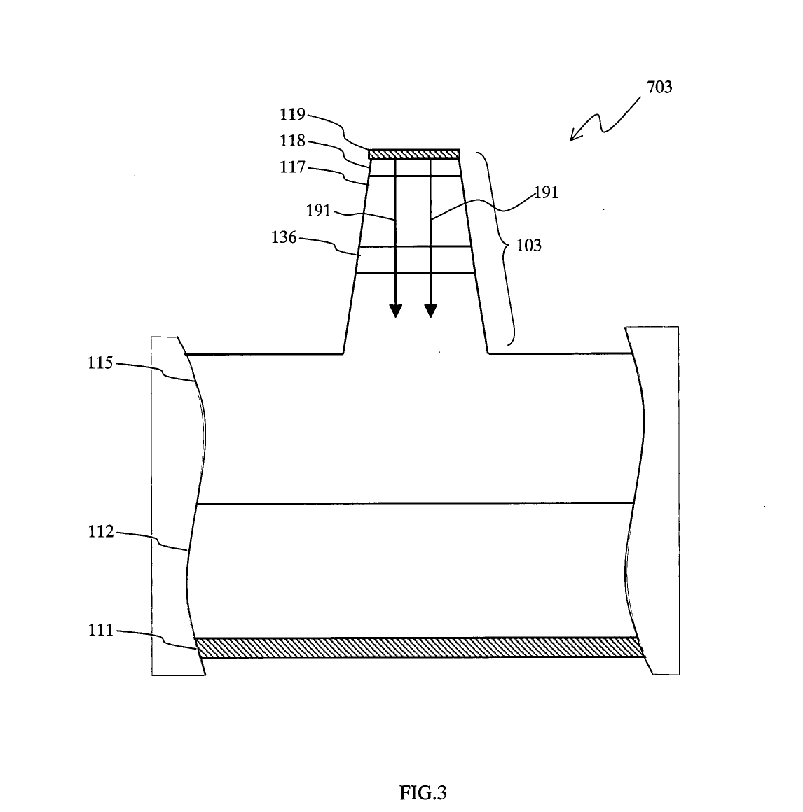

FIG. 3 is a conceptual view showing a configuration of a semiconductor device 703 which is of an embodiment according to a second aspect of the invention. The semiconductor device 703 includes the electrode 111, the substrate 112, the first semiconductor layer 115, a band gap change layer 136, the second semiconductor layer 117, and the electrode 119. In the semiconductor device 703, the semiconductor layers are deposited on the substrate 112.

In the depositing direction, the mesa shape may be formed in the range of the electrode to the first semiconductor layer, in the range of the electrode to a part of the first semiconductor layer, or in the range of the electrode to the whole of the first semiconductor layer.

In the semiconductor device 703, a mesa 103 is made by forming the range of the electrode 119 to a part of the first semiconductor layer 115 in the mesa shape.

In FIG. 3, the constituent designated by the same numeral as that used in FIG. 1 has the same semiconductor film and the same function. The semiconductor device 703 differs from the semiconductor device 701 of FIG. 1 in that not the band gap change layer 116 but the band gap change layer 136 is arranged between the first semiconductor layer 115 and the second semiconductor layer 117.

Similarly to the semiconductor device 701, one or more semiconductor layers may be deposited between the substrate 112 and the first semiconductor layer 115.

The band gap change layer 136 is an AlₓGa_{y}In_{1-x-y}N compound layer in which the composition is monotonously changed in the depositing direction in a stepwise manner. That is, in the composition of the band gap change layer 136, the values of x and y in the composition formula are monotonously changed in the stepwise manner from one side of the band gap change layer 136 to the other side. Specifically, the band gap change layer 136 includes the plural AlₓGa_{y}In_{1-x-y}N compound thin films which are deposited in the order of the wider band gap or in the order of the narrower band gap. For example, the band gap change layer 136 sequentially includes the GaN compound thin film, the Al_{0.02}Ga_{0.98}N compound thin film, the Al_{0.04}Ga_{0.96}N compound thin film, the Al_{0.06}Ga_{0.94}N compound thin film, and the Al_{0.08}Ga_{0.92}N compound thin film whose thickness are 10 nm from one side of the band gap change layer 136 to the other side in the depositing direction. The band gap of the band gap change layer 136 is monotonously changed in the stepwise manner from one side toward the other side, namely, from the narrowest band gap of the GaN compound thin film to the broadest band gap of the Al_{0.08}Ga_{0.92}N compound thin film. The composition of the compound thin film may unevenly be changed, and the thickness of the compound thin film may be uneven. Since the composition of the band gap change layer 136 is monotonously changed in the stepwise manner, the polarization charge can be decreased in the band gap change layer 136.

Preferably the thickness of the band gap change layer 136 is 3 (nm) or more and less than 100 (nm), and more preferably the thickness ranges from 3 (nm) to 50 (nm).

When the second semiconductor layer 117 is made of a p-type semiconductor, in order to form the band gap change layer 136 into the p-type semiconductor, the p-type impurity may be added to the band gap change layer 136 in the impurity concentration range described in the band gap change layer 116 of FIG. 1. Specifically, Mg can be cited as an example of the p-type impurity, and the impurity concentration ranges from 1×10¹⁸ (cm⁻³) to 1×10¹⁹ (cm⁻³) by way of example. As described in the band gap change layer 116 of FIG. 1, the impurity concentration range of the band gap change layer 136 is preferably computed from the charge density of the polarization generated at the interface between the first semiconductor layer 115 and the second semiconductor layer 117 and the thickness of the band gap change layer 136.

The semiconductor device 703 is produced as follows. The first semiconductor layer 115, the band gap change layer 136, the second semiconductor layer 117, and the contact layer 118 are sequentially deposited on the substrate 112 using the MOCVD method described in the first embodiment. In the production of the band gap change layer 136, the production parameters described in the first embodiment are changed to deposit the band gap change layer 136 in the stepwise manner in each predetermined time. Then, as described in the semiconductor device 701 of FIG. 1, the electrode 111 and the electrode 119 are deposited by the sputtering method or the vacuum evaporation method, the mesa 103 is formed by utilizing the lithography and the dry etching, and the semiconductor device 703 is produced.

The composition on one side of the band gap change layer 136 is equalized to that of the first semiconductor layer 115 while the composition on the other side is equalized to that of the second semiconductor layer 117, which obtains the same effect as that of the band gap change layer 116 of FIG. 1. That is, the band gap change layer 136 is deposited such that one side of the band gap change layer 136 is adjacent to the first semiconductor layer 115 while the other side is adjacent to the second semiconductor layer 117, which eliminates the steep change in composition between the first semiconductor layer 115 and the band gap change layer 136 and between the second semiconductor layer 117 and the band gap change layer 136. Accordingly, the polarization charge obstructing the carrier transport can be dispersed, and the carriers can be smoothly moved near the center portion of the mesa 103 from the second semiconductor layer 117 to the first semiconductor layer 115. For example, in the case where the second semiconductor layer 117 is made of a p-type semiconductor, the holes can be smoothly moved near the center portion of the mesa 103 from the second semiconductor layer 117 to the first semiconductor layer 115.

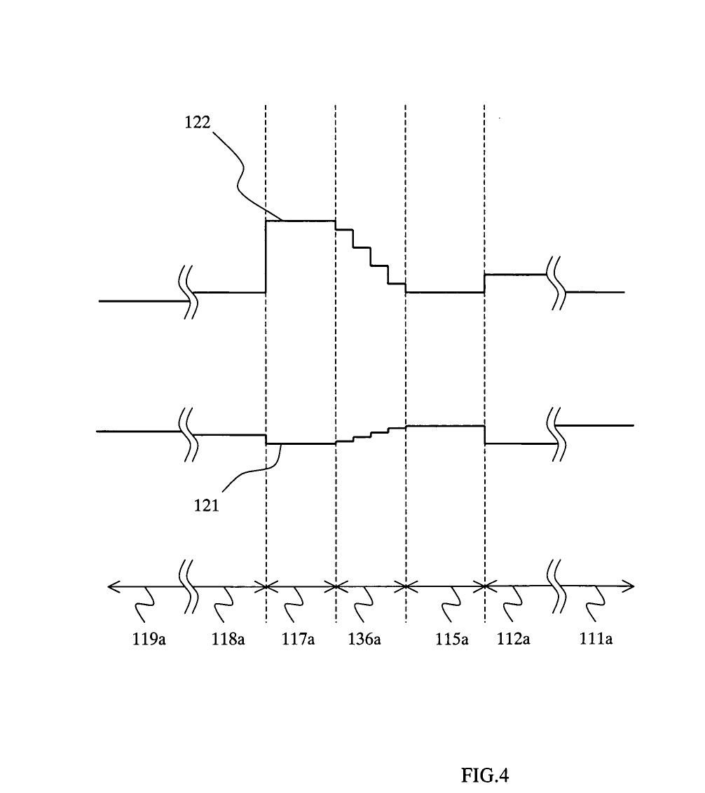

FIG. 4 is a conceptual view showing a band diagram of the semiconductor device 703. In FIG. 4, the same numeral as that used in FIG. 2 designates the same region of the deposited film having the same function. The band diagram of the semiconductor device 703 of FIG. 4 differs from the band diagram of the semiconductor device 701 of FIG. 2 in that the region 116a of the band gap change layer 116 does not exist between the region 115a of the first semiconductor layer 115 and the region 117a of the second semiconductor layer 117 but the region 136a of the band gap change layer 136 is displayed. In FIG. 4, parts of the band gaps are not shown in the range of the contact layer 118 to the electrode 119 and in the range of the substrate 112 to the electrode 111. In the following description, the second semiconductor layer 117 and the contact layer 118 are made of the p-type semiconductor.

As described in the band diagram of the semiconductor device 701 of FIG. 2, the holes injected from the electrode 119 are moved to the second semiconductor layer 117.

The top level 121 of the valence band of the first semiconductor layer 115 and the top level 121 of the valence band of the second semiconductor layer 117 are connected to each other in the stepwise manner by the band gap change layer 136, which allows the holes to be moved along the top level 121 of the valence band to the first semiconductor layer 115 which is stabilized from the viewpoint of energy.

Because the band gap change layer 136 of the mesa 103 makes the hole transport smooth between the second semiconductor layer 117 and the first semiconductor layer 115, the holes of the semiconductor device 703 can be moved near the center portion of the mesa 103 having the good crystallinity as shown by the carrier flows 191 of FIG. 3, and the electrical resistance can be decreased in the mesa 103.

That is, in the mesa, the band gap change layer is arranged between the second semiconductor layer and the first semiconductor layer, which allows the carriers to smoothly be moved in the center portion of the mesa having the good crystallinity.

Accordingly, the second aspect of the invention can provide a semiconductor device in which the carriers can be smoothly moved and thereby the electrical resistance becomes low in the mesa where the first semiconductor layer 115 and second semiconductor layer 117 having the different compositions are deposited.

Similarly to the semiconductor device 701, the semiconductor device 703 can obtain the effects of the decrease in drive voltage and the improvement of the reliability.

Similarly to the semiconductor device 701, in the semiconductor device 703, the effect of the band gap change layer 136, namely, the effect of the dispersion of the polarization charge becomes maximum, in the case where the first semiconductor layer 115, the band gap change layer 136, and the second semiconductor layer 117 are deposited while the c-axis of the crystals are orientated.

Accordingly, the second aspect of the invention can provide a semiconductor device in which the carriers can be smoothly moved and thereby the electrical resistance becomes low in the mesa where group-III nitride compound crystals having the different compositions are deposited while orientated in the c-axis direction.

### Third Embodiment

Preferably the semiconductor device according to the first and second aspects of the invention further includes an active layer between the substrate and the first semiconductor layer, the active layer emitting light by recombination of an electron and a hole, wherein the first semiconductor layer functions as a light guide layer which guides the light emitted from the active layer, the light guide layer having relationship of x=0 and 0.95≦y≦1 in the composition formula, the second semiconductor layer functions as a cladding layer which supplies carriers to the active layer, the cladding layer having a relationship of x=m (0.05≦m≦0.1) and x+y=1 in the composition formula, a composition of the band gap change layer ranges within a relationship of 0≦x≦m and x+y=1 in the composition formula, and the semiconductor device functions as a semiconductor laser for the entire structure in which the first semiconductor layer, the band gap change layer, the second semiconductor layer, and the active layer are deposited.

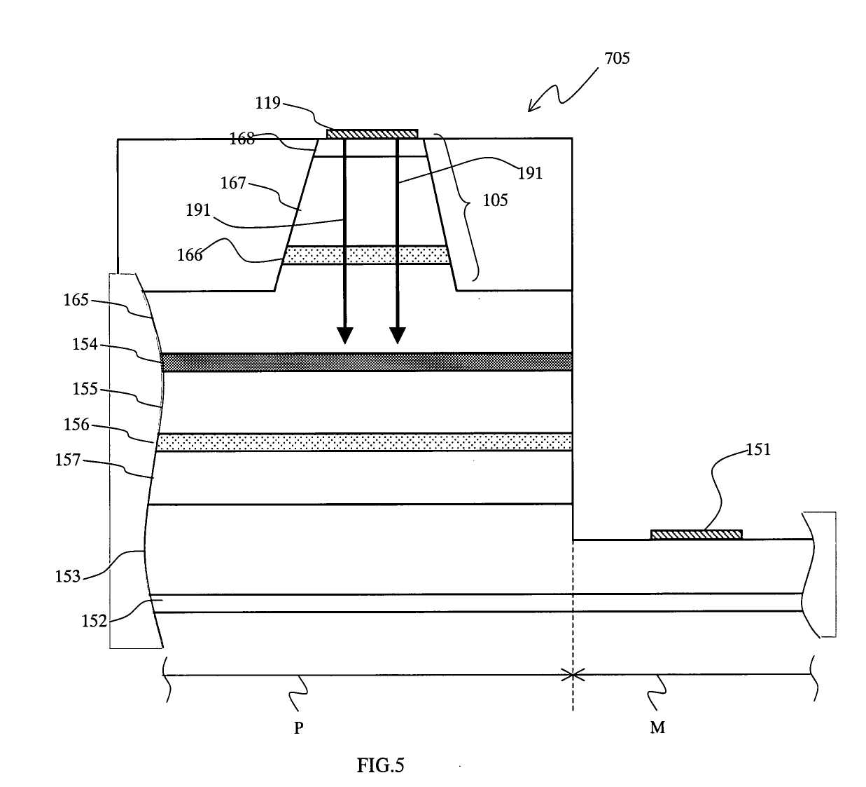

FIG. 5 is a conceptual view showing a configuration of a semiconductor device 705 which is of another embodiment according to the first aspect of the invention. The semiconductor device 705 includes an electrode 151, an n-type substrate 152, an n-type underlying layer 153, an n-type second semiconductor layer 157, an n-side band gap change layer 156, an n-side first semiconductor layer 155, an active layer 154, a p-side first semiconductor layer 165, a p-side band gap change layer 166, a p-type second semiconductor layer 167, a p-type contact layer 168, and an electrode 119. In FIG. 5, the same numerals 119 and 191 as those used in FIG. 1 designate the same electrode and carrier flow respectively. The semiconductor device 705 functions as the semiconductor laser.

The substrate 152 physically supports the semiconductor device 705. A material on which a semiconductor thin film is well grown is selected as the substrate of the semiconductor device 705. In the case where the AlₓGa_{y}In_{1-x-y}N compound is deposited, sapphire can be cited as an example of the substrate.

The n-type underlying layer 153 can improve the crystallinity of the n-type second semiconductor layer 157. For example, the GaN compound including the impurity of Si can be cited as an example of the n-type underlying layer 153. Si is added to the GaN compound having the thickness ranging from 1 μm to 5 μm as the impurity to form the n-type GaN compound. For example, the impurity concentration ranges from 5×10¹⁷ (cm⁻³) to 1×10¹⁹ (cm⁻³).

The electrode 151 functions as an anode which applies the voltage to the semiconductor device 705. Similarly to the electrode 111 of FIG. 1, Ti/Al/Ti/Au and Al/Au can be cited as an example of a material of the electrode 151.

The active layer 154 is a layer which emits the light by recombination of the electron and the hole. A wavelength of the emitting light is determined by the band gap of the material used for the active layer 154. A direct transition type semiconductor having high luminous efficiency is preferably used as the material used for the active layer 154. The wide varieties of band gap can be made by the composition change using the AlₓGa_{y}In_{1-x-y}N compound thin film, and the semiconductor light emitting device having the desired wavelength can be produced. At least two kinds of the semiconductor thin films having the different band gaps are alternately arranged, which allows the active layer 154 to have a multiple quantum well (MQW) structure in which the semiconductor thin film having the broader band gap is set at a barrier while the semiconductor thin film having the narrower band gap is set at a quantum well. The active layer 154 can efficiently emit the light by forming the active layer 154 into the MQW. In the case of the MQW, the wavelength of the emitting light is determined by the band gap of the quantum well. The both ends of MQW may be formed by the semiconductor thin films which become the barrier, and both ends of the MQW may be formed by the semiconductor thin films which become the quantum well. For example, the group-III nitride compound thin film in which x=0 and y=q (0.95≦q≦1, preferably 0.97≦q≦1) in the composition formula, namely, the group-III nitride compound thin film whose composition formula is expressed by Ga_{q}In_{1-q}N can be cited as an example of the semiconductor thin film which becomes the barrier. The group-III nitride compound thin film in which x=0 and y=p (p<q and 0.80≦p≦0.95, preferably 0.85≦p≦0.9) in the composition formula, namely, the group-III nitride compound thin film whose composition formula is expressed by GaₚIn₁₋ₚN can be cited as an example of the semiconductor thin film which becomes the quantum well. In the following description, “the group-III nitride compound whose composition formula is expressed by Ga_{q}In_{1-q}N” is abbreviated to “Ga_{q}In_{1-q}N compound,” and “the group-III nitride compound whose composition formula is expressed by GaₚIn₁₋ₚN” is abbreviated to “GaₚIn₁₋ₚN compound.”

Preferably the thickness of the semiconductor thin film which becomes the barrier ranges from 5 (nm) to 20 (nm), and more preferably the thickness ranges from 7 (nm) to 15 (nm).

Preferably the thickness of the semiconductor thin film which becomes the quantum well ranges from 1 (nm) to 10 (nm), and more preferably the thickness ranges from 3 (nm) to 5 (nm).

In the thicknesses of the active layer 154, the thickness of the MQW (the total of thicknesses of the semiconductor thin film which becomes the barrier and the semiconductor thin film which becomes the quantum well) preferably ranges from 380 (nm) to 480 (nm).

The electron barrier layer made of an AlₓGa_{y}In_{1-x-y}N compound may be arranged at the end of the MQW on the p-type side with respect to the MQW. The electron barrier layer prevents a phenomenon of carrier overflow, in which the electrons receiving the thermal energy by generating the heat associated with the light emission of the semiconductor device overcome the barrier of the quantum well and are moved to the semiconductor layer on the p-type side. Because the electron barrier layer has the wide band gap and the high bottom level of the conduction band, even the electron which obtains the thermal energy cannot be moved to the semiconductor layer on the p-type side through the electron barrier layer. For example, the group-III nitride compound thin film in which x=s and x+y=1 (0.1≦s≦0.3, preferably 0.15≦s≦0.25) in the composition formula, namely, the group-III nitride compound thin film whose composition formula is expressed by AlₛGa₁₋ₛN (hereinafter “group-III nitride compound thin film whose composition formula is expressed by AlₛGa₁₋ₛN” is abbreviated to “AlₛGa₁₋ₛN compound”) can be cited as an example of the electron barrier layer. For example, the thickness of the electron barrier layer ranges from 10 (nm) to 30 (nm), and preferably the thickness ranges from 15 (nm) to 25 (nm). In the p-type semiconductor layer, because the carrier overflow electron becomes the ineffective carrier which does not engages in the light emission, and then the luminous efficiency of the semiconductor device is decreased, the active layer 154 can decrease the number of ineffective carriers to enhance the luminous efficiency of the semiconductor device by having the electron barrier layer.

In order to form the semiconductor device 705 into the high-efficiency semiconductor laser, in the active layer 154, it is desirable that the semiconductor thin film which becomes the quantum well of MQW have p=0.87 in the composition formula, namely, the Ga_{0.87}In_{0.13}N compound, the semiconductor thin film which becomes the barrier of MQW have q=1 in the composition formula, namely, GaN compound, and the electron barrier layer have s=0.2 in the composition formula, namely, the Al_{0.2}Ga_{0.8}N compound. It is desirable that the thickness of the semiconductor thin film which becomes the quantum well be 3 (nm), the thickness of the semiconductor thin film which becomes the barrier be 10 (nm), and the thickness of the electron barrier layer be 20 (nm). The impurity of Mg is added to the electron barrier layer in order to form the p-type semiconductor. For example, the impurity concentration ranges from 1×10¹⁹ (cm⁻³) to 1×10²⁰ (cm⁻³), and preferably the impurity concentration is 5×10¹⁹ (cm⁻³).

The n-type second semiconductor layer 157 is a semiconductor layer made of an AlₓGa_{y}In_{1-x-y}N compound. An example of the n-type second semiconductor layer 157 includes the AlₘGa₁₋ₘN compound described in the second semiconductor layer 117 of FIG. 1. In order to form the semiconductor device 705 into the high-efficiency semiconductor laser, the n-type second semiconductor layer 157 is preferably made of the Al_{0.08}Ga_{0.92}N compound. The n-type impurity for enhancing the carrier density is added to the n-type second semiconductor layer 157 such that the n-type second semiconductor layer 157 functions as a cladding layer for supplying the electrons to the active layer 154. Si can be cited as an example of the impurity added to the n-type second semiconductor layer 157. For example, the impurity concentration of the n-type second semiconductor layer 157 ranges from 5×10¹⁷ (cm⁻³) to 1×10¹⁹ (cm⁻³). Preferably the thickness of the n-type second semiconductor layer 157 ranges from 300 (nm) to 2000 (nm), and more preferably the thickness ranges from 400 (nm) to 1200 (nm).

In order to form the semiconductor device 705 into the high-efficiency semiconductor laser, more preferably the impurity concentration of the n-type second semiconductor layer 157 is 3×10¹⁸ (cm⁻³) and the thickness is 1000 (nm).

The n-side first semiconductor layer 155 is a semiconductor layer made of an AlₓGa_{y}In_{1-x-y}N compound, which functions as a light guide layer for reflecting and guiding the light emitted from the active layer 154. The composition of the AlₓGa_{y}In_{1-x-y}N compound is designed such that a refractive index of the n-side first semiconductor layer 155 is smaller than that of the active layer 154. For example, the n-side first semiconductor layer 155 can be made of the GaN compound or GaInN compound described in the first semiconductor layer 115 of FIG. 1. In order not to diffuse the impurity into the active layer 154, the impurity is not added to the n-side first semiconductor layer 155, or the impurity having the concentration lower than that of the impurity in the n-type second semiconductor layer 157 is added to the n-side first semiconductor layer 155. The band gap of the n-side first semiconductor layer 155 is designed to be broader than that of the active layer 154 and to be narrower than that of the n-type second semiconductor layer 157. In the case where the active layer 154 has MQW, the band gap of the n-side first semiconductor layer 155 is broader than that of the barrier constituting the MQW, and the band gap of the n-side first semiconductor layer 155 is narrower than that of the n-type second semiconductor layer 157. The thickness of the n-side first semiconductor layer 155 is preferably located within the range described in the first semiconductor layer 115 of FIG. 1.

In order to form the semiconductor device 705 into the high-efficiency semiconductor laser, the n-side first semiconductor layer 155 is preferably the non-doped GaN compound or the low-doped GaN compound in which the concentration of the impurity Si is not more than 1×10¹⁸ (cm⁻³), and the thickness of the n-side first semiconductor layer 155 is preferably 100 (nm).

The n-side band gap change layer 156 is an AlₓGa_{y}In_{1-x-y}N compound layer in which the composition is continuously monotonously changed in the depositing direction. That is, in the composition in the depositing direction of the n-side band gap change layer 156, the values of x and y in the composition formula are continuously monotonously changed from one side of the n-side band gap change layer 156 to the other side. An example of the n-side band gap change layer 156 includes the group-III nitride compound having the same composition as the band gap change layer 116 described in FIG. 1. Since the composition of the n-side band gap change layer 156 is continuously monotonously changed, the polarization charge can be decreased in the n-side band gap change layer 156.

Preferably the thickness of the n-side band gap change layer 156 is 3 (nm) or more and less than 100 (nm), and more preferably the thickness ranges from 3 (nm) to 50 (nm).

The n-type impurity may be added to the n-side band gap change layer 156 in order to form the n-side band gap change layer 156 into the n-type semiconductor. Specifically, Si can be cited as an example of the n-type impurity. For example, the impurity concentration ranges from 5×10¹⁷ (cm⁻³) to 5×10¹⁸ (cm⁻³). As described in the band gap change layer 116 of FIG. 1, the impurity concentration range of the n-side band gap change layer 156 is preferably computed from the charge density of the polarization generated at the interface between the n-side first semiconductor layer 155 and the n-type second semiconductor layer 157 and the thickness of the n-side band gap change layer 156.

In order to form the semiconductor device 705 into the high-efficiency semiconductor laser, for example, the thickness of the n-side band gap change layer 156 is 10 (nm), the added impurity concentration n ranges from 1.5×10¹⁸ (cm⁻³) to 9×10¹⁸ (cm⁻³), and preferably the impurity concentration n is 3×10¹⁸ (cm⁻³)

The p-type second semiconductor layer 167 is a semiconductor layer made of an AlₓGa_{y}In_{1-x-y}N compound. An example of the p-type second semiconductor layer 167 includes AlₘGa₁₋ₘN compound described in the second semiconductor layer 117 of FIG. 1. In order to form the semiconductor device 705 into the high-efficiency semiconductor laser, the p-type second semiconductor layer 167 is preferably made of the Al_{0.08}Ga_{0.92}N compound. In order to cause the p-type second semiconductor layer 167 to function as the cladding layer for supplying the holes to the active layer 154, the p-type impurity which enhances the carrier density, e.g., Mg is added to the p-type second semiconductor layer 167. The impurity concentration and thickness of the p-type second semiconductor layer 167 are preferably located within the range described in the second semiconductor layer 117 of FIG. 1.

In order to form the semiconductor device 705 into the high-efficiency semiconductor laser, more preferably the impurity concentration of the p-type second semiconductor layer 167 is 3×10¹⁹ (cm⁻³) and the thickness is 500 (nm).

Similarly to the n-side first semiconductor layer 155, the p-side first semiconductor layer 165 is a semiconductor layer made of an AlₓGa_{y}In_{1-x-y}N compound which functions as the light guide layer. For example, the p-side first semiconductor layer 165 can be formed by the GaN compound described in the first semiconductor layer 115 of FIG. 1. In order not to diffuse the impurity into the active layer 154, the impurity is not added to the p-side first semiconductor layer 165, or the impurity having the concentration lower than that of the impurity in the p-side second semiconductor layer 167 is added to the p-side first semiconductor layer 165. The band gap of the p-side first semiconductor layer 165 is designed to be broader than that of the active layer 154 and to be narrower than that of the p-type second semiconductor layer 167. In the case where the active layer 154 has MQW, the band gap of the p-side first semiconductor layer 165 is broader than that of the barrier constituting MQW, and the band gap of the p-side first semiconductor layer 165 is narrower than that of the p-type second semiconductor layer 167. The thickness of the p-side first semiconductor layer 165 is preferably located within the range described in the first semiconductor layer 115 of FIG. 1.

In order to form the semiconductor device 705 into the high-efficiency semiconductor laser, the p-side first semiconductor layer 165 is preferably the non-doped GaN compound or the low-doped GaN compound in which the concentration of the impurity Mg is not more than 1×10¹⁹ (cm⁻³), and the thickness of the p-side first semiconductor layer 165 is preferably 100 (nm).

The p-side band gap change layer 166 is an AlₓGa_{y}In_{1-x-y}N compound layer in which the composition is continuously monotonously changed in the depositing direction. The p-side band gap change layer 166 has the same configuration and effect as the band gap change layer 116 of FIG. 1. An example of the p-side band gap change layer 166 includes the group-III nitride compound having the same composition as the band gap change layer 116 described in FIG. 1. In order to form the p-side band gap change layer 166 into the p-type semiconductor, the p-type impurity, e.g., Mg may be added to the p-side band gap change layer 166 within the impurity concentration range described in the band gap change layer 116 of FIG. 1. The thickness of the p-side band gap change layer 166 is preferably located within the range described in the band gap change layer 116 of FIG. 1.

In order to form the semiconductor device 705 into the high-efficiency semiconductor laser, for example, the thickness of the p-side band gap change layer 166 is 10 (nm), the added impurity concentration n ranges from 1.5×10¹⁸ (cm⁻³) to 9×10¹⁸ (cm⁻³), and preferably the impurity concentration n is 3×10¹⁸ (cm⁻³).

The configuration and effect of the p-type contact layer 168 are similar to those of the contact layer 118 of FIG. 1. In order to form the semiconductor device 705 into the high-efficiency semiconductor laser, the thickness of the p-type contact layer 168 is preferably 50 (nm).

The semiconductor device 705 is produced as follows. The n-type underlying layer 153, the n-type second semiconductor layer 157, the n-side band gap change layer 156, then-side first semiconductor layer 155, the active layer 154, the p-side first semiconductor layer 165, the p-side band gap change layer 166, the p-type second semiconductor layer 167, and the p-type contact layer 168 are sequentially deposited on the n-type substrate 152 using the MOCVD method described in the first embodiment. Then, the mesa 105 is formed as described in the semiconductor device 701 of FIG. 1.

In order to remove the semiconductor layer of a negative electrode portion M at the point where the electrode 151 is formed, the resist pattern with which the upper layer of a positive electrode portion P is formed again by the lithography technique, and the semiconductor layer is removed in the range of the p-type contact layer 168 of the negative electrode portion M to a part of the n-type underlying layer 153 by the dry etching. Because the etching is performed up to a part of the n-type underlying layer 153, the end point, namely, the thickness of the n-type underlying layer 153 which is left in the negative electrode portion M is controlled by the etching time.

After the negative electrode portion M is formed, the electrode 151 is formed by utilizing the MOCVD method, the lithography technique, and the dry etching.

In the p-type side with respect to the active layer 154 of the semiconductor device 705, the p-side first semiconductor layer 165, the p-side band gap change layer 166, the p-type second semiconductor layer 167, and the p-type contact layer 168 are substituted for the first semiconductor layer 115, the band gap change layer 116, the second semiconductor layer 117, and the contact layer 118 in the semiconductor device 701 of FIG. 1 respectively.

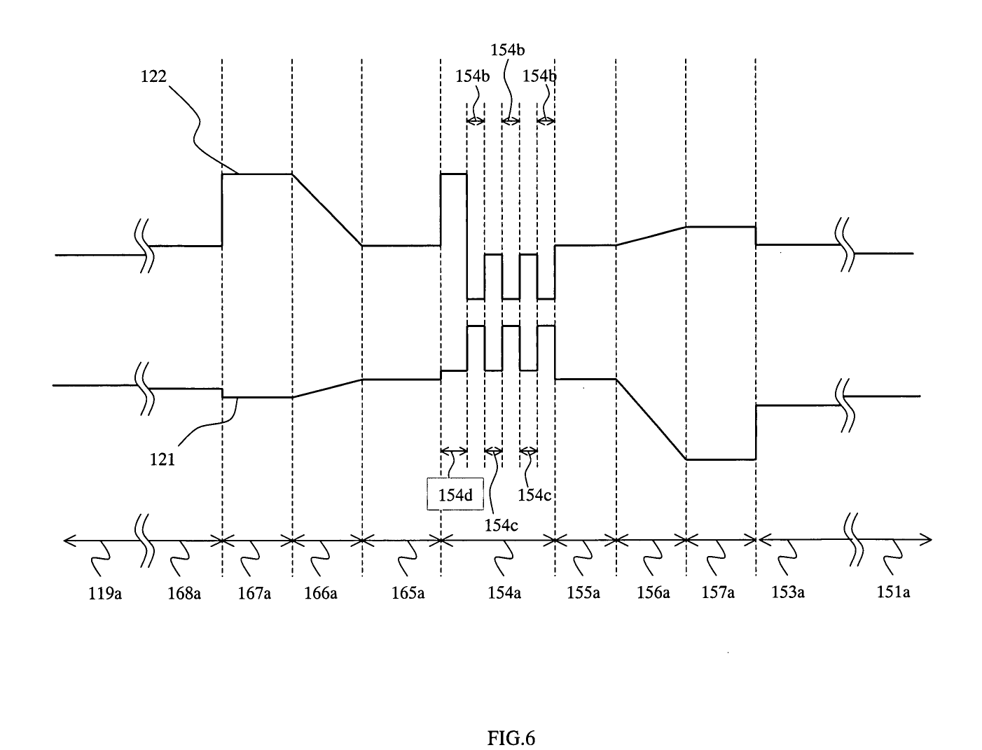

FIG. 6 is a conceptual view showing a band diagram of the semiconductor device 705. In FIG. 6, the numeral 151a designates a band gap in a region of the electrode 151, the numeral 153a designates a band gap in a region of the n-type underlying layer 153, the numeral 155a designates a band gap in a region of the n-side first semiconductor layer 155, the numeral 156a designates a band gap in a region of the n-side band gap change layer 156, the numeral 157a designates a band gap in a region of the n-type second semiconductor layer 157, the numeral 154a designates a band gap in a region of the active layer 154, the numeral 165a designates a band gap in a region of the p-side first semiconductor layer 165, the numeral 166a designates a band gap in a region of the p-side band gap change layer 166, the numeral 167a designates a band gap in a region of the p-type second semiconductor layer 167, the numeral 168a designates a band gap in a region of the p-type contact layer 168, and the numeral 119a designates a band gap in a region of the stripe-shape electrode 119. The numeral 121 designates the top level of the valence band, and the numeral 122 designates the bottom level of the conduction band. In the band diagram of FIG. 6, the active layer 154 of the semiconductor device 705 has the MQW, and the electron barrier layer is located at the end of MQW on the p-type side with respect to the MQW. In the region 154a of the active layer 154, the numeral 154b designates a region of the semiconductor thin film which becomes the quantum well, the numeral 154c designates a region of the semiconductor thin film which becomes the barrier, and the numeral 154d designates a region of the electron barrier layer. In FIG. 6, parts of the band gaps are not shown in the range of the electrode 151 to the n-type underlying layer 153 and in the range of the p-type contact layer 168 to the electrode 119.

The electrode 119 is set at the anode, the electrode 151 is set at the cathode, and the voltage is applied. This enables the electrons from the electrode 151 and the holes from the electrode 119 are injected into the semiconductor device 705.

The electrons injected from the electrode 151 can be smoothly moved toward the active layer 154 through the n-type underlying layer 153 and n-type second semiconductor layer 157 in which the electrons are the majority carriers. The band gap of the n-side first semiconductor layer 155 is narrower than that of the n-type second semiconductor layer 157, the bottom level 122 of the conduction band of then-side first semiconductor layer 155 and the bottom level 122 of the conduction band of the n-type second semiconductor layer 157 are gently connected to each other by the n-side band gap change layer 156, and the electrons can be moved along the bottom level 122 of the conduction band to the n-side first semiconductor layer 155 which is stabilized from the viewpoint of energy. The steep composition change does not exist between the n-side first semiconductor layer 155 and the n-type second semiconductor layer 157, and the polarization charge obstructing the electron transport is dispersed, so that the electrons can be smoothly moved from the n-type second semiconductor layer 157 to the n-side first semiconductor layer 155. The electrons are concentrated in each quantum well of the active layer 154 where the band gap is narrower than that of the n-side first semiconductor layer 155.

On the other hand, as described in the band diagram of the semiconductor device 701 of FIG. 2, the holes injected from the electrode 119 are moved to the p-side first semiconductor layer 165 through the p-type contact layer 168, the p-type second semiconductor layer 167, and the p-side band gap change layer 166. The holes moved to the p-side first semiconductor layer 165 are concentrated in each quantum well of the active layer 154 where the band gap is narrower than that of the p-side first semiconductor layer 165. Because the electron barrier layer of the active layer 154 has the high top level 121 of the valence band while having the wide band gap, the electron barrier layer has the little influence on the movement of the holes.

The active layer 154 emits the light having the wavelength according to the band gap expressed between the top level 121 of the valence band and the bottom level 122 of conduction band in the quantum well by the recombination of the electrons and the holes concentrated in each quantum well of the active layer 154.

Accordingly, the invention can provide a semiconductor device which can function as the semiconductor laser having the low electrical resistance by smoothly moving the carriers in the mesa where the p-side first semiconductor layer 165 and p-type second semiconductor layer 167 having the different compositions are deposited.

Similarly to the semiconductor device 701, the semiconductor device 705 can obtain the effects of the decrease in drive voltage and the improvement of the reliability.

In the semiconductor device 705, even if the band gap change layer 136 described in FIG. 3 is arranged instead of the p-side band gap change layer 166, the same effects can be obtained. Further, even if the AlₓGa_{y}In_{1-x-y}N compound layer in which the composition is monotonously changed in the stepwise manner in the depositing direction is arranged instead of the n-side band gap change layer 156, the same effects can be obtained.

### Fourth Embodiment

A fourth embodiment is a semiconductor light emitting device including an active layer which emits light by recombination of an electron and a hole; a first semiconductor layer which is deposited on a p-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the p-type side with respect to the active layer and a center in the direction of thickness of the band gap change layer ranges from 30 (nm) to 200 (nm), and a band gap of the band gap change layer is continuously monotonously changed from a band gap which is substantially equal to that of the first semiconductor layer to a band gap which is substantially equal to that of the second semiconductor layer from the side adjacent to the first semiconductor layer to the side adjacent to the second semiconductor layer.

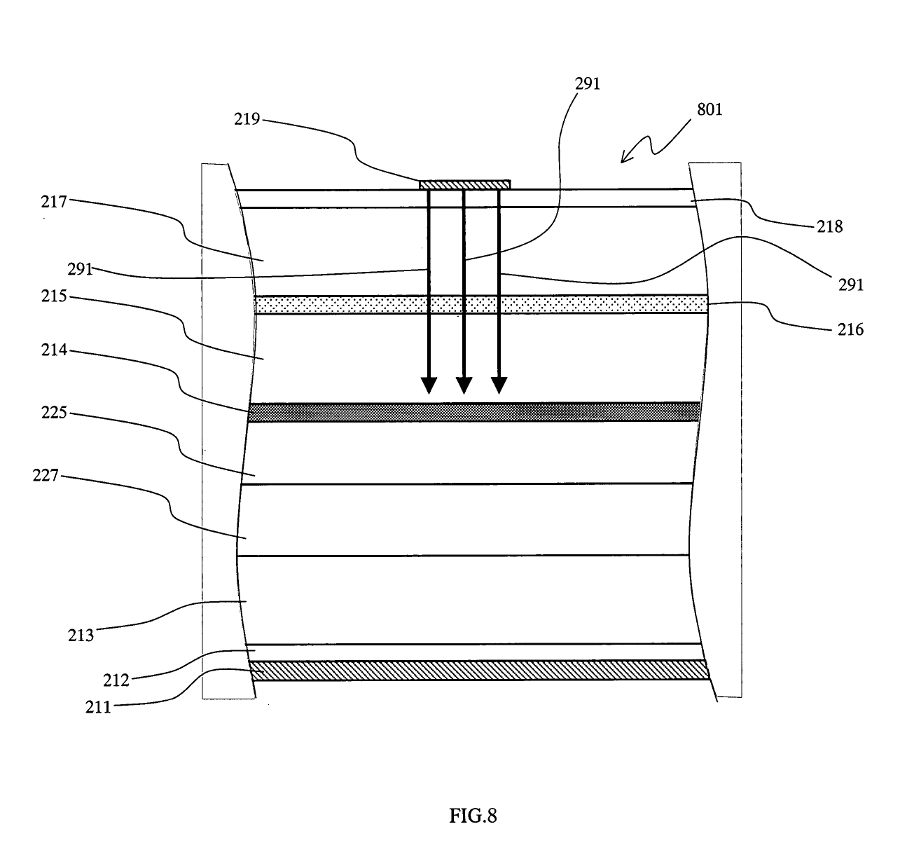

FIG. 8 is a conceptual view showing a cross section of a semiconductor light emitting device 801 which is of an embodiment according to a third aspect of the invention. The semiconductor light emitting device 801 includes an electrode 211, an n-type substrate 212, an n-type underlying layer 213, an n-side first semiconductor layer 225, an n-type second semiconductor layer 227, an active layer 214, a p-side first semiconductor layer 215, a p-side band gap change layer 216, a p-type second semiconductor layer 217, a p-type contact layer 218, and a stripe-shape electrode 219. In the semiconductor light emitting device 801, the semiconductor layers are deposited on the n-type substrate 212, and at least the p-type second semiconductor layer 217 and the p-type contact layer 218 are formed into the p-type semiconductor in the semiconductor layers on the side of the stripe-shape electrode 219 with respect to the active layer 214. On the other hand, at least the n-type second semiconductor layer 227, the n-type underlying layer 213, and the n-type substrate 212 are formed into the n-type semiconductor in the semiconductor layers on the side of electrode 211 with respect to the active layer 214. The semiconductor light emitting device 801 is a both-side electrode type of semiconductor light emitting device in which the semiconductor layers including the n-type substrate 212 are sandwiched between the electrode 211 and the stripe-shape electrode 219.

The electrode 211 and the stripe-shape electrode 219 are arranged in order to apply the voltage to the semiconductor light emitting device 801. It is desirable that the electrode 211 and the stripe-shape electrode 219 be made of a material which can come into ohmic contact with the semiconductor, because the efficiency is lost as the semiconductor light emitting device when the rectification is generated in bringing the electrode and the semiconductor into contact with each other. It is also desirable that the electrode 211 and the stripe-shape electrode 219 be made of a material having the small contact resistance with the interconnection of a device such as the external power supply. Therefore, it is preferable to form a structure in which a material which becomes the buffer is sandwiched between the material being in contact with the semiconductor and the material connected to the interconnection. Ti/Al/Ti/Au and Al/Au can be cited as an example of the material of the electrode 211 being in contact with the n-type semiconductor. Ni/Au, Pd/Au, and Pt/Au can be cited an example of the material of the stripe-shape electrode 219 being in contact with the p-type semiconductor.

In order to decrease the contact resistance with the n-type substrate 212, the electrode 211 is preferably deposited in the whole surface on the opposite side to the side on which the n-type underlying layer 213 of the n-type substrate 212 is deposited (hereinafter “the opposite side to the side on which the n-type underlying layer 213 of the n-type substrate 212 is deposited” is abbreviated to as “backside of n-type substrate 212”). On the other hand, the stripe-shape electrode 219 is arranged in the stripe shape on the p-type contact layer 218 in order to supply the carriers while the carriers are concentrated in a part of the active layer 214.

The n-type substrate 212 physically supports the semiconductor light emitting device 801. A material on which a semiconductor thin film is well grown is selected as the substrate of the semiconductor light emitting device 801. In the case where the group-III nitride compound expressed by the composition formula of AlₓGa_{y}In_{1-x-y}N (0≦x≦1, 0≦y≦1, 0≦x+y≦1) (hereinafter “the group-III nitride compound expressed by the composition formula of AlₓGa_{y}In_{1-x-y}N (0≦x≦1, 0≦y≦1, 0≦x+y≦1)” is abbreviated to “AlₓGa_{y}In_{1-x-y}N compound”) is deposited, gallium nitride (GaN) or silicon carbide (SiC) can be cited as an example of the n-type substrate 212.

The active layer 214 is a layer which emits the light by recombination of the electron and the hole. A wavelength of the emitting light is determined by the band gap of the material used for the active layer 214. The direct transition type semiconductor having the high luminous efficiency is preferably used as the material used for the active layer 214. The wide varieties of band gap can be made by the composition change using the AlₓGa_{y}In_{1-x-y}N compound thin film, and the semiconductor light emitting device having the desired wavelength can be produced. At least two kinds of the semiconductor thin films having the different band gaps are alternately arranged, which allows the active layer 214 to have the multiple quantum well (MQW) structure in which the semiconductor thin film having the broader band gap is set at the barrier while the semiconductor thin film having the narrower band gap is set at the quantum well. The active layer 214 can efficiently emit the light by forming the active layer 214 into the MQW. In the case of the MQW, the wavelength of the emitting light is determined by the band gap of the quantum well. The both ends of the MQW may be formed into the barrier or the quantum well. For example, the group-III nitride compound thin film in which x=0 and y=q (0.95≦q≦1, preferably 0.97≦q≦1) in the composition formula, namely, the group-III nitride compound thin film whose composition formula is expressed by Ga_{q}In_{1-q}N can be cited as an example of the semiconductor thin film which becomes the barrier. The group-III nitride compound thin film in which x=0 and y=p (p<q and 0.80≦p≦0.95, preferably 0.85≦p≦0.9) in the composition formula, namely, the group-III nitride compound thin film whose composition formula is expressed by GaₚIn₁₋ₚN can be cited as an example of the semiconductor thin film which becomes the quantum well. In the following description, “the group-III nitride compound whose composition formula is expressed by GaN” is abbreviated to “GaN compound”, “the group-III nitride compound whose composition formula is expressed by Ga_{q}In_{1-q}N” is abbreviated to “Ga_{q}In_{1-q}N compound” and “the group-III nitride compound whose composition formula is expressed by GaₚIn₁₋ₚN” is abbreviated to “GaₚIn₁₋ₚN compound.”

Preferably the thickness of the semiconductor thin film which becomes the barrier ranges from 5 (nm) to 20 (nm), and more preferably the thickness ranges from 7 (nm) to 15 (nm).

Preferably the thickness of the semiconductor thin film which becomes the quantum well ranges from 1 (nm) to 10 (nm), and more preferably the thickness ranges from 3 (nm) to 5 (nm).

In the thicknesses of the active layer 214, the thickness of the MQW (the total of thicknesses of the semiconductor thin film which becomes the barrier and the semiconductor thin film which becomes the quantum well) preferably ranges from 380 (nm) to 480 (nm).

The electron barrier layer made of an AlₓGa_{y}In_{1-x-y}N compound may be arranged at the end of the MQW on the p-type side with respect to the MQW. The electron barrier layer prevents the phenomenon of the carrier overflow, in which the electrons receiving the thermal energy by generating the heat associated with the light emission of the semiconductor device overcome the barrier of the quantum well and are moved to the semiconductor layer on the p-type side. Because the electron barrier layer has the wide band gap and the high bottom level of the conduction band, even the electron which obtains the thermal energy cannot be moved to the semiconductor layer on the p-type side through the electron barrier layer. For example, the group-III nitride compound in which x=s and x+y=1 (0.1≦s≦0.3, preferably 0.15≦s≦0.25) in the composition formula, namely, the group-III nitride compound thin film whose composition formula is expressed by AlₛGa₁₋ₛN (hereinafter “group-III nitride compound thin film whose composition formula is expressed by AlₛGa₁₋ₛN” is abbreviated to “AlₛGa₁₋ₛN compound”) can be cited as an example of the electron barrier layer. For example, the thickness of the electron barrier layer ranges from 10 (nm) to 30 (nm), and preferably the thickness ranges from 15 (nm) to 25 (nm). In the p-type semiconductor layer, because the carrier overflow electron becomes the ineffective carrier which does not engages in the light emission and then the luminous efficiency of the semiconductor device is decreased, the active layer 214 can decrease the number of ineffective carriers to enhance the luminous efficiency of the semiconductor light emitting device by having the electron barrier layer.

The n-type second semiconductor layer 227 is a semiconductor layer made of an AlₓGa_{y}In_{1-x-y}N compound. An example of the n-type second semiconductor layer 227 includes the group-III nitride compound having relationships of x=m (0.01≦m≦0.15, preferably 0.05≦m≦0.1) and x+y=1 in the composition formula, namely, the group-III nitride compound in which the composition formula is expressed as AlₘGa₁₋ₘN (hereinafter “the group-III nitride compound in which the composition formula is expressed as AlₘGa₁₋ₘN” is abbreviated to “AlₘGa₁₋ₘN compound”). The n-type impurity, e.g., Si is added to the n-type second semiconductor layer 227 in order to enhance the carrier density. For example, the impurity concentration ranges from 5×10¹⁷ (cm⁻³) to 1×10¹⁹ (cm⁻³). Preferably the thickness of the n-type second semiconductor layer 227 ranges from 300 (nm) to 2000 (nm), and more preferably the thickness ranges from 400 (nm) to 1200 (nm).

Then-side first semiconductor layer 225 is a semiconductor layer made of an AlₓGa_{y}In_{1-x-y}N compound. In order not to diffuse the impurity in the active layer 214, the impurity is not added to the n-side first semiconductor layer 225, or the impurity having the concentration lower than that of the impurity in the n-type second semiconductor layer 227 is added to the n-side first semiconductor layer 225. The band gap of the n-side first semiconductor layer 225 is designed to be broader than that of the active layer 214 and to be narrower than that of the n-type second semiconductor layer 227. In the case where the active layer 214 has the MQW, the band gap of the n-side first semiconductor layer 225 is broader than that of the barrier constituting the MQW, and the band gap of the n-side first semiconductor layer 225 is narrower than that of the n-type second semiconductor layer 227. Specifically, an example of the n-side first semiconductor layer 225 includes the group-III nitride compound having relationships of x=0 and y=1 in the composition formula, namely, the GaN compound. The composition of the n-side first semiconductor layer 225 may be set at x=0 and 0.95≦y≦1 in the composition formula, namely, the n-side first semiconductor layer 225 may be made of the GaInN compound. Preferably the thickness of the n-side first semiconductor layer 225 ranges from 20 (nm) to 200 (nm), and more preferably the thickness ranges from 50 (nm) to 150 (nm).

The p-type second semiconductor layer 217 is a semiconductor layer made of an AlₓGa_{y}In_{1-x-y}N compound. An example of the p-type second semiconductor layer 217 includes the group-III nitride compound having relationships of x=m (0.01≦m≦0.15, preferably 0.05≦m≦0.1) and x+y=1 in the composition formula, namely, the AlₘGa₁₋ₘN compound. The p-type impurity, e.g., Mg is added to the p-type second semiconductor layer 217 in order to enhance the carrier density. For example, the impurity concentration ranges from 5×10¹⁸ (cm⁻³) to 1×10²⁰ (cm⁻³). Preferably the thickness of the p-type second semiconductor layer 217 ranges from 100 (nm) to 2000 (nm), and more preferably the thickness ranges from 200 (nm) to 500 (nm).

The p-side first semiconductor layer 215 is a semiconductor layer made of an AlₓGa_{y}In_{1-x-y}N compound. In order not to diffuse the impurity in the active layer 214, the impurity is not added to the p-side first semiconductor layer 215, or the impurity having the concentration lower than that of the impurity in the p-type second semiconductor layer 217 is added to the p-side first semiconductor layer 215. The band gap of the p-side first semiconductor layer 215 is designed to be broader than that of the active layer 214. In the case where the active layer 214 has the MQW, the band gap of the p-side first semiconductor layer 215 is broader than that of the barrier constituting the MQW, and the band gap of the p-side first semiconductor layer 215 is narrower than that of the p-type second semiconductor layer 217. Specifically, an example of the p-side first semiconductor layer 215 includes the GaN compound having relationships of x=0 and y=1 in the composition formula. The composition of the p-side first semiconductor layer 215 may be set at x=0 and 0.95≦y≦1 in the composition formula, namely, the p-side first semiconductor layer 215 may be made of the GaInN compound. Preferably the thickness of the p-side first semiconductor layer 215 ranges from 20 (nm) to 200 (nm), and more preferably the thickness ranges from 50 (nm) to 150 (nm).

The p-side band gap change layer 216 is an AlₓGa_{y}In_{1-x-y}N compound layer in which the composition is continuously monotonously changed in the depositing direction. That is, in the composition in the depositing direction of the p-side band gap change layer 216, the values of x and y in the composition formula are continuously monotonously changed from one side of the p-side band gap change layer 216 to the other side. For example, in the depositing direction of the p-side band gap change layer 216, one side of the p-side band gap change layer 216 is the GaN compound in which x=0 and y=1 in the composition formula, the other side of the p-side band gap change layer 216 is the Al_{0.08}Ga_{0.92}N compound in which x=0.08 and y=0.92 in the composition formula, and the value of x is continuously monotonously changed from one side toward the other side in the composition formula while the value of y is continuously monotonously changed from 1 to 0.92 with the relationship of x+y=1 maintained.

Since the composition of the p-side band gap change layer 216 is continuously monotonously changed, the lattice strain caused by the steep change in composition can be decreased in the p-side band gap change layer 216.

Preferably the thickness of the p-side band gap change layer 216 is 3 (nm) or more and less than 100 (nm), and more preferably the thickness ranges from 3 (nm) to 50 (nm).

The p-type impurity may be added to the p-side band gap change layer 216 in order to form the p-side band gap change layer 216 into the p-type semiconductor. Specifically Mg can be cited as an example of the p-type impurity. For example, the impurity concentration can range from 1×10¹⁸ (cm⁻³) to 1×10¹⁹ (cm⁻³).

Assuming that ρ (cm⁻²) is charge density of the polarization generated at the interface where the group-III nitride compound of the first semiconductor layer and the group-III nitride compound of the second semiconductor layer are adjacent to each other and d (cm) is the thickness of the band gap change layer, an impurity concentration n (cm⁻³) of the impurity added into the band gap change layer is preferably set in the range of Formula 4, namely, the impurity concentration n is preferably set in the range of 50% to 300% of a quotient in which the charge density ρ is divided by the thickness d of the band gap change layer.
0.5×ρ/d≦n≦3×ρ/d [Formula 4]

Preferably the impurity concentration n is set in the range of Formula 5, and more preferably the impurity concentration n is set in the range of Formula 6.
0.8×ρ/d≦n≦2×ρ/d [Formula 5]
0.95×ρ/d≦n≦1.05×ρ/d [Formula 6]

The impurity concentration of the band gap change layer arranged between the GaN compound and the Al_{0.08}Ga_{0.92}N compound will be illustrated below. The polarization charge density generated at the interface between the GaN compound and the Al_{0.08}Ga_{0.92}N compound is ρ=3×10¹² (cm⁻²). When the thickness of the band gap change layer is set at 10 (nm), the impurity concentration n of the impurity added into the band gap change layer preferably ranges from 1.5×10¹⁸ (cm⁻³) to 9×10¹⁸ (cm⁻³).

The p-type contact layer 218 is a semiconductor layer which is in ohmic contact with the stripe-shape electrode 219. The GaN compound whose thickness ranges from 10 (nm) to 100 (nm) can be cited as an example of the p-type contact layer 218. In the case where the p-type contact layer 218 is made of the GaN compound, Mg can be cited as an example of the added impurity.

The n-type underlying layer 213 can improve the crystallinity of the semiconductor deposited on the n-type underlying layer 213. For example, the GaN compound including the impurity of Si can be cited as an example of the n-type underlying layer 153. Si is added to the GaN compound having the thickness ranging from 1 μm to 5 μm as the impurity to form the n-type semiconductor. For example, the impurity concentration ranges from 5×10¹⁷ (cm⁻³) to 1×10¹⁹ (cm⁻³).

In the semiconductor light emitting device 801, the n-type underlying layer 213, the n-type second semiconductor layer 227, the n-side first semiconductor layer 225, the active layer 214, the p-side first semiconductor layer 215, the p-side band gap change layer 216, the p-type second semiconductor layer 217, and the p-type contact layer 218 are sequentially deposited on the n-type substrate 212. Means for depositing the semiconductor layers will be described later.

In the case where the composition on one side of the p-side band gap change layer 216 is equalized to that of the p-side first semiconductor layer 215 while the composition on the other side is equalized to that of p-type second semiconductor layer 217, the p-side band gap change layer 216 is deposited such that one side of the p-side band gap change layer 216 is adjacent to the p-side first semiconductor layer 215 while the other side is adjacent to the p-type second semiconductor layer 217. Since the composition is continuously monotonously changed from the p-side first semiconductor layer 215 to the p-type second semiconductor layer 217, the band gap is also continuously monotonously changed from the p-side first semiconductor layer 215 to the p-type second semiconductor layer 217. For example, in the case where the p-side first semiconductor layer 215 is made of the GaN compound while the p-type second semiconductor layer 217 is made of the Al_{0.08}Ga_{0.92}N compound, the composition on one side of the p-side band gap change layer 216 is set to GaN while the composition on the other side is set to Al_{0.08}Ga_{0.92}N, which eliminates the steep composition change between the p-side first semiconductor layer 215 and the p-side band gap change layer 216 and between the p-type second semiconductor layer 216 and the p-type second semiconductor layer 217 to continuously monotonously change the composition from the p-side first semiconductor layer 215 to the p-type second semiconductor layer 217.

Accordingly, because the steep composition change is eliminated between the p-side first semiconductor layer 215 and the p-side band gap change layer 216 and between the p-side band gap change layer 216 and the p-type second semiconductor layer 217, the polarization charge obstructing the carrier transport can be dispersed, and the holes can be smoothly moved from the p-type second semiconductor layer 217 to the p-side first semiconductor layer 215.

Each of the semiconductor layers in the semiconductor light emitting device 801 is deposited by utilizing the metal organic chemical vapor deposition method (hereinafter “metal organic chemical vapor deposition” is abbreviated to “MOCVD method”). The MOCVD method is one in which reactant gas is introduced to the reactor (chamber), fixed to the inside of the chamber and the reactant gas is thermally decomposed and reacted to perform the epitaxial growth of the thin film on the substrate whose temperature is kept in the range of 600° C. to 1100° C. The semiconductor layers having the different compositions or different thicknesses can easily be deposited by controlling production parameters such as a flow rate and a concentration of the reactant gas, reaction temperature and time, and a kind of diluent gas.

In the case where the n-type underlying layer 213, the n-type second semiconductor layer 227, the n-side first semiconductor layer 225, the active layer 214, the p-side first semiconductor layer 215, the p-side band gap change layer 216, the p-type second semiconductor layer 217, and the p-type contact layer 218 are formed by the AlₓGa_{y}In_{1-x-y}N compound thin films, the vapor in which the bubbling is performed with hydrogen or nitrogen which is of the carrier gas to the group III elements of Ga(CH₃)₃ (trimethyl gallium, hereinafter abbreviated to “TMG”), In(C₂H₅)₃ (triethyl indium, hereinafter abbreviated to “TMI”), and Al(CH₃)₃ (trimethyl aluminium, hereinafter abbreviated to “TMA”) is used as the source gas, and the ammonia vapor is used in order to make the nitride in the MOCVD method. For the impurity, CP₂Mg (cyclopentadienyl magnesium) which is of the p-type dopant can be used as the source gas, or SiH₄ (silane) which is of the n-type dopant is introduced into the chamber in the form of the vapor. In the MOCVD method, the desired AlₓGa_{y}In_{1-x-y}N compound can be grown by setting a ratio of the mixed gas in which CP₂Mg or SiH₄, TMG, TMI, TMA, and ammonia are mixed together, the flow rate of the mixed gas, and the substrate temperature as the production parameters. In the MOCVD method, the thickness of the AlₓGa_{y}In_{1-x-y}N compound can be controlled by the reaction time.

Specifically the semiconductor light emitting device 801 is produced as follows. The n-type substrate 212 is placed in the chamber, and the temperature of the n-type substrate 212 is raised to an extend ranging from 600 to 1100° C. while the carrier gas is substituted for the inside of the chamber.

The source gas is introduced into the chamber along with the carrier gas of hydrogen or nitrogen.

The mixed gas (mixed gas A) of TMG, ammonia, and SiH₄ having the mixture ratio in which the GaN compound is grown is introduced, and the reaction is performed on the n-type substrate 212 to deposit the n-type underlying layer 213 for a predetermined time.

Then, the mixed gas (mixed gas B) of TMG, TMI, TMA, ammonia, and SiH₄ having the mixture ratio in which the n-type second semiconductor layer 227 is grown is introduced, and the reaction is performed on the n-type underlying layer 213 to deposit the n-type second semiconductor layer 227 for a predetermined time. For example, in the case where the n-type second semiconductor layer 227 is made of the Al_{0.08}Ga_{0.92}N compound, the mixed gas B of TMG, TMA, ammonia and SiH₄ is used.

Similarly, the mixed gas (mixed gas C) of TMG, TMI, TMA, ammonia, and SiH₄ having the mixture ratio in which the n-side first semiconductor layer 225 is grown is introduced, and the reaction is performed on the n-type second semiconductor layer 227 to deposit the n-side first semiconductor layer 225 for a predetermined time. In the case where the impurity is not added, the reaction is performed while the supply of SiH₄ is stopped. For example, in the case where the n-side first semiconductor layer 225 is made of the non-doped GaN compound, the mixed gas C of TMG and ammonia is used.

Similarly the active layer 214 is deposited on the n-side first semiconductor layer 225. In the case where the active layer 214 has the MQW, the semiconductor thin film which becomes the barrier and the semiconductor thin film which becomes the quantum well can alternately be deposited by changing the production parameters at predetermined intervals. In the case where the active layer 214 has the electron barrier layer, the electron barrier layer can be deposited at the end on the p-type side of the MQW by changing the production parameters at predetermined timing.

For example, the active layer 214 includes the semiconductor thin film which becomes the barrier, the semiconductor thin film which becomes the quantum well, and the electron barrier layer, the semiconductor thin film which becomes the barrier is formed by the Ga_{0.97} In_{0.03}N compound thin film, the semiconductor thin film which becomes the quantum well is formed by the Ga_{0.9}In_{0.1}N compound thin film, and the electron barrier layer is formed by the Al_{0.2}Ga_{0.8}N compound. In the case where the active layer 214 is deposited, first the Ga_{0.9}In_{0.1}N compound thin film is grown with the mixed gas (mixed gas D) of TMG, TMI, and ammonia in order to deposit the semiconductor thin film which becomes the quantum well on the n-side first semiconductor layer 225. Then, the Ga_{0.97}In_{0.03}N compound thin film is grown with the mixed gas (mixed gas E) of TMG, TMI, and ammonia in order to deposit the semiconductor thin film which becomes the barrier on the Ga_{0.9}In_{0.1}N compound thin film. Then, the semiconductor thin film which becomes the quantum well is deposited again by changing the mixed gas E to the mixed gas D. Then, the semiconductor thin film which becomes the barrier is further deposited by changing the mixed gas D to the mixed gas E. Similarly the predetermined number of quantum wells can be formed by changing the mixed gas D and the mixed gas E predetermined times. After the predetermined number of quantum wells is formed, in order to deposit the electron barrier layer, the Al_{0.2}Ga_{0.8}N compound thin film is grown using the mixed gas (mixed gas F) of TMG, TMA, CP₂Mg, and ammonia.

After the active layer 214 is deposited, the mixed gas (mixed gas G) of TMG, TMI, TMA, ammonia, and CP₂Mg having the mixture ratio in which the p-side first semiconductor layer 215 is grown is introduced, and the reaction is performed on the active layer 214 to deposit the p-side first semiconductor layer 215 for a predetermined time. For example, in the case where the p-side first semiconductor layer 215 is made of the non-doped GaN compound, the mixed gas G of TMG and ammonia is used.

Then, the p-side band gap change layer 216 is deposited on the p-side first semiconductor layer 215. The reaction gas for depositing the p-side band gap change layer 216 will be described later.

Then, the mixed gas (mixed gas H) of TMG, TMI, TMA, ammonia, and CP₂Mg having the mixture ratio in which the p-type second semiconductor layer 217 is grown is introduced, and the reaction is performed on the p-side band gap change layer 216 to deposit the p-type second semiconductor layer 217 for a predetermined time. For example, in the case where the p-type second semiconductor layer 217 is made of the Al_{0.08}Ga_{0.92}N compound, the mixed gas H of TMG, TMA, ammonia, and CP₂Mg in each predetermined ratio is used.

In the growth of the p-side band gap change layer 216, the mixed gas introduced into the chamber is reacted while the mixture ratio of the mixed gas is continuously monotonously changed from the ratio of the mixed gas G to the ratio of the mixed gas H. In the depositing direction, the composition of the p-side band gap change layer 216 deposited by the reaction is continuously monotonously changed from the composition of the p-side first semiconductor layer 215 to the composition of the p-type second semiconductor layer 217. Accordingly, the p-side band gap change layer 216 becomes a semiconductor layer in which the band gap is not steeply changed. The p-side band gap change layer 216 can be formed into the p-type semiconductor by adding CP₂Mg to the reaction gas.

After the p-type second semiconductor layer 217 is deposited, the mixed gas (mixed gas I) of TMG, ammonia, and CP₂Mg having the mixture ratio in which the p-type contact layer 218 is grown is introduced, and the reaction is performed on the p-type second semiconductor layer 217 to deposit the p-type contact layer 218 for a predetermined time.

The depositions of the p-side first semiconductor layer 215 and the p-side band gap change layer 216 are controlled such that a distance in the depositing direction from the interface between the active layer 214 and the p-side first semiconductor layer 215 to the center in the direction of thickness of the p-side band gap change layer 216 ranges from 30 (nm) to 200 (nm), preferably ranges from 30 (nm) to 100 (nm). That is, a time interval between the time when the mixed gas F is changed to the mixed gas G and a half of the deposition time of the p-side band gap change layer 216 is controlled. Accordingly, the thickness of the p-side first semiconductor layer 215 is restricted such that the distance in the depositing direction between the active layer 214 and the p-side band gap change layer 216 exists within the range.

The molecular beam epitaxial growth method (MBE method) may be adopted for the method of growing the group-III nitride compound on the n-type substrate 212.

After the p-type contact layer 218 is deposited, the material of the stripe-shape electrode 219 is deposited on the p-type contact layer 218, and the material of the electrode 211 is deposited on the backside of the n-type substrate 212. The sputtering method or the vacuum evaporation method can be adopted for the method of depositing the materials of the electrodes.

The stripe-shape electrode 219 is formed after the materials of the electrodes are deposited. The lithography technique and the dry etching can be used as the method of forming the stripe-shape electrode 219. A stripe-shape resist pattern is formed by the lithography technique, and the material of the stripe-shape electrode 219 is etched in the stripe shape. The material of the stripe-shape electrode 219 which is not covered with the resist pattern can be well etched while the p-type contact layer 218 functions as an etching stop layer by using the etching gas having the high etching selectivity for the material of the stripe-shape electrode 219 and p-type contact layer 218, e.g., the GaN compound. Then, the stripe-shape electrode 219 can be formed by removing the resist.

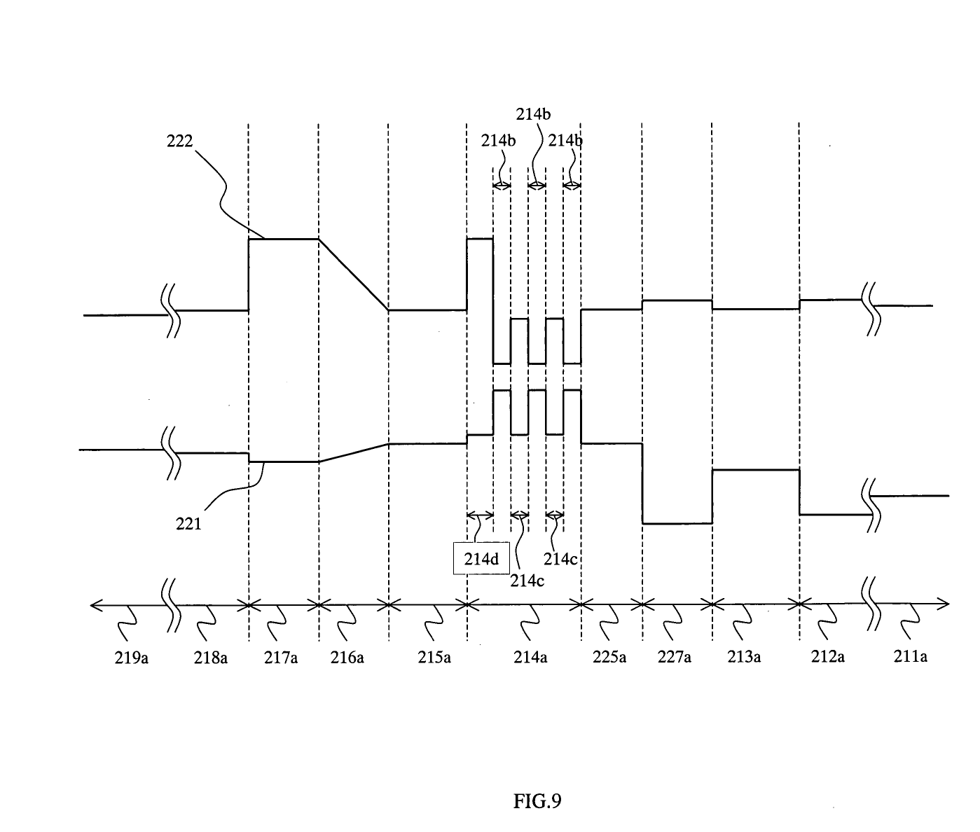

FIG. 9 is a conceptual view showing a band diagram of the semiconductor light emitting device 801. In FIG. 9, the numeral 211a designates a band gap in a region of the electrode 211, the numeral 212a designates a band gap in a region of n-type substrate 212, the numeral 213a designates a band gap in a region of the n-type underlying layer 213, the numeral 225a designates a band gap in a region of the n-side first semiconductor layer 225, the numeral 227a designates a band gap in a region of the n-type second semiconductor layer 227, the numeral 214a designates a band gap in a region of the active layer 214, the numeral 215a designates a band gap in a region of the p-side first semiconductor layer 215, the numeral 216a designates a band gap in a region of the p-side band gap change layer 216, the numeral 217a designates a band gap in a region of the p-type second semiconductor layer 217, the numeral 218a designates a band gap in a region of the p-type contact layer 218, and the numeral 219a designates a band gap in a region of the stripe-shape electrode 219. The numeral 221 designates the top level of the valence band, and the numeral 222 designates the bottom level of the conduction band. In the band diagram of FIG. 9, the active layer 214 of the semiconductor light emitting device 801 has the MQW, and the active layer 214 has the electron barrier layer at the end of MQW on the p-type side. In the region 214a of the active layer 214, the numeral 214b designates a region of the semiconductor thin film which becomes the quantum well, the numeral 214c designates a region of the semiconductor thin film which becomes the barrier, and the numeral 214d designates a region of the electron barrier layer. In FIG. 9, parts of the band gaps are not shown in the range of the electrode 211 to the n-type substrate 212 and in the range of the p-type contact layer 218 to the stripe-shape electrode 219.

The stripe-shape electrode 219 is set at the anode, the electrode 211 is set at the cathode, and the voltage is applied. This enables the electrons from the electrode 211 and the holes from the stripe-shape electrode 219 are injected into the semiconductor light emitting device 801.

The electrons injected from the electrode 211 can be smoothly moved toward the active layer 214 through the n-type substrate 212, n-type underlying layer 213 and n-type second semiconductor layer 227 in which the electrons are the majority carrier. The band gap of the n-side first semiconductor layer 225 is narrower than that of the n-type second semiconductor layer 227, so that the electrons can be smoothly moved along the bottom level 222 of the conduction band to the n-side first semiconductor layer 225 which is stabilized from the viewpoint of energy. The electrons are concentrated in each quantum well of the active layer 214 where the band gap is narrower than that of the n-side first semiconductor layer 225.

On the other hand, the holes injected from the stripe-shape electrode 219 are moved toward the active layer 214 through the p-type contact layer 218 and the p-type second semiconductor layer 217. The band gap of the p-side first semiconductor layer 215 is narrower than that of the p-type second semiconductor layer 217, the top level 221 of the valence band of the p-side first semiconductor layer 215 and the top level 221 of the valence band of the p-type second semiconductor layer 217 are gently connected by the p-side band gap change layer 216, and the holes can be moved along the top level 221 of the valence band to the p-side first semiconductor layer 215 which is stabilized from the viewpoint of energy. The holes moved to the p-side first semiconductor layer 215 are concentrated in each quantum well of the active layer 214 where the band gap is narrower than that of the p-side first semiconductor layer 215. Because the p-type electron barrier layer of the active layer 214 has the high top level 221 of the valence band while having the wide band gap, the electron barrier layer has the little influence on the movement of the hole.

The active layer 214 emits the light having the wavelength according to the band gap expressed between the top level 221 of the valence band and the bottom level 222 of conduction band in the quantum well by the recombination of the electrons and the holes concentrated in each quantum well of the active layer 214.

Because the distance in the depositing direction between the active layer 214 and the p-side band gap change layer 216 exists within the constant range, the diffusion of the holes narrowed and injected by the stripe-shape electrode 219 is decreased in the p-type second semiconductor layer 217, the p-side band gap change layer 216, and the p-side first semiconductor layer 215, and the holes intensively reach the portion immediately below the stripe-shape electrode 219 of the active layer 214 as shown by hole flows 291 of FIG. 8.

Accordingly, the invention can provide a semiconductor light emitting device in which the carriers can be smoothly moved between the two semiconductor layers having the different compositions without increasing the impurity concentration, namely, without degrading the optical characteristics and reliability. Particularly, in the case where Mg is added as the p-type impurity in the related art, it is necessary that the impurity concentration be increased in order to smoothly perform the hole transport. However, in the invention, the p-side band gap change layer 216 enables the smooth hole transport even if the impurity concentration is decreased, thereby effect of the invention is large.

Because the repulsive force applied to the hole is decreased by the dispersion of the polarization charge, the electrical resistance and built-in voltage is decreased in the semiconductor light emitting device 801, and the drive voltage applied to the semiconductor light emitting device 801 can be decreased. Accordingly, in the case where the semiconductor light emitting device 801 is the semiconductor laser, the decrease in threshold current and current-light quantity slope efficiency can be improved. In the case where the semiconductor light emitting device 801 is LED, the improvement of brightness can be achieved.

The lattice strain is generated most strongly and the polarization charge emerges prominently, when the crystals of the two group-III nitride compounds having the different compositions are deposited while orientated in the c-axis direction. Therefore, the effect of the p-side band gap change layer 216, namely, the effect of the dispersion of the polarization charge becomes maximum, in the case where the depositing directions of the p-side first semiconductor layer 215, the p-side band gap change layer 216, and the p-type second semiconductor layer 217 are parallel to the c-axis directions of the group-III nitride compound crystals of the p-side first semiconductor layer 215, the p-side band gap change layer 216, and the p-type second semiconductor layer 217. Accordingly, the p-side band gap change layer 216 makes the carrier transport smooth between the two semiconductor layers having the different compositions without increasing the impurity concentration of the p-side first semiconductor layer 215, namely, without degrading the optical characteristics and reliability.

### Fifth Embodiment

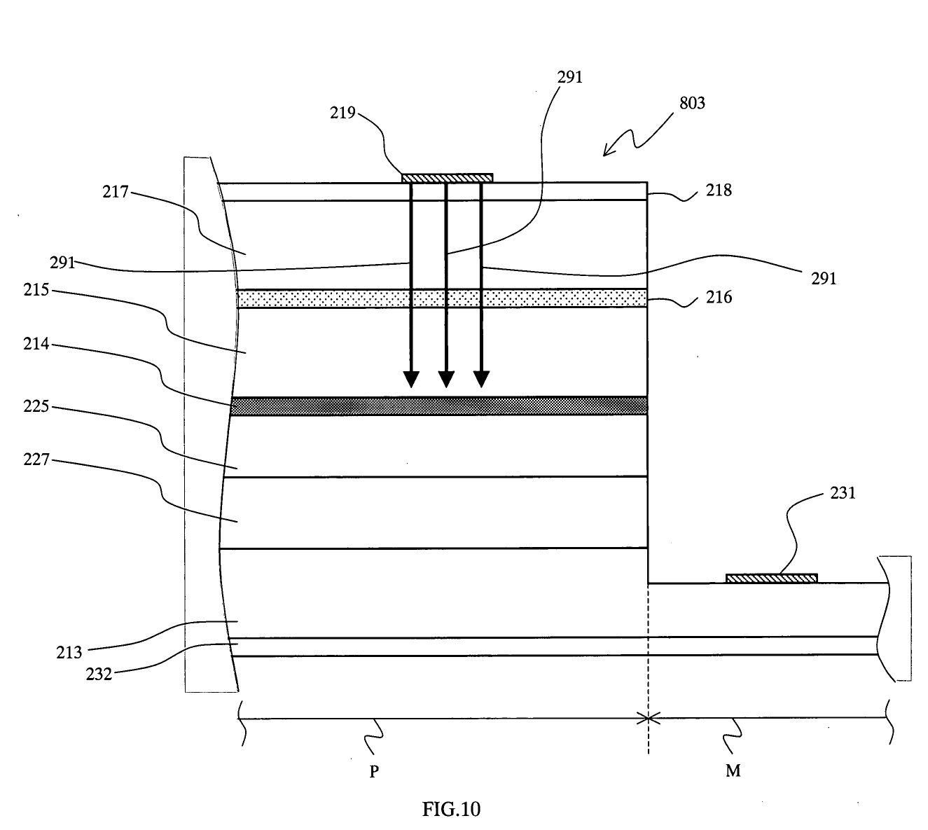

FIG. 10 is a conceptual view showing a cross section of a semiconductor light emitting device 803 which is of another embodiment according to the third aspect of the invention. In FIG. 10, the same semiconductor layer having the same function as FIG. 8 is designated by same numeral. The semiconductor light emitting device 803 differs from the semiconductor light emitting device 801 of FIG. 8 in that the semiconductor light emitting device 803 is a type in which the positive electrode and the negative electrode are located in the same direction with respect to the substrate while the semiconductor light emitting device 801 is the both-side electrode type in which the positive electrode is provided in the backside of the substrate. Specifically, the electrode 211 and n-type substrate 212 of the semiconductor light emitting device 801 are not provided in the semiconductor light emitting device 803, but an n-type substrate 232 and an electrode 231 are provided in the semiconductor light emitting device 803.

The n-type substrate 232 physically supports the semiconductor light emitting device 803. A material on which a semiconductor thin film is well grown is selected as the substrate of the semiconductor light emitting device 803. In the case where the AlₓGa_{y}In_{1-x-y}N compound is deposited, sapphire can be cited as an example of the substrate.

The electrode 231 is arranged in order to apply the voltage to the semiconductor light emitting device 803. The electrode 231 has the function similar to the electrode 211 of FIG. 8, and Ti/Al/Ti/Au and Al/Au can be cited as an example of a material of the electrode 231.

The semiconductor light emitting device 803 is produced as follows. The n-type underlying layer 213, the n-type second semiconductor layer 227, the n-side first semiconductor layer 225, the active layer 214, the p-side first semiconductor layer 215, the p-side band gap change layer 216, the p-type second semiconductor layer 217, and the p-type contact layer 218 are sequentially deposited on the n-type substrate 232 using the MOCVD method. Then, the stripe-shape electrode 219 is formed as described in the semiconductor light emitting device 801 of FIG. 8.

In order to remove the semiconductor layer of the negative electrode portion M at the point where the electrode 231 is formed, the resist pattern with which the upper layer of the positive electrode portion P is formed again by the lithography technique, and the semiconductor layer is removed in the range of the p-type contact layer 218 of the negative electrode portion M to a part of the n-type underlying layer 213 by the dry etching. Because the etching is performed up to a part of the n-type underlying layer 213, the end point, namely, the thickness of the n-type underlying layer 213 which is left in the negative electrode portion M is controlled by the etching time.

After the negative electrode portion M is formed, the electrode 231 is formed similarly to the formation of the stripe-shape electrode 219.

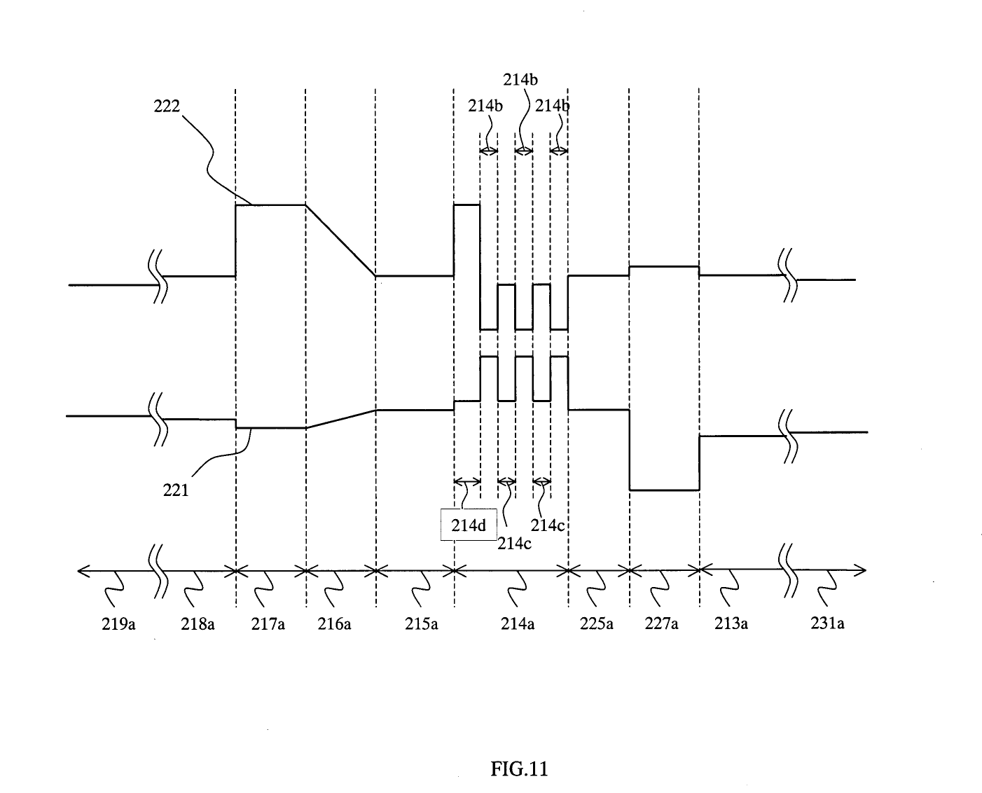

FIG. 11 is a conceptual view showing a band diagram of the semiconductor light emitting device 803. In FIG. 11, the region of the same deposited film having the same function as FIG. 9 is designated by the same numeral. The band diagram of the semiconductor light emitting device 803 of FIG. 11 differs from the band diagram of the semiconductor light emitting device 801 of FIG. 9 in that n-type the region 212a of the substrate 212 and the region 211a of the electrode 211 do not exist on the n-type side with respect to the region 214a of the active layer 214, but the region 231a of the electrode 231 is displayed. In FIG. 11, parts of the band gaps are not shown in the range of the p-type contact layer 218 to the stripe-shape electrode 219 and in the range of the n-type underlying layer 213 to the electrode 231.

The stripe-shape electrode 219 is set at the anode, the electrode 231 is set at the cathode, and the voltage is applied. This enables the electrons from the electrode 231 and the holes from the stripe-shape electrode 219 are injected into the semiconductor light emitting device 803.

As described in the band diagram of the semiconductor light emitting device 801 of FIG. 9, the electrons injected from the electrode 231 are concentrated in each quantum well of the active layer 214 of the semiconductor light emitting device 803.

On the other hand, as described in the band diagram of the semiconductor light emitting device 801 of FIG. 9, the holes injected from the stripe-shape electrode 219 are concentrated in each quantum well of the active layer 214 of the semiconductor light emitting device 803. Accordingly, the semiconductor light emitting device 803 emits the light having the wavelength according to the band gap expressed between the top level 221 of the valence band and the bottom level 222 of conduction band in the quantum well.

Similarly to the semiconductor light emitting device 801 of FIG. 8, in the semiconductor light emitting device 803, the distance in the depositing direction between the active layer 214 and the p-side band gap change layer 216 exists within the constant range. Therefore, the holes narrowed and injected by the stripe-shape electrode 219 intensively reach the portion immediately below the stripe-shape electrode 219 of the active layer 214 as shown by the hole flows 291 of FIG. 8.

Accordingly, the invention can provide a semiconductor light emitting device in which the carriers can be smoothly moved between the two semiconductor layers having the different compositions without increasing the impurity concentration, namely, without degrading the optical characteristics and reliability.

That is, similarly to the semiconductor light emitting device 801, the semiconductor light emitting device 803 can obtain the effects such as the decrease in threshold current, the current-light quantity slope efficiency, and the improvement of the brightness.

Similarly to the semiconductor light emitting device 801, the effect of the p-side band gap change layer 216, namely, the effect of the dispersion of the polarization charge becomes maximum in the semiconductor light emitting device 803, in the case where the depositing directions of the p-side first semiconductor layer 215, the p-side band gap change layer 216, and the p-type second semiconductor layer 217 are orientated toward the c-axis directions of the group-III nitride compound crystals. Accordingly, the p-side band gap change layer 216 makes the carrier transport smooth between the two semiconductor layers having the different compositions without increasing the impurity concentration of the p-side first semiconductor layer 215, namely, without degrading the optical characteristics and reliability.

### Sixth Embodiment

A sixth embodiment is a semiconductor light emitting device including an active layer which emits light by recombination of an electron and a hole; a first semiconductor layer which is deposited on a p-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the p-type side with respect to the active layer and a center in the direction of thickness of the band gap change layer ranges from 30 (nm) to 200 (nm), and a band gap of the band gap change layer is monotonously changed in the stepwise manner from a band gap which is substantially equal to that of the first semiconductor layer to a band gap which is substantially equal to that of the second semiconductor layer from the side adjacent to the first semiconductor layer to the side adjacent to the second semiconductor layer.

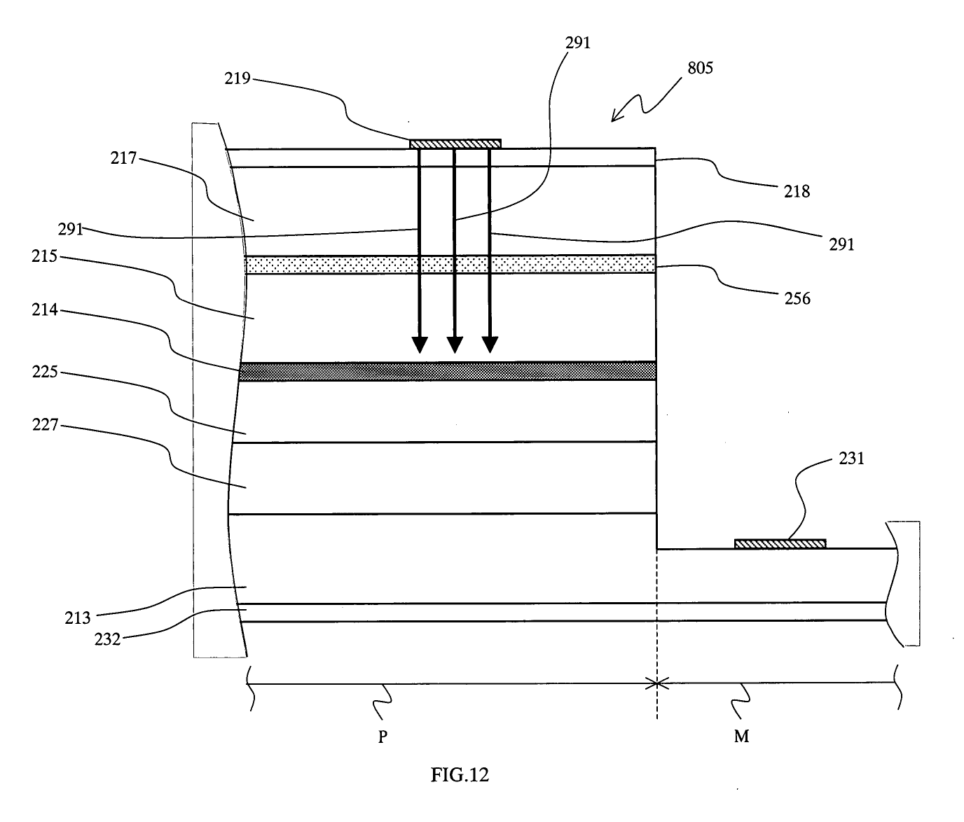

FIG. 12 is a conceptual view showing a cross section of a semiconductor light emitting device 805 which is of an embodiment according to the fourth aspect of the invention. In FIG. 12, the same semiconductor layer having the same function as FIGS. 8 and 10 is designated by same numeral. The semiconductor light emitting device 805 differs from the semiconductor light emitting device 803 of FIG. 10 in that the semiconductor light emitting device 805 does not include the p-side band gap change layer 216 of the semiconductor light emitting device 803 but include a p-side band gap change layer 256.

The p-side band gap change layer 256 is an AlₓGa_{y}In_{1-x-y}N compound layer in which the composition is monotonously changed in the depositing direction in the stepwise manner. That is, in the composition of the p-side band gap change layer 256, the values of x and y in the composition formula are monotonously changed in the stepwise manner from one side of the p-side band gap change layer 256 to the other side. Specifically, the p-side band gap change layer 256 includes the plural AlₓGa_{y}In_{1-x-y}N compound thin films which are deposited in the order of the wide band gap or in the order of the narrower band gap. For example, the p-side band gap change layer 256 sequentially includes the GaN compound thin film, the Al_{0.02}Ga_{0.98}N compound thin film, the Al_{0.04}Ga_{0.96}N compound thin film, the Al_{0.06}Ga_{0.94}N compound thin film, and the Al_{0.08}Ga_{0.92}N compound thin film whose thickness are 10 nm from one side of the band gap change layer 136 to the other side in the depositing direction. The band gap of the p-side band gap change layer 256 is monotonously changed in the stepwise manner from one side toward the other side, namely, from the narrowest band gap of the GaN compound thin film to the broadest band gap of the Al_{0.08}Ga_{0.92}N compound thin film. The composition of the compound thin film may unevenly be changed, and the thickness of the compound thin film may be uneven.

Since the composition of the p-side band gap change layer 256 is monotonously changed in the stepwise manner, the lattice strain caused by the steep composition change can be decreased in the p-side band gap change layer 256.

Preferably the thickness of the p-side band gap change layer 256 is 3 (nm) or more and less than 100 (nm), and more preferably the thickness ranges from 3 (nm) to 50 (nm).

In order to form the p-side band gap change layer 256 into the p-type semiconductor, the p-type impurity may be added to the p-side band gap change layer 256. Specifically, Mg can be cited as an example of the p-type impurity, and the impurity concentration n ranges from 1×10¹⁸ (cm⁻³) to 1×10¹⁹ (cm⁻³) by way of example. As described in the p-side band gap change layer 216 of FIG. 8, the impurity concentration range of the p-side band gap change layer 256 is preferably computed from the charge density of the polarization generated at the interface between the p-side first semiconductor layer 215 and the p-type second semiconductor layer 217 and the thickness of the p-side band gap change layer 256.

The semiconductor light emitting device 805 is produced as follows. The n-type underlying layer 213, the n-type second semiconductor layer 227, the n-side first semiconductor layer 225, the active layer 214, the p-side first semiconductor layer 215, the p-side band gap change layer 256, the p-type second semiconductor layer 217, and the p-type contact layer 218 are sequentially deposited on the n-type substrate 232 using the MOCVD method. In the production of the p-side band gap change layer 256, the production parameters described in the third embodiment are changed to deposit the p-side band gap change layer 256 in the stepwise manner in each predetermined time. The depositions of the p-side first semiconductor layer 215 and the p-side band gap change layer 256 are controlled such that the distance in the depositing direction from the interface between the active layer 214 and the p-side first semiconductor layer 215 to the center in the direction of thickness of the p-side band gap change layer 256 ranges from 30 (nm) to 200 (nm), preferably ranges from 30 (nm) to 100 (nm).

Then, the stripe-shape electrode 219 is formed as described in the semiconductor light emitting device 801 of FIG. 8. Then, the negative electrode portion M is formed to form the electrode 231 as described in semiconductor light emitting device 803 of FIG. 10.

The composition on one side of the p-side band gap change layer 256 is equalized to that of the p-side first semiconductor layer 215 while the composition on the other side is equalized to that of the p-type second semiconductor layer 217, which obtains the same effect as that of the p-side band gap change layer 216 of FIG. 8. That is, the p-side band gap change layer 256 is deposited such that one side of the p-side band gap change layer 256 is adjacent to the p-side first semiconductor layer 215 while the other side is adjacent to the p-type second semiconductor layer 217, which eliminates the steep change in composition between the p-side first semiconductor layer 215 and the p-side band gap change layer 256 and between the p-side band gap change layer 256 and the p-type second semiconductor layer 217. Accordingly, the polarization charge obstructing the carrier transport can be dispersed, and the holes can be smoothly moved from the p-type second semiconductor layer 217 to the p-side first semiconductor layer 215.

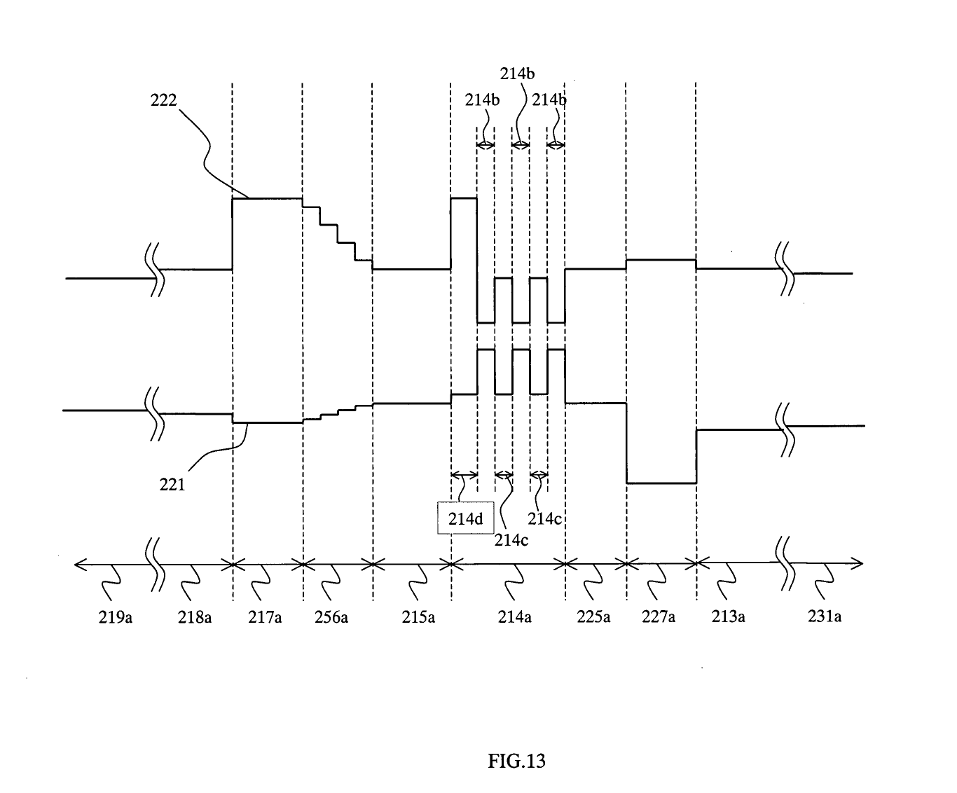

FIG. 13 is a conceptual view showing a band diagram of the semiconductor light emitting device 805. In FIG. 13, the same numeral as FIGS. 9 and 11 designates the same region of the deposited film having the same function. The band diagram of the semiconductor light emitting device 805 of FIG. 13 differs from the band diagram of the semiconductor light emitting device 803 of FIG. 11 in that the region 216a of the band gap change layer 216 does not exist on the p-type side with respect to the region 214a of the active layer 214, but the region 256a of the p-side band gap change layer 256 is displayed. In FIG. 13, parts of the band gaps are not shown in the range of the p-type contact layer 218 to the stripe-shape electrode 219 and in the range of the n-type underlying layer 213 to the electrode 231.

The stripe-shape electrode 219 is set at the anode, the electrode 231 is set at the cathode, and the voltage is applied. This enables the electrons from the electrode 231 and the holes from the stripe-shape electrode 219 are injected into the semiconductor light emitting device 805.

As described in the band gap of the semiconductor light emitting device 801 of FIG. 9, the electrons injected from the electrode 231 are concentrated in each quantum well of the active layer 214 of the semiconductor light emitting device 805.

On the other hand, the top level 221 of the valence band of the p-side first semiconductor layer 215 and the top level 221 of the valence band of the p-type second semiconductor layer 217 are connected in the stepwise manner on the p-type side with respect to the active layer 214 by the p-side band gap change layer 256, and the holes injected from the stripe-shape electrode 219 can be moved along the top level 221 of the valence band to the p-side first semiconductor layer 215 which is stabilized from the viewpoint of energy. As described in the band gap of the semiconductor light emitting device 801 of FIG. 9, the holes moved to the p-side first semiconductor layer 215 are concentrated in each quantum well of the active layer 214 of the semiconductor light emitting device 805.

Accordingly, the semiconductor light emitting device 805 emits the light having the wavelength according to the band gap expressed between the top level 221 of the valence band and the bottom level 222 of conduction band in the quantum well.

Similarly to the semiconductor light emitting device 801 of FIG. 8, in the semiconductor light emitting device 805, the distance in the depositing direction between the active layer 214 and the p-side band gap change layer 256 exists within the constant range. Therefore, the holes narrowed and injected by the stripe-shape electrode 219 intensively reach the portion immediately below the stripe-shape electrode 219 of the active layer 214 as shown by the hole flows 291 of FIG. 8.

Accordingly, the invention can provide a semiconductor light emitting device in which the carriers can be smoothly moved between the two semiconductor layers having the different compositions without increasing the impurity concentration, namely, without degrading the optical characteristics and reliability.

That is, similarly to the semiconductor light emitting device 801, the semiconductor light emitting device 805 can obtain the effects such as the decrease in threshold current, the current-light quantity slope efficiency, and the improvement of the brightness.

Similarly to the semiconductor light emitting device 801, the effect of the p-side band gap change layer 256, namely, the effect of the dispersion of the polarization charge becomes maximum in the semiconductor light emitting device 805, in the case where the depositing directions of the p-side first semiconductor layer 215, the p-side band gap change layer 256, and the p-type second semiconductor layer 217 are orientated toward the c-axis directions of the group-III nitride compound crystals. Accordingly, the p-side band gap change layer 256 makes the carrier transport smooth between the two semiconductor layers having the different compositions without increasing the impurity concentration of the p-side first semiconductor layer 215, namely, without degrading the optical characteristics and reliability.

Similarly to the semiconductor light emitting device 801, the semiconductor light emitting device 805 can be formed into the both-side electrode type semiconductor light emitting device by depositing the semiconductor layer on the n-type substrate 212 described in the semiconductor light emitting device 801 of FIG. 8.

### Seventh Embodiment

A seventh embodiment is a semiconductor light emitting device including an active layer which emits light by recombination of an electron and a hole; a first semiconductor layer which is deposited on an n-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the n-type side with respect to the active layer and a center in the direction of thickness of the band gap change layer ranges from 30 (nm) to 200 (nm), and a band gap of the band gap change layer is continuously monotonously changed from a band gap which is substantially equal to that of the first semiconductor layer to a band gap which is substantially equal to that of the second semiconductor layer from the side adjacent to the first semiconductor layer to the side adjacent to the second semiconductor layer.

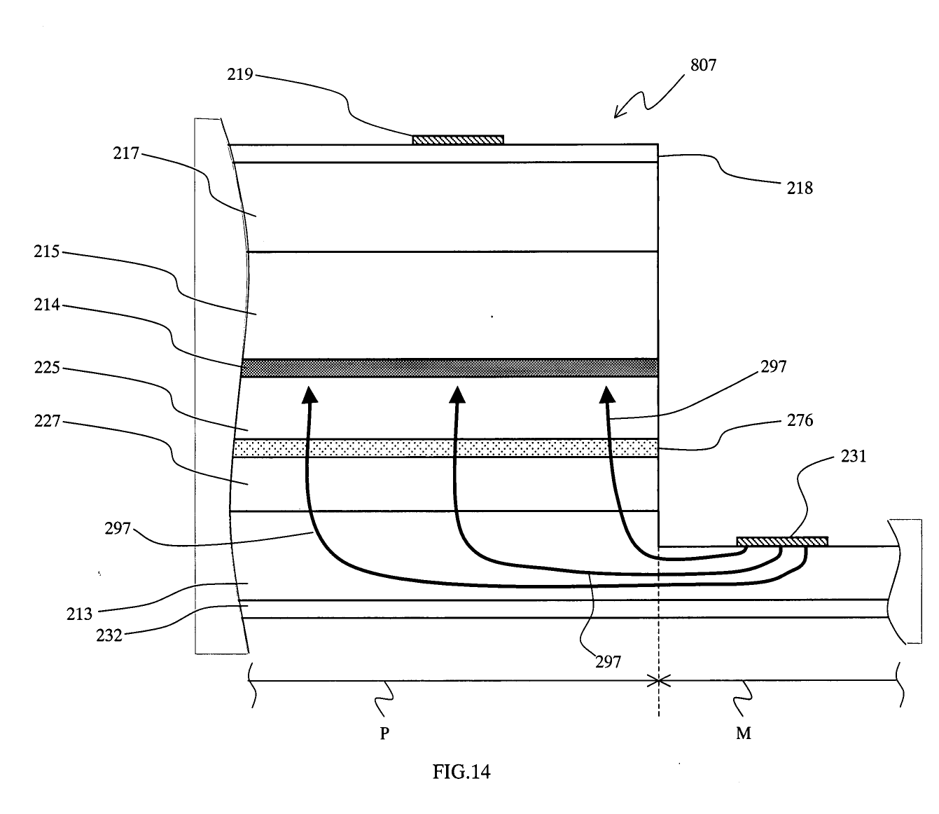

FIG. 14 is a conceptual view showing a cross section of a semiconductor light emitting device 807 which is of an embodiment according to a fifth aspect of the invention. In FIG. 14, the same semiconductor layer having the same function as FIGS. 8, 10, and 12 is designated by the same numeral. The semiconductor light emitting device 807 differs from the semiconductor light emitting device 803 of FIG. 10 in that the semiconductor light emitting device 807 does not include the p-side band gap change layer 216 of the semiconductor light emitting device 803 but include an n-side band gap change layer 276.

Similarly to the p-side band gap change layer 216 of FIG. 8, then-side band gap change layer 276 is an AlₓGa_{y}In_{1-x-y}N compound layer in which the composition is continuously monotonously changed in the depositing direction. That is, in the composition in the depositing direction of the n-side band gap change layer 276, the values of x and y in the composition formula are continuously monotonously changed from one side of the n-side band gap change layer 276 to the other side. An example of the n-side band gap change layer 276 includes the group-III nitride compound having the same composition as the p-side band gap change layer 216 described in FIG. 8.

Since the composition of the n-side band gap change layer 276 is continuously monotonously changed, the lattice strain caused by the steep change in composition can be decreased in the n-side band gap change layer 276.

Preferably the thickness of the n-side band gap change layer 276 is 3 (nm) or more and less than 100 (nm), and more preferably the thickness ranges from 3 (nm) to 50 (nm).

The n-type impurity may be added to the n-side band gap change layer 276 in order to form the n-side band gap change layer 276 into the n-type semiconductor. Specifically Si can be cited as an example of the n-type impurity. For example, the impurity concentration n can range from 5×10¹⁷ (cm⁻³) to 5×10¹⁸ (cm⁻³). As described in the p-side band gap change layer 216 of FIG. 8, the impurity concentration range of the n-side band gap change layer 276 is preferably computed from the charge density of the polarization generated at the interface between the n-side first semiconductor layer 225 and the n-type second semiconductor layer 227 and the thickness of the n-side band gap change layer 276.

The semiconductor light emitting device 807 is produced as follows. The n-type underlying layer 213, the n-type second semiconductor layer 227, the n-side band gap change layer 276, the n-side first semiconductor layer 225, the active layer 214, the p-side first semiconductor layer 215, the p-type second semiconductor layer 217, and the p-type contact layer 218 are sequentially deposited on the n-type substrate 232 using the MOCVD method. The n-side first semiconductor layer 225 and the n-side band gap change layer 276 are deposited such that the distance in the depositing direction from the interface between the active layer 214 and the n-side first semiconductor layer 225 to the center in the direction of thickness of the n-side band gap change layer 276 ranges from 30 (nm) to 200 (nm), preferably ranges from 30 (nm) to 100 (nm). Therefore, in order to set the distance between the active layer 214 and the n-side band gap change layer 276 at the above range, the thickness of the n-side first semiconductor layer 225 ranges from 20 (nm) to 200 (nm).

Then, the stripe-shape electrode 219 is formed as described in the semiconductor light emitting device 801 of FIG. 8. Then, the negative electrode portion M is formed to form the electrode 231 as described in semiconductor light emitting device 803 of FIG. 10.

The composition on one side of the n-side band gap change layer 276 is equalized to that of the n-side first semiconductor layer 225 while the composition on the other side is equalized to that of the n-type second semiconductor layer 227, which obtains the same effect as that of the p-side band gap change layer 216 of FIG. 8. That is, the n-side band gap change layer 276 is deposited such that one side of the n-side band gap change layer 276 is adjacent to the n-side first semiconductor layer 225 while the other side is adjacent to the n-type second semiconductor layer 227, which eliminates the steep change in composition between the n-side first semiconductor layer 225 and the n-side band gap change layer 276 and between the n-side band gap change layer 276 and the n-type second semiconductor layer 227. Accordingly, the polarization charge obstructing the carrier transport can be dispersed, and the electrons can be smoothly moved from the n-type second semiconductor layer 227 to the n-side first semiconductor layer 225.

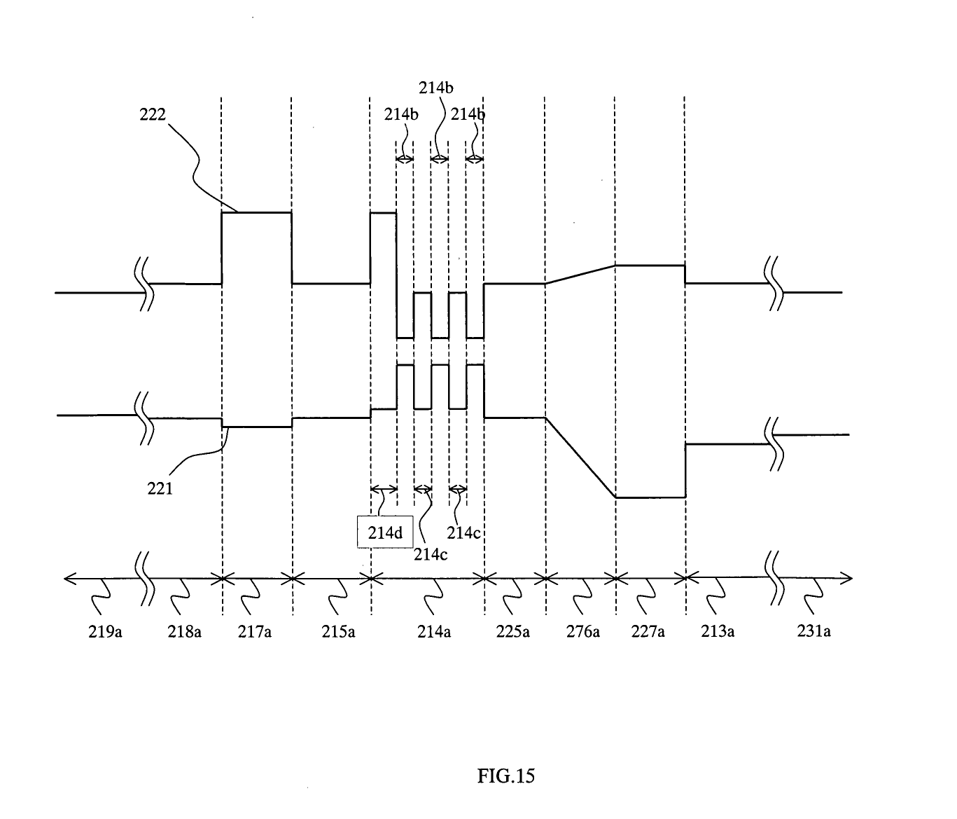

FIG. 15 is a conceptual view showing a band diagram of the semiconductor light emitting device 807. In FIG. 15, the same numeral as FIGS. 9, 11, and 13 designates the same region of the deposited film having the same function. The band diagram of the semiconductor light emitting device 807 of FIG. 15 differs from the band diagram of the semiconductor light emitting device 803 of FIG. 11 in that the region 216a of the band gap change layer 216 does not exist on the p-type side with respect to the region 214a of the active layer 214, but the region 276a of the n-side band gap change layer 276 is displayed on the n-type side with respect to the region 214a of the active layer 214. In FIG. 15, parts of the band gaps are not shown in the range of the p-type contact layer 218 to the stripe-shape electrode 219 and in the range of the n-type underlying layer 213 to the electrode 231.

The stripe-shape electrode 219 is set at the anode, the electrode 231 is set at the cathode, and the voltage is applied. This enables the electrons from the electrode 231 and the holes from the stripe-shape electrode 219 are injected into the semiconductor light emitting device 807.

The electrons injected from the electrode 231 can be smoothly moved toward the active layer 214 through the n-type underlying layer 213 and n-type second semiconductor layer 227 in which the electrons are the majority carriers. The band gap of the n-side first semiconductor layer 225 is narrower than that of the n-type second semiconductor layer 227, and the bottom level 222 of the conduction band of the n-side first semiconductor layer 225 and the bottom level 222 of the conduction band of the n-type second semiconductor layer 227 are gently connected by the n-side band gap change layer 276, so that the electrons can be smoothly moved along the bottom level 222 of the conduction band to the n-side first semiconductor layer 225 which is stabilized from the viewpoint of energy. The electrons moved to the n-side first semiconductor layer 225 are concentrated in each quantum well of the active layer 214 where the band gap is narrower than that of the n-side first semiconductor layer 225.

On the other hand, the holes injected from the stripe-shape electrode 219 are moved toward the active layer 214 through the p-type contact layer 218 and p-type second semiconductor layer 217 where the hole is the majority carrier. Because the band gap of the p-side first semiconductor layer 215 is narrower than that of the p-type second semiconductor layer 217, the holes can be moved along the top level 221 of the valence band to the p-side first semiconductor layer 215 which is stabilized from the viewpoint of energy. The holes are concentrated in each quantum well of the active layer 214 where the band gap is narrower than that of the p-side first semiconductor layer 215.

Accordingly, the semiconductor light emitting device 807 emits the light having the wavelength according to the band gap expressed between the top level 221 of the valence band and the bottom level 222 of conduction band in the quantum well.

The distance in the depositing direction between the active layer 214 and the n-side band gap change layer 276 exists within the constant range, and the electrons can be smoothly moved from the n-type second semiconductor layer 227 to the n-side first semiconductor layer 225. Therefore, the electrons injected from the electrode 231 are not concentrated in one point, but the electrons can evenly be moved through the n-type second semiconductor layer 227, the n-side band gap change layer 276, and the n-side first semiconductor layer 225 as shown by electron flows 297 of FIG. 14 to decrease the electrical resistance of the semiconductor light emitting device 807.

Accordingly, the invention can provide a semiconductor light emitting device in which the carriers can be smoothly moved between the two semiconductor layers having the different compositions without increasing the impurity concentration, namely, without degrading the optical characteristics and reliability.

That is, similarly to the semiconductor light emitting device 801, the semiconductor light emitting device 807 can obtain the effects such as the decrease in threshold current, the current-light quantity slope efficiency, and the improvement of the brightness.

Similarly to the semiconductor light emitting device 801, the effect of the n-side band gap change layer 276, namely, the effect of the dispersion of the polarization charge becomes maximum in the semiconductor light emitting device 807, in the case where the depositing directions of the n-side first semiconductor layer 225, the n-side band gap change layer 276, and the n-type second semiconductor layer 227 are orientated toward the c-axis directions of the group-III nitride compound crystals. Accordingly, the n-side band gap change layer 276 makes the carrier transport smooth between the two semiconductor layers having the different compositions without increasing the impurity concentration of the n-side first semiconductor layer 225, namely, without degrading the optical characteristics and reliability.

Similarly to the semiconductor light emitting device 801, the semiconductor light emitting device 807 can be formed into the both-side electrode type semiconductor light emitting device by depositing the semiconductor layer on the n-type substrate 212 described in the semiconductor light emitting device 801 of FIG. 8.

### Eighth Embodiment

An eighth embodiment is a semiconductor light emitting device including an active layer which emits light by recombination of an electron and a hole; a first semiconductor layer which is deposited on an n-type side with respect to the active layer, the first semiconductor layer being made of a group-III nitride compound expressed by a composition formula of AlₓGa_{y}In_{1-x-y}N (0≦x≦1, 0≦y≦1, and 0≦x+y≦1); a band gap change layer which is deposited adjacent to the first semiconductor layer while located on an opposite side to the active layer, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; and a second semiconductor layer which is deposited adjacent to the band gap change layer while located on an opposite side to the first semiconductor layer, the second semiconductor layer being made of a group-III nitride compound expressed by the composition formula of AlₓGa_{y}In_{1-x-y}N (0≦x≦1, 0≦y≦1, and 0≦x+y≦1), wherein a distance in the depositing direction between an end of the active layer on the n-type side with respect to the active layer and a center in the direction of thickness of the band gap change layer ranges from 30 (nm) to 200 (nm), a band gap of the band gap change layer is monotonously changed in the stepwise manner from a band gap which is substantially equal to that of the first semiconductor layer to a band gap which is substantially equal to that of the second semiconductor layer from the side adjacent to the first semiconductor layer to the side adjacent to the second semiconductor layer.

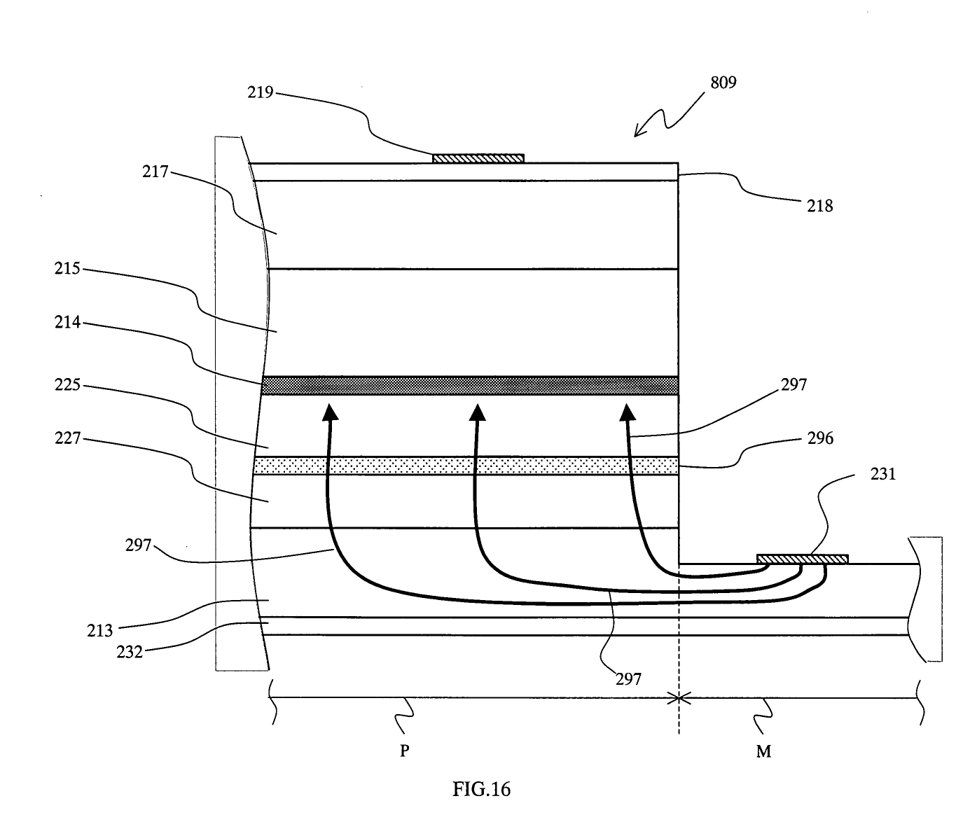

FIG. 16 is a conceptual view showing a cross section of a semiconductor light emitting device 809 which is of an embodiment according to a sixth aspect of the invention. In FIG. 16, the same semiconductor layer having the same function as FIGS. 8, 10, 12, and 14 is designated by the same numeral. The semiconductor light emitting device 809 differs from the semiconductor light emitting device 807 of FIG. 14 in that the semiconductor light emitting device 809 does not include the n-side band gap change layer 276 of the semiconductor light emitting device 807 but include an n-side band gap change layer 296.

The n-side band gap change layer 296 is an AlₓGa_{y}In_{1-x-y}N compound layer in which the composition is monotonously changed in the stepwise manner in the depositing direction. That is, in the composition in the depositing direction of the n-side band gap change layer 296, the values of x and y in the composition formula are monotonously changed in the stepwise manner from one side of the n-side band gap change layer 296 to the other side. An example of the n-side band gap change layer 296 includes the group-III nitride compound having the same composition as the p-side band gap change layer 256 described in FIG. 12.

Since the composition of the n-side band gap change layer 296 is monotonously changed in the stepwise manner, the lattice strain caused by the steep change in composition can be decreased in the n-side band gap change layer 296.

Preferably the thickness of the n-side band gap change layer 296 is 3 (nm) or more and less than 100 (nm), and more preferably the thickness ranges from 3 (nm) to 50 (nm).

In order to form the n-side band gap change layer 296 into the n-type semiconductor, the n-type impurity may be added to the n-side band gap change layer 296 in the impurity concentration range described in the p-side band gap change layer 216 of FIG. 8. Specifically Si can be cited as an example of the n-type impurity. For example, the impurity concentration n can range from 5×10¹⁷ (cm⁻³) to 5×10¹⁸ (cm⁻³). As described in the p-side band gap change layer 216 of FIG. 8, the impurity concentration range of the n-side band gap change layer 296 is preferably computed from the charge density of the polarization generated at the interface between the n-side first semiconductor layer 225 and the n-type second semiconductor layer 227 and the thickness of the n-side band gap change layer 296.

The semiconductor light emitting device 809 is produced as follows. The n-type underlying layer 213, the n-type second semiconductor layer 227, the n-side band gap change layer 296, the n-side first semiconductor layer 225, the active layer 214, the p-side first semiconductor layer 215, the p-type second semiconductor layer 217, and the p-type contact layer 218 are sequentially deposited on the n-type substrate 232 using the MOCVD method. As described in the semiconductor light emitting device 805 of FIG. 12, in the production of the n-side band gap change layer 296, the production parameters are changed to deposit the n-side band gap change layer 296 in the stepwise manner in each predetermined time. The n-side first semiconductor layer 225 and the n-side band gap change layer 296 are deposited such that the distance in the depositing direction from the interface between the active layer 214 and the n-side first semiconductor layer 225 to the center in the direction of thickness of the n-side band gap change layer 296 ranges from 30 (nm) to 200 (nm), preferably ranges from 30 (nm) to 100 (nm).

Then, the stripe-shape electrode 219 is formed as described in the semiconductor light emitting device 801 of FIG. 8. Then, the negative electrode portion M is formed to form the electrode 231 as described in semiconductor light emitting device 803 of FIG. 10.

The composition on one side of the n-side band gap change layer 296 is equalized to that of the n-side first semiconductor layer 225 while the composition on the other side is equalized to that of the n-type second semiconductor layer 227, which obtains the same effect as that of the p-side band gap change layer 216 of FIG. 8. That is, the n-side band gap change layer 296 is deposited such that one side of the n-side band gap change layer 296 is adjacent to the n-side first semiconductor layer 225 while the other side is adjacent to the n-type second semiconductor layer 227, which eliminates the steep change in composition between the n-side first semiconductor layer 225 and the n-side band gap change layer 296 and between the n-side band gap change layer 296 and the n-type second semiconductor layer 227. Therefore, the polarization charge obstructing the carrier transport can be dispersed, and the electrons can be smoothly moved from the n-type second semiconductor layer 227 to the n-side first semiconductor layer 225.

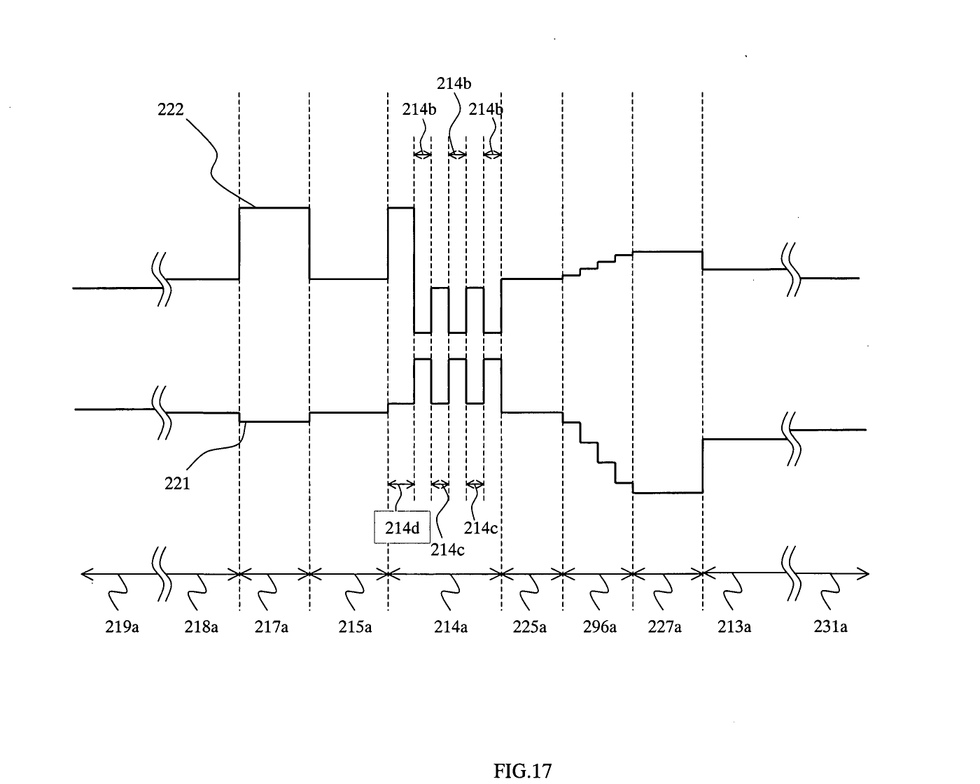

FIG. 17 is a conceptual view showing a band diagram of the semiconductor light emitting device 809. In FIG. 17, the same numeral as FIGS. 9, 11, 13, and 15 designates the same region of the deposited film having the same function. The band diagram of the semiconductor light emitting device 809 of FIG. 17 differs from the band diagram of the semiconductor light emitting device 807 of FIG. 14 in that the region 276a of the n-side band gap change layer 276 does not exist on the n-type side with respect to the region 214a of the active layer 214, but a region 296a of the n-side band gap change layer 296 is displayed. In FIG. 17, parts of the band gaps are not shown in the range of the p-type contact layer 218 to the stripe-shape electrode 219 and in the range of the n-type underlying layer 213 to the electrode 231.

The stripe-shape electrode 219 is set at the anode, the electrode 231 is set at the cathode, and the voltage is applied. This enables the electrons from the electrode 231 and the holes from the stripe-shape electrode 219 are injected into the semiconductor light emitting device 809.

The bottom level 222 of the conduction band of the n-side first semiconductor layer 225 and the bottom level 222 of the conduction band of the n-type second semiconductor layer 227 are connected in the step wise manner by the n-side band gap change layer 296, so that the electrons can be smoothly moved along the bottom level 222 of the conduction band to the n-side first semiconductor layer 225 which is stabilized from the viewpoint of energy. The electrons moved to the n-side first semiconductor layer 225 are concentrated in each quantum well of the active layer 214 of the semiconductor light emitting device 809.

On the other hand, as described in the band diagram of the semiconductor light emitting device 801 of FIG. 8, the holes injected from the stripe-shape electrode 219 are concentrated in each quantum well of the active layer 214 of the semiconductor light emitting device 809.

Accordingly, the semiconductor light emitting device 809 emits the light having the wavelength according to the band gap expressed between the top level 221 of the valence band and the bottom level 222 of conduction band in the quantum well.

Similarly to the n-side band gap change layer 276 of the semiconductor light emitting device 807 shown in FIG. 14, in the n-side band gap change layer 296 of the semiconductor light emitting device 809, the distance in the depositing direction between the active layer 214 and the n-side band gap change layer 296 exists within the constant range. Therefore, the electrons can be smoothly moved from the n-type second semiconductor layer 227 to the n-side first semiconductor layer 225 to decrease the electrical resistance of the semiconductor light emitting device 809.

Accordingly, the invention can provide a semiconductor light emitting device in which the carriers can be smoothly moved between the two semiconductor layers having the different compositions without increasing the impurity concentration, namely, without degrading the optical characteristics and reliability.

That is, similarly to the semiconductor light emitting device 801, the semiconductor light emitting device 809 can obtain the effects such as the decrease in threshold current, the current-light quantity slope efficiency, and the improvement of the brightness.

Similarly to the semiconductor light emitting device 801, the effect of the n-side band gap change layer 296, namely, the effect of the dispersion of the polarization charge becomes maximum in the semiconductor light emitting device 809, in the case where the depositing directions of the n-side first semiconductor layer 225, the n-side band gap change layer 296, and the n-type second semiconductor layer 227 are orientated toward the c-axis directions of the group-III nitride compound crystals. Accordingly, the n-side band gap change layer 296 makes the carrier transport smooth between the two semiconductor layers having the different compositions without increasing the impurity concentration of the n-side first semiconductor layer 225, namely, without degrading the optical characteristics and reliability.

Similarly to the semiconductor light emitting device 801, the semiconductor light emitting device 809 can be formed into the both-side electrode type semiconductor light emitting device by depositing the semiconductor layer on the n-type substrate 212 described in the semiconductor light emitting device 801 of FIG. 8.

### Ninth Embodiment

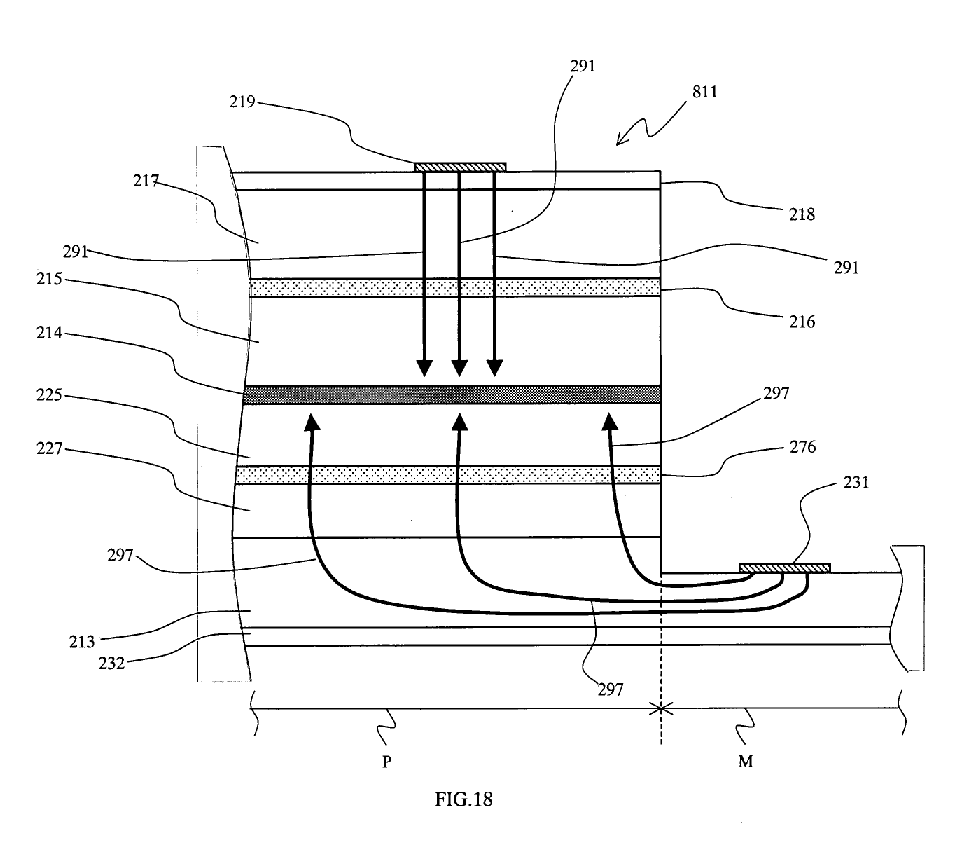

FIG. 18 is a conceptual view showing a cross section of a semiconductor light emitting device 811 which is of another embodiment according to the third aspect of the invention. In FIG. 18, the same semiconductor layer having the same function as FIGS. 8, 10, 12, 14, and 16 is designated by the same numeral. The semiconductor light emitting device 811 differs from the semiconductor light emitting device 803 of FIG. 10 in that the semiconductor light emitting device 811 includes the n-side band gap change layer 276 between the n-side first semiconductor layer 225 and the n-type second semiconductor layer 227 of the semiconductor light emitting device 803.

The semiconductor light emitting device 811 is produced as follows. The n-type underlying layer 213, the n-type second semiconductor layer 227, the n-side band gap change layer 276, the n-side first semiconductor layer 225, the active layer 214, the p-side first semiconductor layer 215, the p-type second semiconductor layer 217, and the p-type contact layer 218 are sequentially deposited on the n-type substrate 232 using the MOCVD method. The p-side first semiconductor layer 215, the p-side band gap change layer 216, the n-side first semiconductor layer 225, and the n-side band gap change layer 276 are deposited such that the distance in the depositing direction from the interface between the active layer 214 and the p-side first semiconductor layer 215 to the center in the direction of thickness of the p-side band gap change layer 216 and the distance in the depositing direction from the interface between the active layer 214 and the n-side first semiconductor layer 225 to the center in the direction of thickness of the n-side band gap change layer 276 range from 30 (nm) to 200 (nm), preferably ranges from 30 (nm) to 100 (nm).

Then, the stripe-shape electrode 219 is formed as described in the semiconductor light emitting device 801 of FIG. 8. Then, the negative electrode portion M is formed to form the electrode 231 as described in semiconductor light emitting device 803 of FIG. 10.

As described in the semiconductor light emitting device 801 of FIG. 8 and in the semiconductor light emitting device 807 of FIG. 14, the polarization charge obstructing the carrier transport can be dispersed by arranging the p-side band gap change layer 216 and the n-side band gap change layer 276. Therefore, the holes can be smoothly moved from the p-type second semiconductor layer 217 to the p-side first semiconductor layer 215, and the electrons can be smoothly moved from the n-type second semiconductor layer 227 to the n-side first semiconductor layer 225.

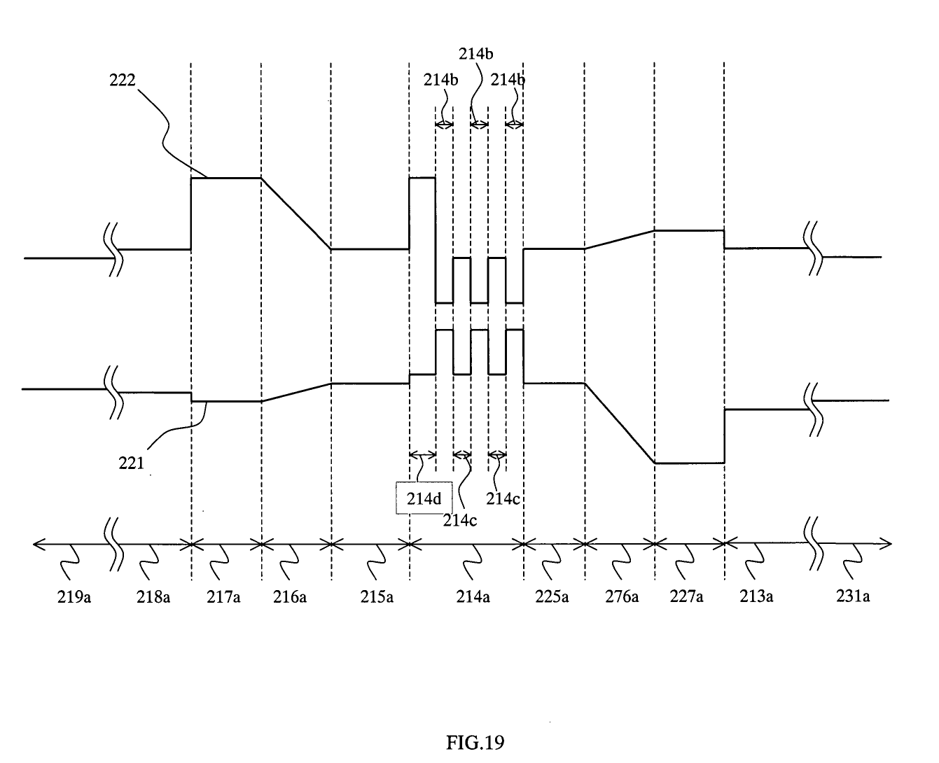

FIG. 19 is a conceptual view showing a band diagram of the semiconductor light emitting device 811. In FIG. 19, the same numeral as FIGS. 9, 11, 13, 15, and 17 designates the same region of the deposited film having the same function. The band diagram of the semiconductor light emitting device 811 of FIG. 19 differs from the band diagram of the semiconductor light emitting device 803 of FIG. 11 in that the region 276a of the n-side band gap change layer 276 is displayed on the n-type side with respect to the region 214a of the active layer 214. In FIG. 19, parts of the band gaps are not shown in the range of the p-type contact layer 218 to the stripe-shape electrode 219 and in the range of the n-type underlying layer 213 to the electrode 231.

The stripe-shape electrode 219 is set at the anode, the electrode 231 is set at the cathode, and the voltage is applied. This enables the electrons from the electrode 231 and the holes from the stripe-shape electrode 219 are injected into the semiconductor light emitting device 811.

As described in the band gap of the semiconductor light emitting device 807 of FIG. 15, the electrons injected from the electrode 231 are concentrated in each quantum well of the active layer 214 of the semiconductor light emitting device 811.

On the other hand, as described in the band diagram of the semiconductor light emitting device 801 of FIG. 9, the holes injected from the stripe-shape electrode 219 are concentrated in each quantum well of the active layer 214 of the semiconductor light emitting device 811.

Accordingly, the semiconductor light emitting device 811 emits the light having the wavelength according to the band gap expressed between the top level 221 of the valence band and the bottom level 222 of conduction band in the quantum well.

Similarly to the semiconductor light emitting device 801 of FIG. 8, in the semiconductor light emitting device 811, the distance in the depositing direction between the active layer 214 and the p-side band gap change layer 216 exists within the constant range. Therefore, the holes narrowed and injected by the stripe-shape electrode 219 intensively reach the portion immediately below the stripe-shape electrode 219 of the active layer 214 as shown by the hole flows 291 of FIG. 18.

On the other hand, similarly to the semiconductor light emitting device 807 of FIG. 14, in the semiconductor light emitting device 811, the distance in the depositing direction between the active layer 214 and the n-side band gap change layer 276 exists within the constant range. Therefore, the electrons can be smoothly moved from the n-type second semiconductor layer 227 to the n-side first semiconductor layer 225 to decrease the electrical resistance of the semiconductor light emitting device 811 as shown by the hole flows 297 of FIG. 18.

Accordingly, the invention can provide a semiconductor light emitting device in which the carriers can be smoothly moved between the two semiconductor layers having the different compositions without increasing the impurity concentration, namely, without degrading the optical characteristics and reliability.

That is, similarly to the semiconductor light emitting device 801, the semiconductor light emitting device 811 can obtain the effects such as the decrease in threshold current, and the improvement of the current-light quantity slope efficiency and the brightness.

Similarly to the semiconductor light emitting device 801 and semiconductor light emitting device 807, the effect of the n-side band gap change layer 276, namely, the effect of the dispersion of the polarization charge becomes maximum in the semiconductor light emitting device 811, in the case where the depositing directions of the semiconductor layers are orientated toward the c-axis directions of the group-III nitride compound crystals.

In the semiconductor light emitting device 811, the same effects can be obtained even if the p-side band gap change layer 256 described in FIG. 12 is arranged instead of the p-side band gap change layer 216 and/or even if the n-side band gap change layer 296 described in FIG. 16 is arranged instead of the n-side band gap change layer 276.

### Tenth Embodiment

In a tenth embodiment, an electrode to which the voltage is applied from the outside is further provided on the opposite side to the side of the band gap change layer of the p-type second semiconductor layer 217, and the mesa may be formed in the range of the electrode 219 to the p-type second semiconductor layer 217 or in the range of the electrode 219 to the p-side first semiconductor layer 215.

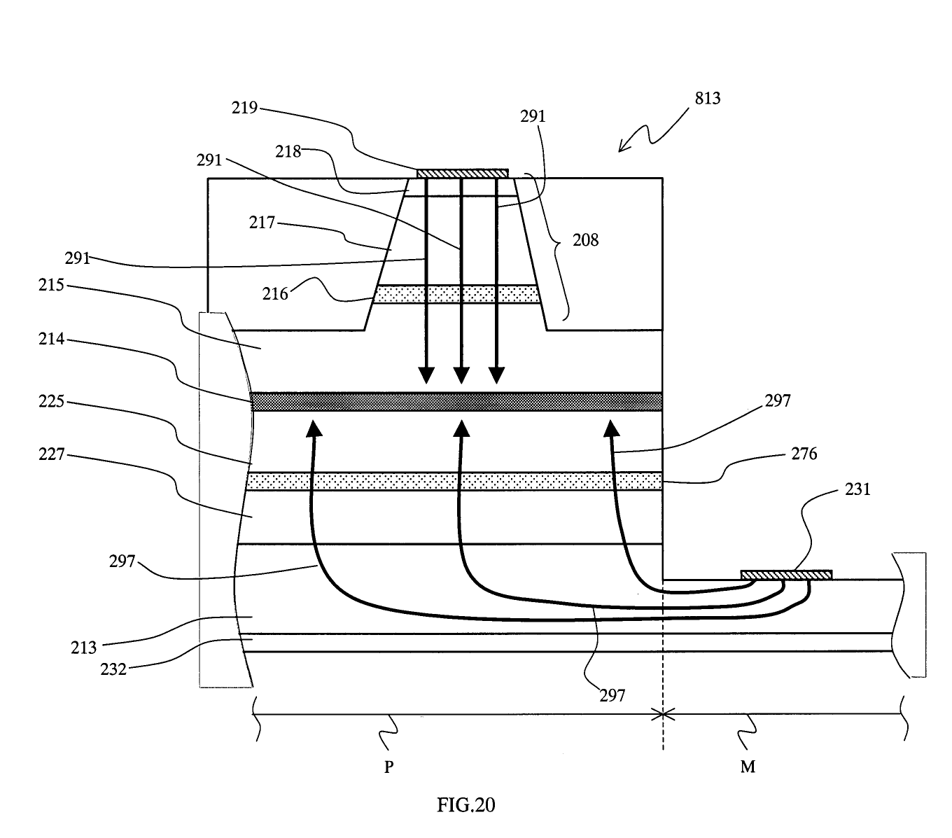

FIG. 20 is a conceptual view showing a cross section of a semiconductor light emitting device 813 which is of still another embodiment according to the third aspect of the invention. The semiconductor light emitting device 813 is a semiconductor laser. The semiconductor light emitting device 813 differs from the semiconductor light emitting device 811 of FIG. 11 in that a mesa 208 is formed in the range of the stripe-shape electrode 219 to a part in the direction of thickness of the p-side first semiconductor layer 215. In FIG. 20, the same semiconductor layer having the same function as FIGS. 8, 10, 12, 14, 16, and 18 is designated by the same numeral. However, in order to cause the semiconductor light emitting device 813 to function as the semiconductor laser, the deposited semiconductor layer is more desirably the following semiconductor.

The n-type underlying layer 213 is desirably made of the GaN compound having the thickness 1 μm or more, in which Si is doped as the impurity. For example, the impurity concentration is 3×10¹⁸ (cm⁻³).

The n-type second semiconductor layer 227 functions as the cladding layer which supplies the electrons to the active layer 214. To this end, desirably the n-type second semiconductor layer 227 is made of the Al_{0.08}Ga_{0.92}N compound, the thickness of the n-type second semiconductor layer 227 is 1000 (nm), and the Si impurity concentration is 3×10¹⁸ (cm⁻³).

The n-side first semiconductor layer 225 functions as the light guide layer which reflects and guides the light emitted from the active layer 214. To this end, desirably the n-side first semiconductor layer 225 is made of the non-doped GaN compound or the low-doped GaN compound in which the Si impurity concentration is not more than 1×10¹⁸ (cm⁻³), and the thickness thereof is 100 (nm).

In the n-side band gap change layer 276, desirably the composition on the side adjacent to the n-side first semiconductor layer 225 is GaN and the composition on the side adjacent to the n-type second semiconductor layer 227 is Al_{0.08}Ga_{0.92}N. In the n-side band gap change layer 276, from the side adjacent to the n-side first semiconductor layer 225 toward the side adjacent to the n-type second semiconductor layer 227, desirably the Al composition is continuously monotonously changed from 0 to 0.08 and the Ga composition is continuously monotonously changed from 1 to 0.92 while the relationship of x+y=is maintained. The thickness of the n-side band gap change layer 276 is 10 (nm). For example, the impurity concentration of the added Si ranges from 1.5×10¹⁸ (cm⁻³) to 9×10¹⁸ (cm⁻³), and preferably the Si impurity concentration is 3×10¹⁸ (cm⁻³).

The active layer 214 has the MQW in which the quantum well is arranged outside, and the active layer 214 has the electron barrier layer at the end of the MQW on the p-type side with respect to the MQW. Desirably the semiconductor thin film which becomes the quantum well is made of the Ga_{0.87} In_{0.13}N compound, the semiconductor thin film which becomes the barrier is made of the GaN compound, and the electron barrier layer is made of the Al_{0.2}Ga_{0.8}N compound. Desirably the thickness of the semiconductor thin film which becomes the quantum well is 3 (nm), the thickness of the semiconductor thin film which becomes the barrier is 10 (nm), and the thickness of the electron barrier layer is 20 (nm). The impurity of Mg is added to the electron barrier layer in order to form the electron barrier layer into the p-type semiconductor. For example, the impurity concentration ranges from 1×10¹⁹ (cm⁻³) to 1×10²⁰ (cm⁻³), and preferably the impurity concentration is 5×10¹⁹ (cm⁻³).

The p-side first semiconductor layer 215 functions as the light guide layer which reflects and guides the light emitted from the active layer 214. To this end, desirably the p-side first semiconductor layer 215 is made of the non-doped GaN compound or the low-doped GaN compound in which the Mg impurity concentration is not more than 1×10¹⁹ (cm⁻³), and the thickness is 100 (nm).

The p-type second semiconductor layer 217 functions as the cladding layer which supplies the holes to the active layer 214. To this end, desirably the p-type second semiconductor layer 217 is m=0.08 in the composition formula, namely, the p-type second semiconductor layer 217 is made of the Al_{0.08}Ga_{0.92}N compound, the thickness is 500 (nm), and the Mg impurity concentration is 3×10¹⁹ (cm⁻³).

In the p-side band gap change layer 216, desirably the composition on the side adjacent to the p-side first semiconductor layer 215 is the GaN compound and the composition on the side adjacent to the p-type second semiconductor layer 217 is the Al_{0.08}Ga_{0.92}N compound. In the p-side band gap change layer 216, from the side adjacent to the p-side first semiconductor layer 215 toward the side adjacent to the p-type second semiconductor layer 217, desirably the Al composition is continuously monotonously changed from 0 to 0.08 and the Ga composition is continuously monotonously changed from 1 to 0.92 while the relationship of x+y=1 is maintained. The thickness of the p-side band gap change layer 216 is 10 (nm). For example, the impurity concentration of the added Mg ranges from 1.5×10¹⁸ (cm⁻³) to 9×10¹⁸ (cm⁻³), and preferably the Mg impurity concentration is 3×10¹⁸ (cm⁻³).

The p-type contact layer 218 is desirably made of the GaN compound, the thickness of the p-type contact layer 218 is 50 (nm), and Mg is doped as the p-type impurity.

In the semiconductor light emitting device 813, the mesa 208 is formed after the semiconductor light emitting device 811 of FIG. 18 is formed.

The stripe-shape electrode 219 is set at the anode, the electrode 231 is set at the cathode, and the voltage is applied. This enables the electrons from the electrode 231 and the holes from the stripe-shape electrode 219 are injected into the semiconductor light emitting device 813.

As described in the semiconductor light emitting device 801 of FIG. 8, in the semiconductor light emitting device 813, because the p-side band gap change layer 216 makes the hole transport smooth between the p-type second semiconductor layer 217 and the p-side first semiconductor layer 215, the holes can be moved near the center portion of the mesa 208 having the good crystallinity.

Because the distance in the depositing direction between the active layer 214 and the p-side band gap change layer 216 exists within the constant range, the diffusion of the holes narrowed and injected by the stripe-shape electrode 219 and mesa 208 is decreased in the p-type second semiconductor layer 217, the p-side band gap change layer 216, and the p-side first semiconductor layer 215, and the holes intensively reach the portion immediately below the stripe-shape electrode 219 of the active layer 214 as shown by the hole flows 291 of FIG. 8.

On the other hand, similarly to the semiconductor light emitting device 807 of FIG. 14, in the semiconductor light emitting device 813, the distance in the depositing direction between the active layer 214 and the n-side band gap change layer 276 exists within the constant range. Therefore, the electrons can be smoothly moved from the n-type second semiconductor layer 227 to the n-side first semiconductor layer 225 to decrease the electrical resistance of the semiconductor light emitting device 813 as shown by the hole flows 297 of FIG. 20.

The electrons and the holes concentrated in the active layer 214 are recombined to emit the light having the wavelength expressed by the quantum well of the MQW. The p-side first semiconductor layer 215 and the n-side first semiconductor layer 225 function as the guide layer which guides the light to promote induced emission.

Accordingly, the invention can provide a semiconductor light emitting device in which the carriers can be smoothly moved between the two semiconductor layers having the different compositions without increasing the impurity concentration, namely, without degrading the optical characteristics and reliability, the semiconductor light emitting device being able to function as the semiconductor laser.

In the semiconductor light emitting device 813, the same effects can be obtained even if the p-side band gap change layer 256 described in FIG. 12 is arranged instead of the p-side band gap change layer 216 and/or even if the n-side band gap change layer 296 described in FIG. 16 is arranged instead of the n-side band gap change layer 276.

Similarly to the semiconductor light emitting device 813, the compositions of the p-side first semiconductor layer 215 and the n-side first semiconductor layer 225 are designed such that a refractive index is smaller than that of the active layer 214 in order to reflect the light emitted from the active layer 214, the p-side first semiconductor layer 215 and the n-side first semiconductor layer 225 have the function of guide layer for guiding the light emitted from the active layer 214, and the p-type second semiconductor layer 217 and the n-type second semiconductor layer 227 function as the cladding layer which supplies the carriers to the active layer 214. Therefore, the semiconductor light-emitting device 801, the semiconductor light emitting device 803, the semiconductor light emitting device 805, the semiconductor light emitting device 807, the semiconductor light emitting device 809, and the semiconductor light emitting device 811 functions as the semiconductor laser for the entire structure.

The configuration of the semiconductor device according to the invention can be applied to light receiving elements. The semiconductor device according to the invention can also be applied to electronic devices such as transistors and diodes and compound high-frequency electronic devices typified by HEMT (High Electron Mobility Transistor).

What is claimed is:

1. A semiconductor device comprising:
a first semiconductor layer which is deposited on a substrate, the first semiconductor layer being made of a group-III nitride compound expressed by a composition formula of AlₓGa_{y}In_{1-x-y}N (0≦x≦1, 0≦y≦1, and 0≦x+y≦1);
a band gap change layer which is deposited adjacent to said first semiconductor layer while located on an opposite side to said substrate, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction;
a second semiconductor layer which is deposited adjacent to said band gap change layer while located on an opposite side to said first semiconductor layer, the second semiconductor layer being made of a group-III nitride compound expressed by the composition formula of AlₓGa_{y}In_{1-x-y}N (0≦x≦1, 0≦y≦1, and 0≦x+y≦1); and
an electrode which is located on an opposite side to said band gap change layer of said second semiconductor layer, a voltage being applied to the electrode from the outside,
wherein, in the depositing direction, the semiconductor device is formed in a mesa shape in a range of said electrode to said second semiconductor layer or to said first semiconductor layer, and
a band gap of said band gap change layer is continuously monotonously changed from a band gap which is substantially equal to that of said first semiconductor layer to a band gap which is substantially equal to that of said second semiconductor layer.

2. A semiconductor device comprising:
a first semiconductor layer which is deposited on a substrate, the first semiconductor layer being made of a group-III nitride compound expressed by a composition formula of AlₓGa_{y}In_{1-x-y}N (0≦x≦1, 0≦y≦1, and 0≦x+y≦1);
a band gap change layer which is deposited adjacent to said first semiconductor layer while located on an opposite side to said substrate, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction;
a second semiconductor layer which is deposited adjacent to said band gap change layer while located on an opposite side to said first semiconductor layer, the second semiconductor layer being made of a group-III nitride compound expressed by the composition formula of AlₓGa_{y}In_{1-x-y}N (0≦x≦1, 0≦y≦1, and 0≦x+y≦1); and
an electrode which is located on an opposite side to said band gap change layer of said second semiconductor layer, a voltage being applied to the electrode from the outside,
wherein, in the depositing direction, the semiconductor device is formed in a mesa shape in a range of said electrode to said second semiconductor layer or said first semiconductor layer, and
in the depositing direction from the first semiconductor layer toward the second semiconductor layer, a band gap of said band gap change layer is monotonously changed in the stepwise manner from a band gap which is substantially equal to that of said first semiconductor layer to a band gap which is substantially equal to that of said second semiconductor layer.

3. A semiconductor device according to claims 1 or 2, wherein said second semiconductor layer is formed into a p-type semiconductor.

4. A semiconductor device according to claims 1 or 2, wherein, in the depositing direction, a thickness of said band gap change layer is 3 (nm) or more and less than 100 (nm).

5. A semiconductor device according to claims 1 or 2, wherein the depositing directions of said first semiconductor layer, said band gap change layer, and said second semiconductor layer are parallel to c-axis directions of the group-III nitride compound crystals of said first semiconductor layer, said band gap change layer, and said second semiconductor layer.

6. A semiconductor device according to claims 1 or 2, wherein, assuming that ρ (cm⁻²) is charge density of polarization generated at an interface where the group-III nitride compound of said first semiconductor layer and the group-III nitride compound of said second semiconductor layer are adjacent to each other and d (cm) is the thickness of said band gap change layer, an impurity concentration n (cm⁻³) of an impurity added into said band gap change layer is in a range of 0.5ρ/d≦n≦3ρ/d.

7. A semiconductor device according to claim 3, further comprising an active layer between said substrate and said first semiconductor layer, the active layer emitting light by recombination of an electron and a hole,
wherein said first semiconductor layer functions as a light guide layer which guides the light emitted from said active layer, the light guide layer having relationship of x=0 and 0.95≦y≦1 in the said composition formula,
said second semiconductor layer functions as a cladding layer which supplies carriers to said active layer, the cladding layer having a relationship of x=m (0.05≦m≦0.1) and x+y=1 in said composition formula,
a composition of said band gap change layer ranges within a relationship of 0≦x≦m and x+y=1 in said composition formula, and
the semiconductor device functions as a semiconductor laser for the entire structure in which said first semiconductor layer, said band gap change layer, said second semiconductor layer, and said active layer are deposited.

8. A semiconductor device according to claim 4, further comprising an active layer between said substrate and said first semiconductor layer, the active layer emitting light by recombination of an electron and a hole,
wherein said first semiconductor layer functions as a light guide layer which guides the light emitted from said active layer, the light guide layer having relationship of x=0 and 0.95≦y≦1 in the said composition formula,
said second semiconductor layer functions as a cladding layer which supplies carriers to said active layer, the cladding layer having a relationship of x=m (0.05≦m≦0.1) and x+y=1 in said composition formula,
a composition of said band gap change layer ranges within a relationship of 0≦x≦m and x+y=1 in said composition formula, and
the semiconductor device functions as a semiconductor laser for the entire structure in which said first semiconductor layer, said band gap change layer, said second semiconductor layer, and said active layer are deposited.

9. A semiconductor device according to claim 5, further comprising an active layer between said substrate and said first semiconductor layer, the active layer emitting light by recombination of an electron and a hole,
wherein said first semiconductor layer functions as a light guide layer which guides the light emitted from said active layer, the light guide layer having relationship of x=0 and 0.95≦y≦1 in the said composition formula,
said second semiconductor layer functions as a cladding layer which supplies carriers to said active layer, the cladding layer having a relationship of x=m (0.05≦m≦0.1) and x+y=1 in said composition formula,
a composition of said band gap change layer ranges within a relationship of 0≦x≦m and x+y=1 in said composition formula, and
the semiconductor device functions as a semiconductor laser for the entire structure in which said first semiconductor layer, said band gap change layer, said second semiconductor layer, and said active layer are deposited.

10. A semiconductor device according to claim 6, further comprising an active layer between said substrate and said first semiconductor layer, the active layer emitting light by recombination of an electron and a hole,
wherein said first semiconductor layer functions as a light guide layer which guides the light emitted from said active layer, the light guide layer having relationship of x=0 and 0.95≦y≦1 in the said composition formula,
said second semiconductor layer functions as a cladding layer which supplies carriers to said active layer, the cladding layer having a relationship of x=m (0.05≦m≦50.1) and x+y=1 in said composition formula,
a composition of said band gap change layer ranges within a relationship of 0≦x≦m and x+y=1 in said composition formula, and
the semiconductor device functions as a semiconductor laser for the entire structure in which said first semiconductor layer, said band gap change layer, said second semiconductor layer, and said active layer are deposited.

11. A semiconductor light emitting device comprising:
an active layer which emits light by recombination of an electron and a hole;
a first semiconductor layer which is deposited on a p-type side with respect to said active layer, the first semiconductor layer being made of a group-III nitride compound expressed by a composition formula of AlₓGa_{y}In_{1-x-y}N (0≦x≦1, 0≦y≦1, and 0≦x+y≦1);
a band gap change layer which is deposited adjacent to said first semiconductor layer while located on an opposite side to said active layer, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; and
a second semiconductor layer which is deposited adjacent to said band gap change layer while located on an opposite side to said first semiconductor layer, the second semiconductor layer being made of a group-III nitride compound expressed by the composition formula of AlₓGa_{y}In_{1-x-y}N (0≦x≦1, 0≦y≦1, and 0≦x+y≦1),
wherein a distance in the depositing direction between an end of said active layer on the p-type side with respect to said active layer and a center in the direction of thickness of said band gap change layer ranges from 30 (nm) to 200 (nm), and
a band gap of said band gap change layer is continuously monotonously changed from a band gap which is substantially equal to that of said first semiconductor layer to a band gap which is substantially equal to that of said second semiconductor layer from the side adjacent to the first semiconductor layer to the side adjacent to the second semiconductor layer.

12. A semiconductor light emitting device comprising:
an active layer which emits light by recombination of an electron and a hole;
a first semiconductor layer which is deposited on a p-type side with respect to said active layer, the first semiconductor layer being made of a group-III nitride compound expressed by a composition formula of AlₓGa_{y}In_{1-x-y}N (0≦x≦1, 0≦y≦1, and 0≦x+y≦1);
a band gap change layer which is deposited adjacent to said first semiconductor layer while located on an opposite side to said active layer, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; and
a second semiconductor layer which is deposited adjacent to said band gap change layer while located on an opposite side to said first semiconductor layer, the second semiconductor layer being made of a group-III nitride compound expressed by the composition formula of AlₓGa_{y}In_{1-x-y}N (0≦x≦1, 0≦y≦1, and 0≦x+y≦1),
wherein a distance in the depositing direction between an end of said active layer on the p-type side with respect to said active layer and a center in the direction of thickness of said band gap change layer ranges from 30 (nm) to 200 (nm), and
a band gap of said band gap change layer is monotonously changed in the stepwise manner from a band gap which is substantially equal to that of said first semiconductor layer to a band gap which is substantially equal to that of said second semiconductor layer from the side adjacent to the first semiconductor layer to the side adjacent to the second semiconductor layer.

13. A semiconductor light emitting device according to claim 11, further comprising an electrode which is located on an opposite side to said band gap change layer of said second semiconductor layer, a voltage being applied to the electrode from the outside,
wherein the semiconductor light emitting device is formed in a mesa shape in a range of said electrode to said second semiconductor layer or to said first semiconductor layer.

14. A semiconductor light emitting device according to claim 12, further comprising an electrode which is located on an opposite side to said band gap change layer of said second semiconductor layer, a voltage being applied to the electrode from the outside,
wherein the semiconductor light emitting device is formed in a mesa shape in a range of said electrode to said second semiconductor layer or to said first semiconductor layer.

15. A semiconductor light emitting device comprising:
an active layer which emits light by recombination of an electron and a hole;
a first semiconductor layer which is deposited on an n-type side with respect to said active layer, the first semiconductor layer being made of a group-III nitride compound expressed by a composition formula of AlₓGa_{y}In_{1-x-y}N (0≦x≦1, 0≦y≦1, and 0≦x+y≦1);
a band gap change layer which is deposited adjacent to said first semiconductor layer while located on an opposite side to said active layer, the band gap change layer being made of a group-III nitride compound expressed by the composition formula of AlₓGa_{y}In_{1-x-y}N (0≦x≦1, 0≦y≦1, and 0≦x+y≦1), a composition being continuously monotonously changed in a depositing direction; and
a second semiconductor layer which is deposited adjacent to said band gap change layer while located on an opposite side to said first semiconductor layer, the second semiconductor layer being made of a group-III nitride compound expressed by the composition formula of AlₓGa_{y}In_{1-x-y}N (0≦x≦1, 0≦y≦1, and 0≦x+y≦1),
wherein a distance in the depositing direction between an end of said active layer on the n-type side with respect to said active layer and a center in the direction of thickness of said band gap change layer ranges from 30 (nm) to 200 (nm), and
a band gap of said band gap change layer is continuously monotonously changed from a band gap which is substantially equal to that of said first semiconductor layer to a band gap which is substantially equal to that of said second semiconductor layer from the side adjacent to the first semiconductor layer to the side adjacent to the second semiconductor layer.

16. A semiconductor light emitting device comprising:
an active layer which emits light by recombination of an electron and a hole;
a first semiconductor layer which is deposited on an n-type side with respect to said active layer, the first semiconductor layer being made of a group-III nitride compound expressed by a composition formula of AlₓGa_{y}In_{1-x-y}N (0≦x≦1, 0≦y≦1, and 0≦x+y≦1);
a band gap change layer which is deposited adjacent to said first semiconductor layer while located on an opposite side to said active layer, the band gap change layer being made of a group-III nitride compound expressed by the composition formula of AlₓGa_{y}In_{1-x-y}N (0≦x≦1, 0≦y≦1, and 0≦x+y≦1), a composition being monotonously changed in a stepwise manner in a depositing direction; and
a second semiconductor layer which is deposited adjacent to said band gap change layer while located on an opposite side to said first semiconductor layer, the second semiconductor layer being made of a group-III nitride compound expressed by the composition formula of AlₓGa_{y}In_{1-x-y}N (0≦x≦1, 0≦y≦1, and 0≦x+y≦1),
wherein a distance in the depositing direction between an end of said active layer on the n-type side with respect to said active layer and a center in the direction of thickness of said band gap change layer ranges from 30 (nm) to 200 (nm), and
a band gap of said band gap change layer is monotonously changed in the stepwise manner from a band gap which is substantially equal to that of said first semiconductor layer to a band gap which is substantially equal to that of said second semiconductor layer from the side adjacent to the first semiconductor layer to the side adjacent to the second semiconductor layer.

17. A semiconductor light emitting device according to any one of claims 11 to 16, wherein, in the depositing direction, a thickness of said band gap change layer is 3 (nm) or more and less than 100 (nm).

18. A semiconductor light emitting device according to any one of claims 11 to 16, wherein the band gap of said second semiconductor layer is broader that that of said first semiconductor layer.

19. A semiconductor light emitting device as in any one of claims 11 to 16, wherein the depositing directions of said first semiconductor layer, said band gap change layer, and said second semiconductor layer are parallel to c-axis directions of the group-III nitride compound crystals of said first semiconductor layer, said band gap change layer, and said second semiconductor layer.

20. A semiconductor light emitting device as in any one of claims 11 to 16, wherein said first semiconductor layer functions as a light guide layer which guides the light emitted from said active layer, the light guide layer having relationship of x=0 and 0.95≦y≦1 in the said composition formula,
said second semiconductor layer functions as a cladding layer which supplies carriers to said active layer, the cladding layer having a relationship of x=m (0.05≦m≦0.1) and x+y=1 in said composition formula,
a composition of said band gap change layer ranges within a relationship of 0≦x≦m and x+y=1 in said composition formula, and
the semiconductor light emitting device functions as a semiconductor laser for the entire structure in which said first semiconductor layer, said band gap change layer, said second semiconductor layer, and said active layer are deposited.

21. A semiconductor light emitting device as in anyone of claims 11 to 16, wherein, assuming that ρ (cm⁻²) is charge density of polarization generated at an interface where the group-III nitride compound of said first semiconductor layer and the group-III nitride compound of said second semiconductor layer are adjacent to each other and d (cm) is the thickness of said band gap change layer, an impurity concentration n (cm⁻³) of an impurity added into said band gap change layer is in a range of 0.5ρ/d≦n≦3ρ/d.
